(19) United States
(12) Patent Application Publication
(10) Pub. No.: US 2024/0413844 A1
(43) Pub. Date: Dec. 12, 2024

(54) MULTI-LOOP SIGNAL PROCESSING

(71) Applicant: Anlotek Limited, London (GB)

(72) Inventors: Jorgen Staal Nielsen, Calgary (CA); Richard Nichols, Manhattan Beach, CA (US)

(21) Appl. No.: 18/517,900

(22) PCT Filed: May 24, 2022
(86) PCT No.: PCT/CA2022/050824

§ 371 Date: Nov. 22, 2023

Related U.S. Application Data
(60) Provisional application No. 63/211,268, filed on Jun. 16, 2021.
(60) Provisional application No. 63/192,055, filed on May 23, 2021.

(51) Int. Cl. H04B 1/00; H03H 17/02; H03M 3/00

(52) U.S. Cl. CPC H04B 1/0028; H03H 17/0286; H03M 3/402; H03M 3/344

(57) ABSTRACT

A signal processing circuit has a first signal loop with a first signal processing block and a first feedback path that extends around the first signal processing block, the first signal processing block having a frequency dependence that causes the first signal loop to generate a passband. A second signal processing block is downstream of the first signal loop. A second feedback path extends from downstream of the second signal processing block to upstream of the first signal processing block. In operation, the first feedback path reinforces a signal in the passband and the second feedback path conditions the signal at an output downstream of the first signal processing block.

### TECHNICAL FIELD

This relates to RF signal processing, and in particular, a multi-loop signal processing architecture.

### BACKGROUND

Tunable radio frequency (RF) filters have used tunable filters in wireless communication as part of the overall processing of received RF signals to extract signal information. Inversely, such tunable filters have been used as part of the process of encoding information onto an RF signal as part of wireless communications.

One type of resonator is an LC tank, although other types of resonators are also known. Within an LC tank, the resonant frequency may be controlled by changing the capacitance, for example via a continuously adjustable capacitor, such as a varactor controlled by a variable bias voltage, or a via a discrete set of capacitances, such as a bank of switched capacitors, or a combination of continuous- and discrete-value capacitances. Other LC resonator implementations that may have a variable L may also be applicable as resonators may also consist of distributed components. Fundamental to a resonator is a structure that can store energy in multiple modalities and that the characteristics of the resonator are a result of the mechanisms for exchanging this energy between these modalities.

Tunable RF filters are generally characterized by control inputs to adjust the center frequency and bandwidth of the resonators that comprise the filter. Issues of operating center frequency, bandwidth, tuning range, resonator stability, and intrinsic noise sources are but a few of the important aspects describing the performance of these tunable RF filters. Additional control of such external factors as temperature or time related component aging needs to be considered.

An RF signal generally refers to a signal that is relatively narrowband such that it can be associated with a carrier frequency that is relatively high. Baseband frequency (BB) is used to imply any frequency that is relatively low. Typically, an RF frequency is at least 10 times that of a BB frequency.

Available wireless radio architectures consist largely of interchanging discrete modules that are designed to meet a required radio frequency (RF) band and process the incoming RF signal. These modules are designed for a discrete frequency range. In general, the carrier frequency may be anywhere from 1 MHz on the low end to 100 GHz on the high end, but this is not limiting.

Current radio architectures for the discrete band RF frequency modules deploy direct-sampling software to process the incoming RF signal and commonly known as a Software Defined Radio (SDR). A direct-sampling software defined radio (DSDR) 10, shown in FIG. 1, is a recent SDR architecture that dispenses with system processing elements such as RF filtering, a down-conversion stage, intermediate frequency (IF) analog processing, and baseband analog processing. DSDR 10 has an antenna 12, analog to digital converter (ADC) 14, digital signal processing (DSP) block 20, digital to analog converter (DAC) 16 and amplifier 18. This direct RF to sampled baseband architecture, illustrated in FIG. 1, is a generic receiver adaptable to any radio signal structure, suitably adapted for the desired RF signal frequency band, with adjustments for the signal center frequency and signal frequency bandwidth.

Antenna 12 as shown in FIG. 1 has separate connections for the receiver and the transmitter for the convenience of illustration. Wideband RF methods can be implemented to accommodate single port antennas.

This existing SDR 10 architecture is enabled by state of the art ADC 14 and DSP 20 signal processing hardware that has emerged with clock rates available up to several tens of GHz. Hence a DSDR 10 can be realized for the range of radio frequencies from 1 MHz to 40 GHz, with essentially only firmware changes via frequency band specific module insertions.

In the ideal DSDR 10 of FIG. 1, the ADC 14 maps the entire RF spectrum into a digitized signal which requires an enormous amount of high-speed DSP following DSDR 10 system ADC 14. Hence while recently available multi-Gsps ADC 14, effective up to 60 Gsps is impressive, albeit power hungry, DSP 10 requires multiple processing steps at very high clock rates and moderate word widths before the signal can be decimated to a lower clock rate.

DSP 20 is one problem but generally the bigger problem is that ADC 14 has to have sufficient dynamic range such that, at the lower end, the quantization noise does not contribute to the receiver NF, and at the upper end, it does not saturate due to the large number of undesired interference signals mixed in with the desired signal.

This has been mitigated to an extent with the recent advent of chip based bandpass filters 22 (BPF) in a front-end module as shown in FIG. 2. Currently available tunable BPF 22 cover discontinuous frequency ranges up to 40 GHz with a tunable response that provides only relatively discrete yet broad bandpass performance. Additional fine tuning is relegated to off-chip discrete frequency surface acoustic wave or bulk acoustic wave (SAW/BAW) filtering with narrower bandwidth and higher Q performance, although there are typically difficulties beyond about 6 GHz. Being fixed, narrow bandwidth, fine tuning off-chip components, these devices take up a significant amount of space on mobile device circuit boards. While the SAW/BAW are typically 10 sq. mm in size, there can be over 30 SAW/BAW devices in a modem mobile device. Not only the size of the SAW/BAW, but the connection terminals and the collective SAW/BAW ground plane allocation adds to the overall circuit board size. However, given the inexorable move to higher frequencies beyond 6 GHz, the SAW/BAW will not likely participate in this trend to higher operating frequencies.

### SUMMARY

According to an aspect, there is provided a signal processing circuit for processing a signal, comprising a bandpass filter having a passband, a signal processing block downstream of the bandpass filter, a first feedback path that extends from between the bandpass filter and the signal processing block to upstream of the bandpass filter, and a second feedback path that extends from downstream of the signal processing block to upstream of the bandpass filter wherein, in operation, the first feedback path reinforces the signal in the passband and the second feedback path conditions the signal at an output downstream of the bandpass filter.

According to other aspects, the signal processing unit may comprise one or more of the following features, alone or in combination: the first feedback path may be a positive feedback path, the second feedback path may be a negative feedback path, and wherein the negative feedback path may suppress internal noise generated downstream of the bandpass filter; a central frequency, a frequency selectivity, or both a central frequency and a frequency selectivity of the bandpass filter may be tunable; the signal processing circuit may further comprise an adjustable scaling block in the first feedback path, the second feedback path, or both the first feedback path and the second feedback path; the signal processing block may apply a first domain transformation, and the negative feedback path may comprise a second processing block that applies a second domain transformation that is the inverse of the first domain transformation; the signal processing block may comprise an analog-to-digital converter (“ADC”), and the second processing block may comprise a digital-to-analog converter (“DAC”); the internal noise may comprise quantization noise from the ADC; the signal processing circuit may further comprise a digital signal processor that conditions a signal in the negative feedback path; an output of the ADC may be connected to a digital signal processor as a receive channel of a software defined radio; the signal processing circuit may comprise a phase control element in the first feedback path, the second feedback path, or each of the first feedback path and the second feedback path; the signal processing circuit may comprise a plurality of bandpass filters connected in series and a plurality of first feedback paths, each bandpass filter comprising a corresponding first feedback path; the signal processing circuit may comprise a plurality of second feedback paths connected in parallel from downstream of the signal processing block to upstream of the plurality of bandpass filters and between adjacent bandpass filters; each of the first feedback paths and the second feedback path may further comprise a gain element; the first feedback path may be a positive feedback path, the second feedback path may be a negative feedback path, and the signal processing circuit may further comprise a controller programmed with instructions to adjust the gain block of the positive feedback path to cause the bandpass filter to self-oscillate, and then adjust the gain block of the negative feedback path to stabilize the bandpass filter; the signal processing circuit may comprise a plurality of bandpass filters and positive and negative feedback paths; the signal processing block may be controlled to control one or more poles of a transfer function of the signal processing circuit; the bandpass filter may comprise an acoustic wave resonator and an adjustable phase control element; and the signal processing may comprise a plurality of acoustic wave filters and a switch that selects a desired one of the plurality of acoustic wave filters

According to an aspect, there is provided a signal processing circuit, comprising a first signal loop having a first signal processing block and a first feedback path that extends around the first signal processing block, the first signal processing block having a frequency dependence that causes the first signal loop to generate a passband. A second signal processing block is downstream of the first signal loop. A second feedback path extends from downstream of the second signal processing block to upstream of the first signal processing block. In operation, the first feedback path reinforces a signal in the passband and the second feedback path conditions the signal at an output downstream of the first signal processing block.

According to other aspects, the signal processing circuit may include one or more of the following aspects: the first feedback path may be a positive feedback path, the second feedback path may be a negative feedback path, and the negative feedback path may suppress internal noise generated downstream of the first signal processing block; the first signal processing block may comprise a resonator; a central frequency, a frequency selectivity, or both a central frequency and a frequency selectivity of the resonator may be tunable; there may be an adjustable scaling block in the first feedback path, the second feedback path, or both the first feedback path and the second feedback path; the second signal processing block may apply a first domain transformation, and the second feedback path may comprise a third processing block that applies a second domain transformation that is an inverse of the first domain transformation; the second signal processing block may comprise an analog-to-digital converter (“ADC”), and the third processing block may comprise a digital-to-analog converter (“DAC”); the internal noise may comprise quantization noise from the ADC; there may be a digital signal processor that conditions a signal in the second feedback path; an output of the ADC may be connected to a digital signal processor as a receive channel of a software defined radio; the first processing block, the second processing block, or both the first processing block and the second processing block may comprise at least a phase control element; the first processing block may comprise a plurality of bandpass filters connected in series, each bandpass filter comprising a corresponding first feedback path; there may be one or more further second feedback paths connected in parallel from downstream of the second signal processing block to between adjacent bandpass filters of the plurality of bandpass filters; the first feedback path may be a positive feedback path, the second feedback path may be a negative feedback path, and there may be a controller programmed with instructions to adjust a positive gain block of the positive feedback path to cause the bandpass filter to self-oscillate, and then adjust a negative gain block of the negative feedback path to stabilize the bandpass filter; the second signal processing block may be controlled by a controller; the first signal processing block may comprise an acoustic wave resonator and an adjustable phase control element; the first signal processing block may comprise a plurality of acoustic wave filters and a switch that selects a desired one of the plurality of acoustic wave filters; there may be a signal input upstream of the first signal loop; there may be a signal input between the first signal processing block and the second signal processing block, the second feedback path comprising a negative gain block.

A method of processing a signal using a signal processing circuit that comprises a first signal loop comprising a first signal processing block and a first feedback path that extends around the first signal processing block such that the first signal loop comprises a passband, a second signal processing block downstream of the bandpass filter, and a second feedback path that extends from downstream of the signal processing block to upstream of the first signal processing block, the method comprising the steps of
causing the first signal loop to generate a filtered signal in the passband;
processing the filtered signal using the second signal processing block downstream of the bandpass filter such that an output signal is conditioned at an output downstream of the bandpass filter.

According to an aspect, there is provided a dual loop signal processing architecture that may be used, for example, for data extraction in a front-end module (FEM), or for other suitable applications. The dual loop architecture may include a set of fixed components whose configuration and operation may be controlled by software. For some examples of a FEM connected to the antenna, the architecture may applicable for both receive and transmit functions.

According to an aspect, there is provided a signal processing circuit for processing a signal, comprising a bandpass filter having a passband; a signal processing block downstream of the bandpass filter; a first feedback path that extends from between the bandpass filter and the signal processing block to upstream of the bandpass filter; and a second feedback path that extends from downstream of the signal processing block to upstream of the bandpass filter. In operation, the first feedback path reinforces the signal in the passband and the second feedback path conditions a signal at an output downstream of the bandpass filter.

In other aspects the signal processing circuit may include one or more of the following aspects, alone or in combination: the first feedback path may be a positive feedback path, the second feedback path may be a negative feedback path, and the negative feedback path may suppress internal noise generated downstream of the bandpass filter; a central frequency, a frequency selectivity, or both a central frequency and a frequency selectivity of the bandpass filter may be tunable; there may be an adjustable scaling block in the first feedback path, the second feedback path, or both the first feedback path and the second feedback path; the signal processing block may apply a first domain transformation, and the negative feedback path may comprise a second processing block that applies a second domain transformation that is the inverse of the first domain transformation, and the signal processing block may comprise an analog-to-digital converter (“ADC”), the second processing block may comprise a digital-to-analog converter (“DAC”), the internal noise may comprises quantization noise from the ADC, there may be a digital signal processor that conditions a signal in the negative feedback path, and an output of the ADC may be connected to a digital signal processor as a receive channel of a software defined radio; there may be a phase control element in the first feedback path, the second feedback path, or each of the first feedback path and the second feedback path; there may be a plurality of bandpass filters connected in series and a plurality of first feedback paths, each bandpass filter may comprise a corresponding first feedback path, there may be a plurality of second feedback paths connected in parallel from downstream of the signal processing block to upstream of the plurality of bandpass filters and between adjacent bandpass filters, each of the first feedback paths and the second feedback path may further comprise a gain element, and where the first feedback path is a positive feedback path and the second feedback path is a negative feedback path, the signal may further comprise a controller programmed with instructions to adjust the gain block of the positive feedback path to cause the bandpass filter to self-oscillate, and then adjust the gain block of the negative feedback path to stabilize the bandpass filter; there may be a plurality of bandpass filters and positive and negative feedback paths; and the signal processing block may be controlled to control one or more poles of a transfer function of the signal processing circuit.

According to an aspect, there is provided a method of processing a signal using a signal processing circuit that comprises a bandpass filter having a passband, a signal processing block downstream of the bandpass filter, a first feedback path that extends from between the bandpass filter and the signal processing block to upstream of the bandpass filter, and a second feedback path that extends from downstream of the signal processing block to upstream of the bandpass filter, the method comprising the steps of filtering a signal in the bandpass filter and reinforcing the signal ins the passband using the first feedback path; processing the filtered signal using the signal processing block downstream of the bandpass filter; and conditioning an output signal at an output downstream of the bandpass filter.

According to other aspects, the method may further comprise one or more of the following elements, alone or in combination: the first feedback path may be a positive feedback path, the second feedback path may be a negative feedback path, and wherein conditioning the output signal may comprise suppressing internal noise generated downstream of the bandpass filter; reinforcing the signal and conditioning the output signal may comprise controlling a gain factor, a phase, or the gain factor and the phase in each of the first feedback path and the second feedback path; the method may further comprise the step of controlling the bandpass filter by tuning a central frequency, a frequency selectivity, or both a central frequency and a frequency selectivity of the bandpass filter; the signal processing block may apply a domain transformation, and the negative feedback path may comprise a second processing block that applies a second domain transformation that is the inverse of the first domain transformation, the signal processing block may be an analog-to-digital converter (“ADC”), and the second processing block comprises a digital-to-analog converter (“DAC”), the internal noise may comprise quantization noise from the ADC; a plurality of bandpass filters may be connected in series with a plurality of positive feedback paths, each bandpass filter comprising a corresponding positive feedback path, and there may be a plurality of negative feedback paths connected in parallel from downstream of the signal processing block to upstream of the plurality of bandpass filters and between adjacent bandpass filters; the method may further comprise the step of adjusting again of the positive feedback path to cause the bandpass filter to self-oscillate, and then adjusting a gain of the negative feedback path to stabilize the bandpass filter; and there may be a plurality of bandpass filters and positive and negative feedback paths.

According to an aspect, there is provided a receive module for a digital communication device, the receive module comprising a bandpass filter having a passband; an analog-to-digital converter (“ADC”) downstream of the bandpass filter, the ADC having an output connected to a processor of the digital communication device; a positive feedback path that extends from between the bandpass filter and the signal processing block to upstream of the bandpass filter; and a negative feedback path that extends from downstream of the signal processing block to upstream of the bandpass filter, the negative feedback path comprising a digital-to-analog converter (“DAC”); wherein, in operation, the positive feedback path reinforces the signal in the passband and the negative feedback path suppresses internal noise generated downstream of the bandpass filter. The digital communication device may comprise a software defined radio.

According to an aspect, there is provided a signal processing circuit for a digital communication device, comprising: an outer signal loop comprising an input, an output, and a transformation block adapted to perform a signal transformation operation on a signal being processed; and an inner signal loop comprising a tunable bandpass filter, the inner signal loop being nested within the outer signal loop such that the tunable bandpass filter is connected within each of the inner signal loop and the outer signal loop, and the transformation block is connected outside the inner signal loop.

According to other aspects, the signal processing circuit may comprise one or more of the following alone or in combination: a central frequency, a frequency selectivity, a Q factor, or combination thereof, of the bandpass filter may be adjustable; the bandpass filter may comprise a plurality of resonator outputs; the transformation block may comprise a processor block that is programmed with instructions to individually control poles of a transfer function of the outer signal loop; the transformation block may be adapted to apply a domain transfer to at least one of the resonator outputs; the transformation block may receive the plurality of resonator outputs in parallel; the outer signal loop may be a negative feedback loop and the inner feedback loop may be a positive feedback loop; the transformation block may be in a signal path of the outer signal loop or in a feedback path of the outer signal loop; the inner signal loop may comprise a positive feedback path and the outer signal loop comprises a negative feedback loop, such that the positive feedback path reinforces the signal in the passband and the negative feedback path suppresses internal noise generated downstream of the bandpass filter; the signal processing block may apply a first domain transformation, and the negative feedback path comprises a second processing block that applies a second domain transformation that is the inverse of the first domain transformation; the signal processing block may comprise an analog-to-digital converter (“ADC”), and the second processing block may comprise a digital-to-analog converter (“DAC”); the internal noise may comprise quantization noise from the ADC; there may be a digital signal processor that conditions a signal in the negative feedback path; the outer signal loop may comprise an output connected to a transmit device; and the inner signal loop may comprise an input upstream of the tunable bandpass filter outer signal loop that is connected to a receive device.

Other aspects of the circuits and methods described above will be apparent from the discussion below.

### BRIEF DESCRIPTION OF THE DRAWINGS

These and other features will become more apparent from the following description in which reference is made to the appended drawings, the drawings are for the purpose of illustration only and are not intended to be in any way limiting, wherein:

FIG. 1 is a schematic diagram of a prior art Direct-Sampling Software defined radio.

FIG. 2 is a schematic diagram of a direct sampling SDR with interchangeable front-end band-pass filtering modules.

FIG. 3 is a schematic diagram of a signal processing circuit.

FIG. 4 is a schematic diagram of an inner loop of a signal processing circuit.

FIG. 5 is a schematic diagram of an inner loop of a signal processing circuit.

FIG. 6 is a plot of a response curve of the inner loop of FIG. 5.

FIG. 7 is a schematic diagram of a sample and hold circuit.

FIG. 8 is a schematic diagram of a signal processing circuit showing the processing.

FIG. 9 is a schematic diagram of a signal processing circuit.

FIG. 10 is a schematic diagram of a signal processing circuit with an additional post processing block.

FIG. 11 is a schematic diagram of a signal processing circuit.

FIG. 12 is a schematic diagram of a signal processing circuit with a plurality of upstream loops.

FIG. 13 is a schematic diagram of a signal processing circuit with a plurality of upstream and downstream loops.

FIG. 14 is a plot showing pole placement of the signal processing circuit of FIG. 5.

FIG. 15 is a schematic diagram of a signal processing circuit.

FIG. 16 plot of the frequency responses of a DPLP compared to a non-DPLP circuit.

FIG. 17 is a schematic diagram of a signal processing circuit with multiple feedback path processing.

FIG. 18 is a schematic diagram of a signal processing path of a wireless signal through a signal processing circuit.

FIG. 19 is a plot showing pole placement moving due to feedback processing.

FIG. 20 is a schematic diagram of a signal processing circuit.

FIG. 21 is a schematic diagram of a signal processing circuit.

FIG. 22 is a schematic diagram of a signal processing circuit,

FIG. 23 is a schematic diagram of a signal processing circuit with a switched capacitor bank.

FIG. 24a is a Bode plot of NRC for a digital resonator with a frequency five percent higher than an RF resonator frequency.

FIG. 24b is a Bode plot of NRC for a digital resonator with a frequency that is the same as the RF resonator frequency.

FIG. 24c is a Bode plot of NRC for a digital resonator with a frequency five percent lower than an RF resonator frequency.

FIG. 25 is a schematic diagram showing a cascade of two transfer functions.

FIG. 26 is a schematic diagram of a multi-loop signal processing circuit.

FIG. 27 is a plot of multi-loop signal processing circuit versus clock cycles.

FIG. 28 is a schematic diagram of a state-space model of a single pole resonator as a pair of integrators.

FIG. 29 is a schematic diagram of a state-space single pole model revised to change the order of the processing.

FIG. 30 is a Simulink model of a single pole Q enhanced resonator.

FIG. 31 is a plot of a simulation output of the model of FIG. 30 with the input being the smaller signal and the output being the larger signal.

FIG. 32 is a Simulink model of a Q enhanced resonator in discrete time sampled form.

FIG. 33 is a plot of a simulation output of the model of FIG. 32 with the input smooth signal and the quantized multi-loop processing output.

FIG. 34 is a schematic diagram of a multi-loop processing circuit with variable delay in the feedback path.

FIG. 35 is a plot showing the difference in frequency response for an inner loop signal processing circuit with a time delay versus normalized frequency for |1/G|<1

FIG. 36 is a Simulink model of a multi-loop signal processing circuit with variable time delay.

FIG. 37 is a plot of a simulation output of the model of FIG. 36 subject to a sinusoidal input.

FIG. 38 is a Simulink model of a multi-loop signal processing circuit for loop analysis.

FIG. 39 is a Bode plot comparing continuous and discrete response.

FIG. 40 is a Simulink model of a multi-loop signal processing circuit with a bandpass phase shifter.

FIG. 41 is a plot of a simulation output of the multi-loop model of FIG. 40 subject to a sinusoidal signal input.

FIG. 42 is a Simulink model of a single pole, continuous time multi-loop signal processing circuit.

FIG. 43 is a plot of the open loop Nyquist resonator curve (NRC) of the model of FIG. 42.

FIG. 44 is a Simulink model of a two pole continuous time multi-loop signal processing circuit.

FIG. 45 is a plot of the Nyquist resonator curve of the model of FIG. 44.

FIG. 46 is a schematic diagram of a signal processing circuit with resonators that have a fixed capacitor value.

FIG. 47 is a plot of the normalized frequency response of a signal processing circuit.

FIG. 48 is a plot of the normalized frequency response of a signal processing circuit before and after DPLP processing.

FIG. 49 is a plot of a section of an NRC for the region around the resonance point.

FIG. 50 is a plot of an example of NRC optimized for a relatively flat passband over the desired bandwidth around the closed loop resonance frequency.

FIG. 51 is a plot of simulated NRC for a two pole resonator and optimized feedback DSP to provide a flat passband response around the closed loop resonance frequency.

FIG. 52a is a signal processing circuit with analog processing.

FIG. 52b is a signal processing circuit with DSP state space processing.

FIG. 53 is a Simulink model of a signal processing circuit.

FIG. 54 is a Simulink model of a signal processing circuit.

FIG. 55 is a plot of a simulation output of the model of FIG. 54.

FIG. 56 is a signal processing circuit configured for down and up conversion.

FIG. 57 is a signal processing circuit with a notch filter.

FIG. 58 is a signal processing circuit with a notch filter and baseband processing.

FIG. 59 is a plot of a frequency response of a commercial variable filter.

FIG. 60 is a plot of a NRC of the commercial variable filter of FIG. 59.

FIG. 61 is a plot of a NRC of a commercial variable filter.

FIG. 62 is a plot of the frequency response of a tunable bandpass filter.

FIG. 63 is a plot of the frequency response of STF and QNTF.

FIG. 64 is a signal processing circuit with a SAW filter.

FIG. 65 is a signal processing circuit with multiple SAWs.

FIG. 66 is a plot showing the tunable bandpass filter delta sigma zero and pole.

FIG. 67 is a plot showing the frequency response of a TSMC SAW filter.

FIG. 68 is a plot showing the NRC of the TSMC SAW filter.

FIG. 69a is a plot of the NRC with G=0.5.

FIG. 69b is a plot of the NRC with G=0.7.

FIG. 69c is a plot of the NRC with G=0.9.

FIG. 70 is a plot of the NRC for a Q-enhanced SAW with G=9 at 1.75 GHz.

FIG. 71 is a plot of the frequency response for the Q-enhanced SAW at 1.75 GHz.

FIG. 72 is a plot of the frequency response of the NTF and the STF for the complex negative feedback loop gain of Go=1j.

FIG. 73 is a plot of the frequency response of the NTF and the STF for the complex negative feedback loop gain of Go=2j.

FIG. 74 is a plot of the frequency response of the NTF and the STF for the complex negative feedback loop gain of Go=4j.

FIG. 75 is a plot of the NRC for the SAW Q enhanced at 1.75 GHz with inner loop signal reinforcement G=0.93.

FIG. 76 Frequency response of the NTF and the STF for the outer loop complex negative feedback loop gain of Go=4j and an inner loop signal strengthening G=0.93.

FIG. 77 is a schematic diagram of general direct scanning receiver processing.

FIG. 78a is a schematic diagram of a receiver.

FIG. 78b is a schematic diagram of a receiver with a bandpass filter.

FIG. 79 is a schematic diagram of a circuit with two inner loops.

FIG. 80 is a schematic diagram of a circuit with two inner loops and negative feedback.

FIG. 81 is a schematic diagram of a circuit with two inner loops and negative feedback.

FIG. 82 is a schematic diagram of a circuit with N inner loops.

FIG. 83 is a schematic diagram of a signal processing circuit.

FIG. 84 is a schematic diagram of a signal processing circuit showing the insertion of quantization noise.

FIG. 85 is a schematic diagram of a signal processing circuit showing the insertion of processing noise.

FIG. 86 is a schematic diagram of a signal processing circuit with output processing and feedback processing.

FIG. 87 is a schematic diagram of a cascaded integrator comb low pass filter and decimation.

FIG. 88 is a schematic diagram of a rudimentary transceiver anti-aliasing design.

FIG. 89 is a schematic diagram of a receive side circuit.

FIG. 90a is a plot showing noise and desired signal.

FIG. 90b is a plot showing folded bands with and without the filter.

FIG. 91 is a schematic diagram of a circuit with analog down conversion.

FIG. 92 is a schematic diagram of a BPSK receiver with a single bit comparator.

FIG. 93 is a schematic diagram of a high speed flash converter.

FIG. 94 is a schematic diagram of a sample and hold circuit.

FIG. 95 is a plot of the Manchester code.

FIG. 96 is a schematic diagram of a signal processing circuit.

FIG. 97 is a schematic diagram of a signal processing circuit.

FIG. 98 is a plot showing the pole of a signal processing circuit.

FIG. 99 is a Simulink model of a signal processing circuit.

FIG. 100 is a plot of the simulation results of the Simulink model of FIG. 99.

FIG. 101 is a plot of the simulation results of the Simulink model of FIG. 99 with different values.

FIG. 102 is a Simulink model of a signal processing circuit.

FIG. 103 is a plot of the simulation results of the Simulink model of FIG. 102.

FIG. 104 is a schematic diagram of a signal processing circuit.

FIG. 105a is a schematic diagram of a signal processing circuit.

FIG. 105b is a Simulink model of the signal processing circuit of FIG. 105a.

FIG. 106 is a plot of the simulation results of the Simulink model of FIG. 105b.

FIG. 107 is a schematic diagram of a signal processing circuit.

FIG. 108 is a schematic diagram of a signal processing circuit.

FIG. 109 is a schematic diagram of a signal processing circuit.

FIG. 110 is a schematic diagram of a signal processing circuit.

FIG. 111 is a schematic diagram of a first order delta sigma loop.

FIG. 112 is a Simulink model of a signal processing circuit.

FIG. 113 is a plot of the simulation results of the Simulink model of FIG. 112.

FIG. 114 is a Simulink model of a signal processing circuit.

FIG. 115 is a plot of the simulation results of the Simulink model of FIG. 114.

FIG. 116 is a schematic diagram of a signal processing circuit with a second order negative feedback loop.

FIG. 117 is a schematic diagram of an equivalent baseband model of the signal processing circuit of FIG. 116.

FIG. 118 is plot of the locus of closed loop poles.

FIG. 119a is a schematic diagram of a signal processing circuit.

FIG. 119b is a Simulink model of the signal processing circuit of FIG. 119a.

FIG. 120 is a plot of the simulation results of the Simulink model of FIG. 119b.

FIG. 121 is a plot of the spectrum of the inter-modulated output of the VBP-DSM with signal and interference added to quantization noise floor.

FIG. 122 is a Simulink model of a signal processing circuit.

FIG. 123 is a plot of the simulation results of the Simulink model of FIG. 122.

FIG. 124 is a Simulink model of a signal processing circuit.

FIG. 125 is a plot of the simulation results of the Simulink model of FIG. 124.

FIG. 126 is a plot of the simulation results of the Simulink model of FIG. 124 with different values.

FIG. 127 is a schematic diagram of a signal processing circuit with taps.

FIG. 128 is a schematic diagram of a signal processing circuit as part of an SDR.

FIG. 129 is a schematic diagram of a signal processing circuit as part of an SDR.

FIG. 130 is a schematic diagram of a signal processing circuit with two processing paths.

FIG. 131 is a schematic diagram of a signal processing circuit with multiple processing paths.

FIG. 132 is a plot of the noise transfer functions of different levels of negative feedback against the signal transfer function.

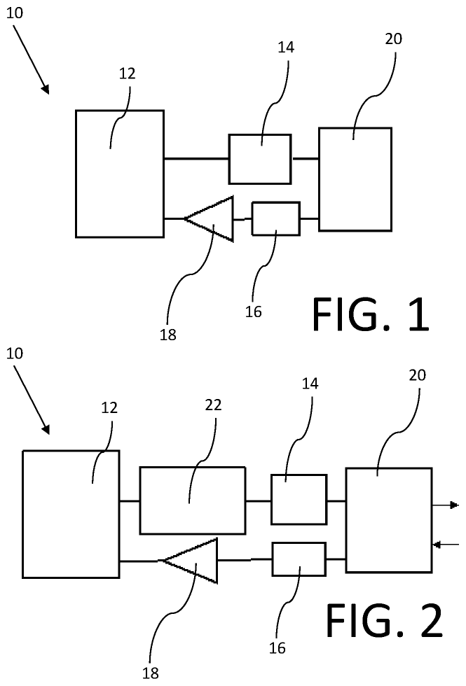

### DETAILED DESCRIPTION OF PREFERRED EMBODIMENTS

A signal processing circuit, generally identified by reference numeral 30, will now be described with reference to the drawings.

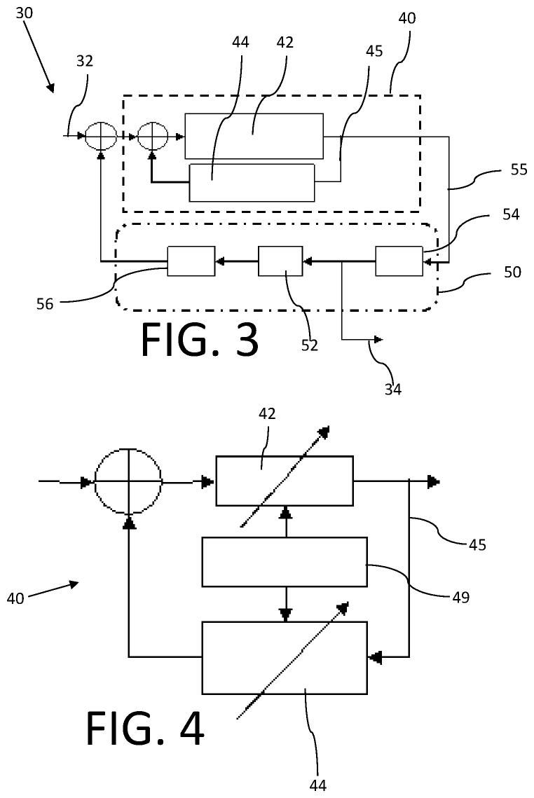

Referring to FIG. 3, signal processing circuit 30 has an input 32 and an output 34 and has a parallel mixed signal processing loop architecture that simultaneously utilizes an inner loop 40 and an outer loop 50.

Inner loop 40, which may also be referred to herein as an upstream loop, with an upstream processing block 42 that has a frequency dependence, and an inner feedback path 45 that extends around upstream processing block 42. In many practical implementations, upstream processing block 42 may be a resonator or bandpass filter. Other components that have a frequency dependence may also be used, which, in combination with feedback path 45, produce a passband. Bandpass filter 42 may be a continuous time tunable RF bandpass filter that enables independent tuning of the filter center frequency and/or the filter bandwidth using Q control. Inner loop 40 may have a positive feedback variable gain block 44 on inner feedback path 45 that reinforces the input signal as an active feedback filter (AFF). The various components in inner loop 40, such as processing block 42 and variable gain block 44, may be variable or tunable to control the output of inner loop 40.

Outer loop 50 has a second, or downstream, signal processing block 54 and an outer feedback path 55 that extends from downstream of the inner loop 40 to upstream of processing block 42. In one example, signal processing may be conducted by a discrete time digital signal processing (DSP) block 52 that may involve domain transfers (ADC 54 and DAC 56). Outer loop 50 also incorporates inner processing block 42 as one leg of outer loop 50. There may be more than two outer loops 50, but the loops are in parallel with inner loop 40, each of the possible multiple outer loops 50 sharing the same inner loop tunable RF bandpass filter 42. Outer loop 50 may include a gain block (not shown).

In some cases, the dual loop architecture, which may be referred to as dual parallel loop processing (DPLP), may be used to suppress internally-generated noise. In this example, inner loop 40 may be a positive feedback loop that reinforces the signal within a desired passband, while outer loop 50 may be a negative feedback loop that is conditioned to negatively interfere with internally-generated noise in the passband. In other examples, the DPLP architecture may be designed with and without a gain block in the outer loop. Signal processing circuit 30 may have a top-level architecture providing a digitized signal output 34, shown in FIG. 3. This output signal may be subject to further processing. It will also be understood that the signal processing circuit 30 may have more than two loops, either upstream loops or downstream loops, and which may be in parallel or in series. As such while the terms dual loop or DPSP may be used, possible designs may include more than two loops, provided that the loops include an inner (or upstream) loop and an outer (or downstream) loop.

The dual loop architecture 30 may be a parallel combination of mixed signal processing that may combine both analog RF processing and digital RF processing. The depicted example includes a digitized signal output 34. In some examples, this mixed signal, dual parallel loop processing (DPLP) may be implemented into the front-end module (FEM) of a wireless communication architecture, and may be used in a software defined radio (SDR).

The function of inner loop 40 will be considered first, after which the function of outer loop 50 will be considered, both with and without a gain block in outer loop 50.

### Inner Loop Processing

While various filter designs may be used in inner loop 40, to maintain simplicity in this description, only the arrangement of inner loop 40 shown in FIG. 4 will be considered herein. It will be understood that, in general, inner loop 40 has a bandpass filter 42 and a feedback path 45 that has inner feedback path processing block 44, which may be a variable gain block. It will be understood that inner feedback path 45 of inner loop 40 shown in FIG. 4 may be incorporated as part of a resonator element, such as an active feedback filter, or feedback path 45 may be separate or distinct from processing block 42, such as if the processing block 42 is a different design that does not include a feedback path as an inherent component.

In some examples, processing block 42 may be a resonator, such as a tunable bandpass filter (BPF), which typically relies on resonator processing control to refine the frequency selectivity of the filter when processing a signal. Generally, the processing relates to the ability to adjust the center frequency and the bandpass region. Also, in general, to control the bandwidth of the signal processing, active feedback in the form of a feedback gain element has been widely used to provide this bandwidth control in a method called Q-enhancement.

As will be understood, methods involving bandwidth control generally refer to the movement of the resonator pole or poles in the s-plane, which are a point of focus in design analysis. As will be recognized, a resonator may have more than a single pole.

By way of example, the context of the discussion herein will be this more complex active feedback resonator signal processing. While the discussion focuses primarily on this active feedback filter (AFF) in signal processing, other tunable filters may also be used, such as those that do not have active feedback, or other types of processing blocks alone or in combination with a resonator.

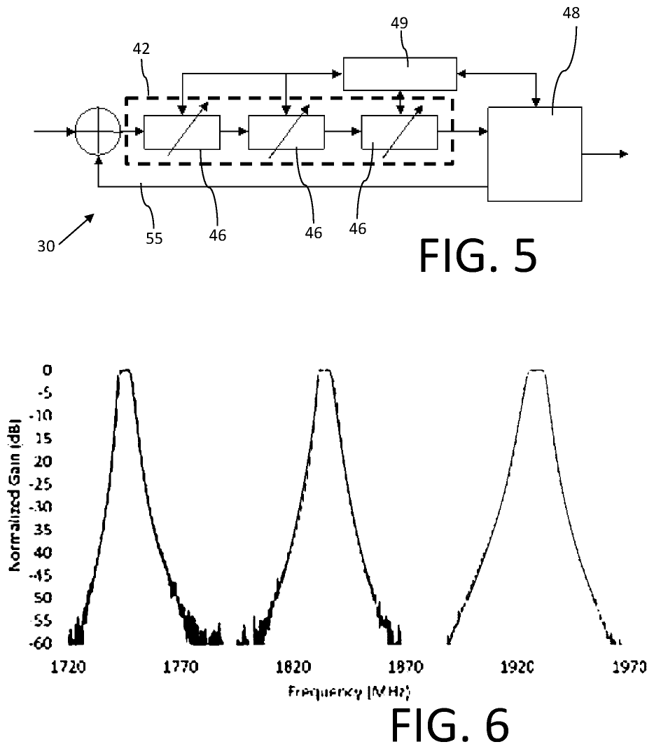

Referring to FIG. 4, processing block 42 is a continuous-time, tunable bandpass resonator network 42 with an inner feedback processing block 44 in feedback path 45. A control block 49 may be used to control bandpass network 42 and feedback processing block 44. Referring to FIG. 5, tunable resonator network 42 may include a number of tunable resonators 46, which may be an LC combination, although other resonator types are possible. Resonators 46 in processing block 42 may also be a packaged tunable resonator, such as resonator modules and SAW/BAW components. While not shown, each resonator 46 may include a feedback path and gain block, or there may be a feedback path around resonator network 42.

Referring again to FIG. 4, a relatively simple form of feedback processing element is shown as a gain block 44 that applies a scaling factor. By setting this scaling factor, the dominant resonator pole may be moved toward the jω axis of the s-plane (Q enhancement), or away from the jω axis (Q spoiling). With a variable feedback gain, the level of Q enhancement or Q spoiling may be controlled. Also, by making the resonator poles variable, the frequency of the Q-modified poles may be tuned. The characteristics of inner loop 40 and its controls may be modified by using one or more filter sections.

In one example, bandpass filter 42 may be an active positive feedback filter (PFF) within the signal loop 40 that both 1) tunes the center passband frequency, and 2) allows for Q enhancement or Q spoiling of a resonator. The Q control is sufficient to allow for the realization of narrowband radio frequency, microwave, and RF millimeter wave (RFMM) bandpass filters. This may be used with resonators 46 in a network as discussed above with respect to FIG. 5. Alternatively, there may be a plurality of signal loops 40 with individual resonators 42 or resonator networks. A further signal loop may also be incorporated around the plurality of signal loops. This versatility enables robust and stable operation and practical circuit implementation for moderate to high levels of Q enhancement. One implementation may include multiple filter sections cascaded as a series topology resulting in an all pole filter, and zeros at DC, but there are possible applications for both parallel and series connections of filter sections.

### Variants of Positive Feedback Filter

Relevant variants of the PFF of FIG. 4 include:
1. As a resonator network, bandpass filter 42 may contain more than one pole and that one or more of these poles may be Q-enhanced (moved toward the jω axis), or Q-spoiled (moved away from the jω axis).
2. Feedback processing 44 may contain phase adjustments. These phase adjustments may be fixed or variable.
3. The components may be re-ordered in loop 40.
4. Input and output ports may be at different points in loop 40.

Referring to FIG. 5, the active feedback may cause the pole(s) of resonator 42 to shift in position in the complex s-plane. Other filter architectures may include multiple network resonators 46 within bandpass filter 42, where each network resonator 46 may have a different pole(s) from other resonators 46 in the architecture.

When more than one pole exists in the s-plane, there may be a dominant pole that is nominally located at the center of the pass band. Other poles tend to be less significant, nonetheless important, in determining the response of the resulting bandpass filter. Herein, when a single pole is referenced in a resonator network 46 response, it is the dominant pole that is being addressed.

Next consider a resonator that contains P>1 poles, with P=3 shown in FIG. 5. Three variable filters 46 may be cascaded to implement the third order Chebyshev tunable bandpass filter response shown in FIG. 6. In this example, the center frequency is successively adjusted to 1745, 1825, and 1930 MHz. Each variable filter 46 realizes a pole of the multipole Chebyshev filter, with the Q of the individual filters in excess of 1000. Such a filter 42 may be designed to be stable with simple and robust tuning and calibration.

### Timing Jitter and Signal Sampling

The minimum sampling rate that may be had using the multi-pole bandpass filter 42 will now considered. Consider a data communications signal that is composed of a sequence of contiguous symbols. Parameters of these symbols (eg. amplitude or phase) contain the data bits or information. In theory, if an analog filter is provided that is ‘matched’ to the communications signal in terms of the symbol shape and the Nyquist condition for ‘zero inter symbol interference’ (ISI), then only one sample is needed per symbol. Other components may be incorporated, such as fixed frequency up and down conversion may be used that reduces the sampling rate required.

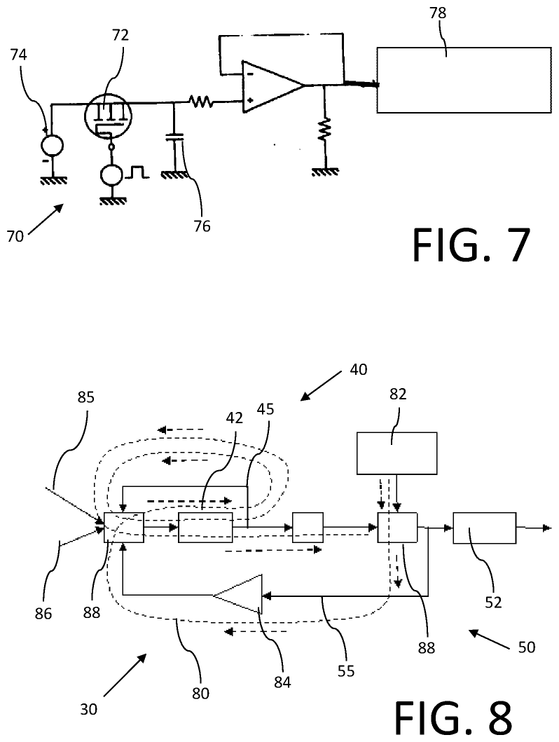

To have the reduced ADC, and subsequently reduced DSP requirements, sampling rate is a key consideration in that it is necessary that the ADC have an aperture time that is small in comparison with the period of the highest frequency component to be digitized. Referring to FIG. 7, a generic sample and hold circuit 70. Sample and hold circuit 70 has a FET gate 72 that is used as a switch that connects the input signal 74 to a capacitor 76 which charges to a level approaching that of a calibrated fraction of the signal amplitude. The current of capacitor 76 is of significance and the input signal driver 74 may have low source impedance. The switch 72 then opens and the capacitor voltage is buffered and becomes available for ADC 78, which can take a longer time to complete the conversion. The difficultly is in making the switch fast enough and having the input signal with a sufficiently low impedance that can drive the current of capacitor 76. For GHz signals, an aperture time may be required on the order of tens of psec.

An additional problem is the nonlinearity of FET gate 72 in that the channel resistance depends on the input signal voltage and the capacitor 76 voltage. Further, the timing jitter of FET gate 72 is of significance. The gate comes from a clock synthesizer with an output emerging from logic gates. The timing jitter of dt will add an uncertainty of (dv/dt)dt to the eventual sample, where dv/dt is the slope of the incoming voltage. This results in a sample uncertainty that is related to the signal through the slope of the signal which is noisy. Hence jitter related noise may be mitigated by a low phase noise clock synthesizer and high current logic, which is a dissipation issue. Jitter may be reduced with DSP if the sampling is highly redundant such that the sampling rate far exceeds the Nyquist rate commensurate with the signal bandwidth. If the sample redundancy is not significant, then DSP may be incapable of improving on the noise resulting from timing jitter.

The smaller the aperture time of the SH, the fewer electrons related to the signal make it into the capacitor. Space charge in the FET channel of the switch is an additional source of electrons that contribute to the capacitor charge depending on the drain and source voltages during the aperture time which contributes to switching noise.

### Mixed Signal Outer Parallel Loop Signal Processing

This section will cover complex concepts involving signal processing loops incorporating both real time and digital time processing. It will be shown that, among other features, the dual loop processing concept reduces or eliminates self-generated noise from the processing, such as quantization noise. These concepts are illustrated in FIG. 8, which depicts the flow of the signal path 80 through the dual loops of signal processing circuit 30. However, the signal enhancing loop (inner loop 40) is real time while the processing noise loop (outer loop 50) is in discrete digital time which is difficult to mentally encapsulate. In the example shown in FIG. 8, processing noise 82 passes through negative gain block 84 before being processed in bandpass filter 42. A desired signal 85 and interference and noise 86 enter the circuit at a sum block 88, as does processing noise 82 at another sum block 88. The signal may flow through the signal enhancing loop many times before emerging and combining destructively with the processing noise. When the initial processing noise and the recirculated processing noise cancel, there is no further output of processing noise to the signal.

### Inner Loop Nyquist Resonator Curve Shaping

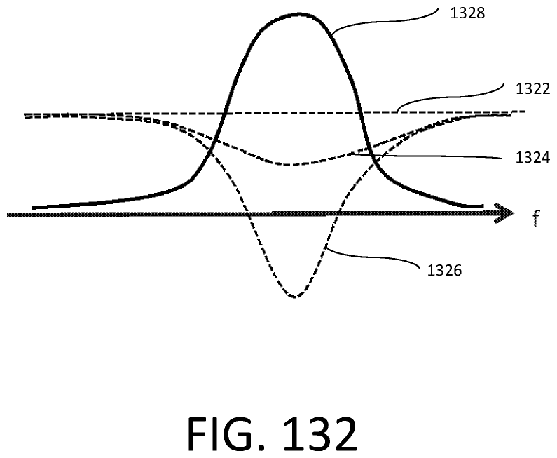

Inner loop 40 has been discussed above, dealing primarily with the benefits to be achieved by the positive feedback filter architecture. However, there is another purpose of the positive feedback loop and that is to modify the Nyquist Resonator Curve (NRC) of the resonator in the upstream signal loop, which may be referred to as an upstream receiver. In this way the negative feedback gain of the outer loop can be set to higher negative gain values. This leads to the ability to suppress downstream receiver processing noise in a controllable way. An example the effect of the negative feedback in outer loop 50 is shown in FIG. 132, where line 1328 is the signal transfer function, line 1322 is the noise transfer function with no negative feedback, line 1324 is the noise transfer function with a small amount of negative feedback, and line 1326 is the noise transfer function with a higher amount of feedback.

The outer loop 50 with negative feedback leads to an effective reduction of the reinforcement of desired signal 85 in the inner loop 40 with positive feedback. Hence to compensate for this effective reduction in inner loop 40 gain from the negative outer loop 50 feedback gain, the positive feedback within inner loop 40 may be made stronger. In fact, the gain of inner loop 40 may be Gᵢₙₙₑᵣ>1 without loss of stability as the effective gain of inner loop 40 is reduced by the negative feedback gain Gₒᵤₜₑᵣ<0, leaving an effective G_{inner eff}<1 again.

The two loops therefore are interactive. For a specific case of a signal of given bandwidth, the net signal reinforcement is commensurate with the signal bandwidth. Inner loop 40 reinforcement may be strong enough to change the shape of the NRC of the upstream receiver such that sufficient negative feedback can be applied without risk of loop instability.

### Overview and Implications of Mixed Signal Dual Loop Processing

FIG. 9 shows the general two loop architecture 90 of signal processing circuit 30. In FIG. 9 through FIG. 13, the input signal is V(s)+I(s), block 92 corresponds to A(s) and represents the bandpass filter 42 of an upstream processing section 91 of the receiver, block 96 corresponds to B(s) and represents a downstream processing section 94 of the receiver, and Y(s) is the output of block 96. Upstream processing 91 relates to inner loop 40 described previously that is configured as an active positive feedback filter that serves to enhance the input signal as described above. Upstream processing 91 includes a positive processing gain of G₁ in gain block 93. Downstream processing 94 relates to the outer processing loop 50 described previously that may include a gain element, represented by gain block 97 with gain G₂. It should be noted that a gain element may be incorporated as part of a DSP despite being shown explicitly.

As used herein, s represents the complex frequency such that A(s) in block 92 represents the frequency response of the upstream inner loop filter processing. Between the upstream and downstream sections 91 and 94 is a tap point 98 shown for reference. Tap point 98 may be used as the notional input of any noise 99 that may be introduced by the downstream outer loop processing 94. Noise 99 is represented by Q(s).

The discussions of outer loop 50 above have noted that a gain element may or may not be present, although FIG. 9 includes a gain element 97 as shown such that the feedback path of outer loop 50 applies a processing gain of G₂ which could be positive or negative. In this implementation both the feedback loops terminate in a summing point at the input side of the upstream receiver. An input signal 95 is V(s)+I(s) wherein V(s) is considered to be a desired bandpass signal, and I(s) is the noise and interference within the bandwidth of the desired signal. An output 100 of the downstream receiver is the digitized signal content Y(s).

A(s) may be a number of different things.
A(s) may be a resonator of fixed or tunable frequency
A(s) may be a set of multiple resonators
A(s) may be a filter or any network that has some form of frequency dependence.
A(s) may be a delay line in which the frequency dependence is a phase shift that increases with frequency
A(s) may be a subsystem comprising a filter or/and a frequency translation stage or/and a gain block

B(s) includes a component for a domain transformation. A domain transformation may be, for example, an input continuous time signal transformed to an output that comprises digitized samples, such as by using an ADC B(s) may be a transformation in frequency such that the input to B(s) is different than the frequency at the output. Part of the processing in the feedback path of outer loop 50 may includes a domain transformation (not shown in FIG. 9) that is the inverse of the domain transformation implied within B(s). The additional signal of Q(s) is added to the signal flowing between the upstream and the downstream receiver sections at the tap point. This signal Q(s) is assumed to be independent of the input signals of V(s) and I(s) to a good approximation. It represents the equivalent noise of the processing in B(s) as injected at the input port of B(s).

Output 100 of the receiver, denoted as Y(s), is a frequency spectral representation. This is meant as a representation only as the output is likely a discrete time sampled signal. Also, as I(s) and Q(s) are random processes, then strictly speaking only the statistical properties of Y(s) are definable. Hence Y(s) should be understood as being a representation of the output which is convenient for discussion. It is not meant as a precise description of the output.

In one example, the processing in FIG. 9 may be used to ferry the desired signal of V(s) to the digitized output of Y(s) without degrading the information content of the detected desired signal. Put in more formal terms, the loss of mutual information between V(s) and Y(s) may be reduced or minimized while achieving the desired domain transformation of the signal in the downstream receiver. As an example, B(s) may include an ADC to quantize samples of the input signal. This would be the domain transformation.

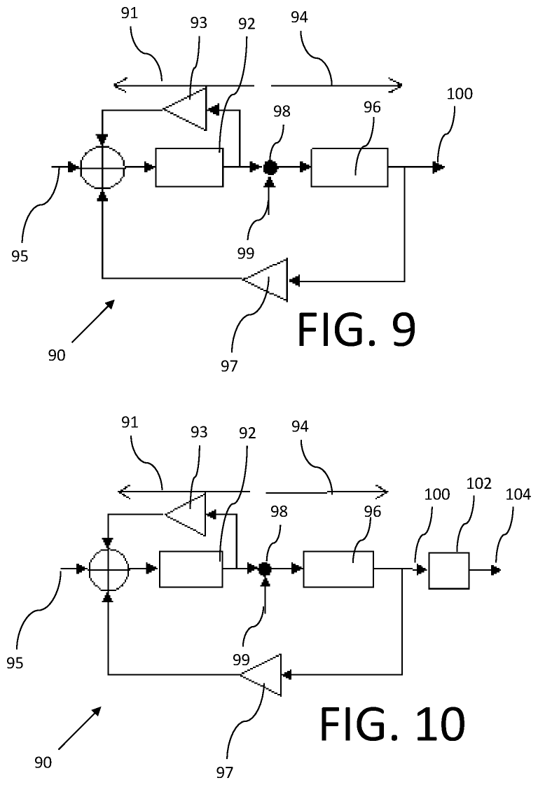

The output signal Y(s) therefore represents the domain transformed variant of the input signal V(s) that is accompanied by some residual noise. It is understood that additional post detection processing is required in order to retrieve and extract the relevant information from the digitized Y(s) data as contained in V(s). Therefore, a post detection processing block D is added as shown in FIG. 10. Here D denotes a post detection processing block 102 and I denotes extracted information 104. Post detection processing block 102 may be realized such that there is little or negligible loss of mutual information in the process from Y(s) to I.

It will be shown that the architecture of FIG. 10 may be implemented in the front end module of a receiver. The processing of D is outside of the scope of the disclosed invention. It is assumed that the processing of the front end receiver and domain transformation places the signal in a form that is compatible with processing that can be efficiently implemented in D. Summarizing, the upstream and downstream signal processing subsystems, in conjunction with the feedback paths, are implemented such that mutual information between the input desired signal of V(s) and transformed output Y(s), in the presence of the noise I(s), is optimized under the constraint that Y(s) is compatible with the implementation of D.

In an implementation of significance for a receiver, inner loop 40 is a positive feedback loop with a gain of G₁ and outer loop 50 with a negative feedback loop gain of G₂. The objective of the positive loop is to enhance the desired signal V(s) relative to the noise and interference of I(s) by narrowing the effective signal bandwidth through the upstream processing such that it is more compatible with the bandwidth of V(s). It shall be shown that the objective of the negative feedback loop around both the upstream and downstream receiver sections is to reduce the presence of the noise source of Q(s) in the output Y(s). The operation of this is evident if the transfer functions are considered.

The signal transfer function is defined as

$${H}_{STF} ( s ) = \frac{Y ( s )}{V ( s )}$$

when Q(s)=0. The “quantization noise” transfer function is defined as

$${H}_{QTF} ( s ) = \frac{Y ( s )}{Q ( s )}$$

when V(s)=0. The noise of the downstream receiver is referred to here as quantization noise as it typically is associated with a quantizer/sampler. However, it is not limited to quantization noise and may include any noise that can be approximated as being additive as described earlier.

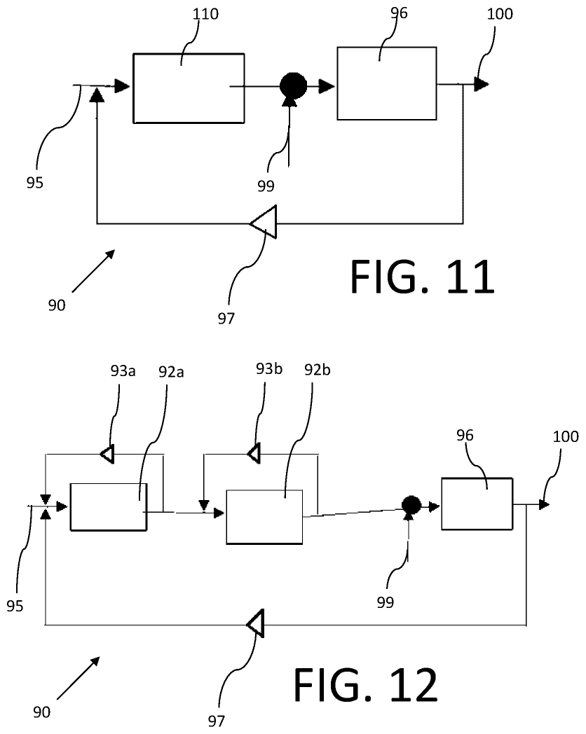

To simplify the calculation of the transfer functions the loop is reorganized as shown in FIG. 11, where block 110 is

$$Consequently , C = \frac{A}{1 - {g}_{1} A}$$

$$and {H}_{STF} ( s ) = \frac{BC}{1 + {g}_{2} BC}$$

$${H}_{QTF} ( s ) = \frac{B}{1 + {g}_{2} BC}$$

As an example, let A(s) represent a single pole of an equivalent complex bandpass. This is a valid approximation if the response of the front end receiver is of relatively narrow bandwidth. The simplification allows a closed form expression of the transfer functions to facilitate the present discussion. Therefore, the form of A(s) is

$$A ( s ) = \frac{p}{s + p}$$

where p is a positive real value. With this C(s), in block 110, becomes

$$C ( s ) = \frac{\frac{p}{s + p}}{1 - {g}_{1} \frac{p}{s + p}} = \frac{p}{s + p - {g}_{1} p} = \frac{p}{s + p ( 1 - {g}_{1} )}$$

Then C(s) is substituted back into the transfer functions, resulting in

$${H}_{STF} ( s ) = \frac{Bp}{s + p ( 1 - {g}_{1} ) + {g}_{2} pB}$$

$$and {H}_{QTF} ( s ) = \frac{B ( s + p ( 1 - {g}_{1} ) )}{s + p ( 1 - {g}_{1} ) + {g}_{2} pB}$$

The zero at s=p(1−g₁) appears in H_{QTF} but not in H_{STF}. Consequently, if V(s) is of narrow bandwidth with a bandwidth realistically comparable with p, then the first order noise cancellation is evident. This is the basis of the action of the feedback receiver of FIG. 9. The inner positive feedback loop reduces p such that the pole of A(s) is moved towards the jω axis (Q enhancement) and the bandwidth is narrowed such that it is compatible with the bandwidth of V(s). The larger G₁ is, the narrower the bandwidth. It may be seen, conversely, that the role of the negative feedback gain of the outer loop is to create the passband zero from this “Q enhanced” passband pole such that the equivalent noise generated by the downstream receiver is suppressed.

In summary, with the inner and outer feedback loops arranged in the manner shown in FIG. 9 are both required for the simultaneous processing of the input signal. The mutual information can be shown to be optimally preserved by the joint cooperation of the two feedback loops with optimum feedback values selected for G₁ and G₂.

It is evident that A(s) can be any processing function that has some dependence of frequency in the vicinity of the band center of the desired signal V(s). In this way positive feedback of the inner loop can be used to narrow the bandwidth of A(s). For example, A(s) could be any fixed or tunable bandpass filter as will be shown.

These expressions may be expanded on with an assumed transfer function of B(s). However, the point is that the insertion of the zero into H_{QTF} is the key feature.

The concept of the dual loop feedback may also be expanded to an architecture as shown in FIG. 12 with the upstream receiver comprising a plurality of bandpass filters in series each with a positive feedback loop for bandwidth narrowing. In FIG. 12, gain blocks 93a and 93b correspond to g1 and g2, respectively, and gain block 97 corresponds to g3.

Letting A1(s) and A2(s), corresponding to blocks 92a and 92b, respectively, be two first order bandpass filters given as complex bandpass equivalents as

$${A}_{1} ( s ) = \frac{{p}_{1}}{s + {p}_{1}}$$

$${A}_{2} ( s ) = \frac{{p}_{2}}{s + {p}_{2}}$$

Then it can be shown that the closed loop for H_{QTF}(S) will have two zeros corresponding to the q enhanced poles of p₁ and p₂.

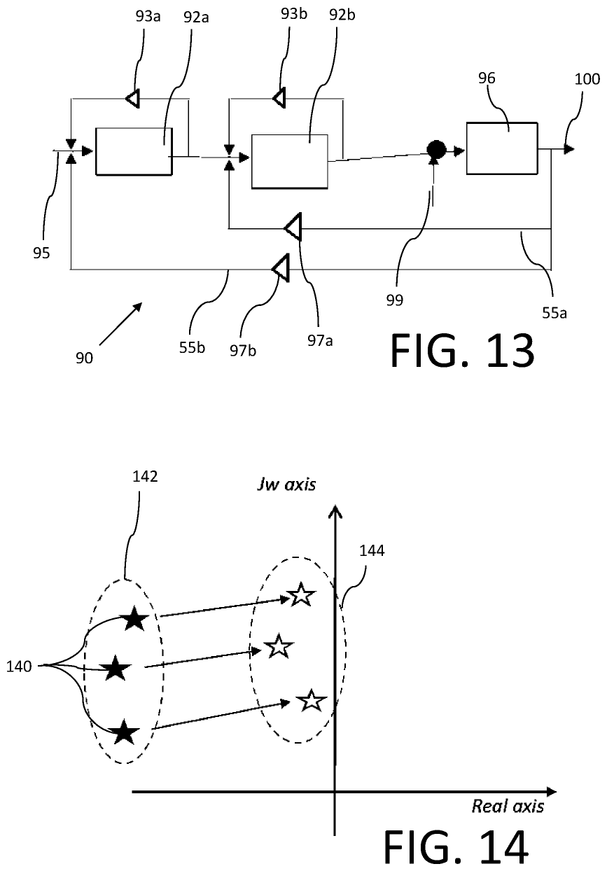

Referring to FIG. 13, further flexibility in the control of the zeros and the poles of the transfer functions of H_{QTF}(s) and H_{STF}(S) can be realized by adding additional negative feedback loops 55a and 55b. In FIG. 13, gain blocks 93a and 93b correspond to g1 and g2, respectively, and gain blocks 97a and 97b corresponds to g3 and g4, respectively.

The closed form expressions become more unwieldy. However, the general structure of positive and negative feedback paths can result in the general architecture with multiple zeros in the passband of H_{QTF}.

There are additional modifications that can be done for enhanced performance and flexibility of implementation. The gain blocks 97a and 97b of {g1, g2, . . . } in FIG. 13 can be augmented to include general processing blocks, as indicated above, as opposed to just scalar gain blocks. These can include domain transformations that are inverse to the transformations occurring in the downstream direction. For instance, the transformations can be signal digitization or frequency translation.

A further flexibility is that the outer loop negative feedback paths can be changed to positive feedback paths and then with processing applied to the feedback paths an arbitrary set of passband poles may be realized. In this way the passband frequency response can be arbitrarily shaped. Hence the resulting frequency response resulting from the upstream and downstream receivers along with the feedback paths can be spectrally shaped and sufficiently frequency selective such that no further post detection processing is required.

The generalized feedback transfer functions of {g1, g2, . . . } can be configured dynamically such that the receiver can respond optimally to a variety of disparate input signal formats and noise contributions. These feedback transfer functions of {g1, g2, . . . } can be implemented in a DSP processor or FPGA processor resulting in a very flexible form of a software definable radio.

### Generalized Feedback Loops in RF Signal Domain and Control Processing

The feedback processing presented herein may be used to control the position of P poles 140 on an individual pole-by-pole basis as shown in FIG. 14. Note that resonator poles may be moved along the real axis changing Q, and/or along the jω axis changing frequency. P poles 140 may be moved from an initial closed loop position 142 to a final closed loop position 144. With this, P poles 140 of the resonator may be placed to provide an arbitrary bandpass transfer function response. This is desired for implementing a passband filter of specified passband characteristics and out of band rejection. As the active feedback affects all P poles 140 in a desired way, a generalized dual parallel loop processing (DPLP) may result.

As will be understood based on the discussion here, it may be possible with feedback processing to simultaneously place each of the resonator poles individually in the s-plane, individually controlling both the bandwidth of the resonator (pole movement parallel to the horizontal axis) and the resonator frequency (pole movement parallel to the vertical axis).

There will now be considered the feedback processing of the active feedback filter (AFF) which may be used to achieve an active multi-pole placement AFF. Generalized control theory concepts will be introduced, applied to the feedback processing functions with control made possible in different processing domains that may characterize an observable, such as frequency or phase, out of the resonator. The signal in the AFF loop is in the RF analog domain. The resonator output will be referred to as an RF analog signal also with domain A.

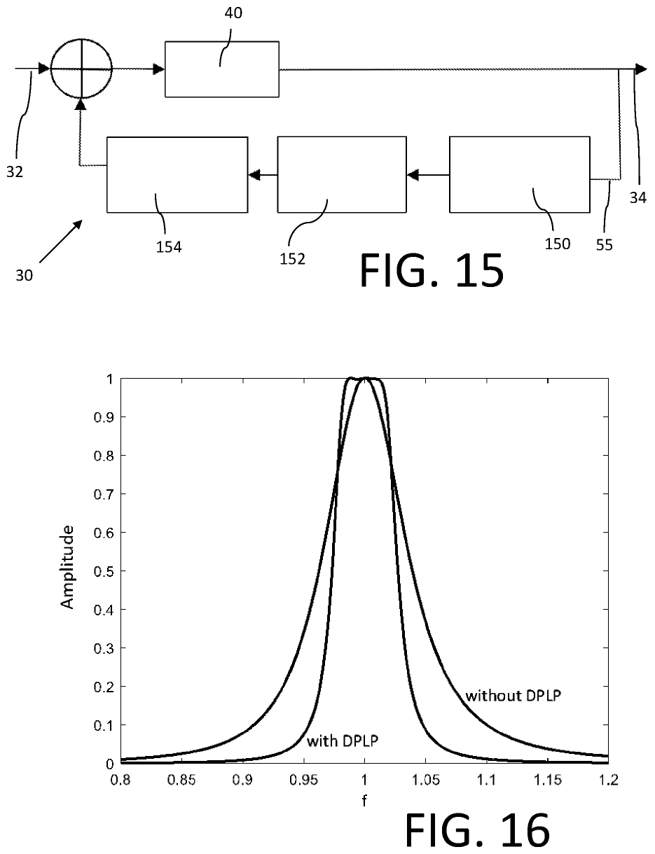

A characteristic of signal processing circuit 30 (or DPLP) may include the state space domain transformation within the feedback loop as shown FIG. 15. Input signal 32, inner loop 40 and output signal 34 will be considered in domain A. Within the outer loop 50 there may be a transformation to another domain B in first transformation block 150 with feedback processing 152 in domain B followed by a transformation back to domain A in second transformation block 154.

As shall be shown in detail below, the result of a DPLP enabled three pole resonator, may be used to provide significantly increased bandwidth as shown in FIG. 16.

In the DPLP, the domain A may be RF analog. Domain B may be different than domain A, of which there are several possibilities, including but not limited to:
RF analog domain B at a different frequency than domain A
Low frequency baseband analog domain
Discrete time sampled domain (analog discrete time samples of signal)
Digital domain (digitized discrete time samples of signal)

An advantage of this domain transformation may be that the feedback processing in a different domain than that of the RF signal domain A is often simpler and more practical to implement. For instance, if domain B is digital, then the feedback processing may be implemented in digital signal processing (DSP) 52. Complex processing functions may be readily implemented in DSP that are not practical to implement in analog RF.

A typical application of the AFF may include narrow bandwidth filtering of a wireless signal intercepted by the antenna prior to down conversion and digitization. Interference and noise outside of the desired signal bandwidth may swamp the desired signal such that the desired signal may be irreversibly corrupted in the down conversion and digitization process. Hence a bandpass filter commensurate with the desired signal bandwidth is necessary to suppress this interference and noise. With the DPLP, more complexity in the feedback signal may be robustly implemented.

Additionally, DPLP may tolerate the large signal amplitudes that may be present in filters of high Q poles as the pole energy storage becomes large. This allows for feedback synthesis to be based on multi-dimensional state-space processing. As will be developed, this allows for the plurality of resonator poles to be simultaneously Q enhanced and arbitrarily placed in the s-plane with a single feedback loop. Thus, complex tunable multi-pole bandpass filter responses may be synthesized.

As noted previously, while the discussion herein is in terms of a dual loop architecture, this is for convenience as there may be a plurality of observations emanating from the resonator which are linearly independent, and which may be simultaneously transformed in parallel into a plurality of domains and acted on by a plurality of feedback domain processors, which may be referred to as multiple parallel loop processing (MPLP). It will be understood that, where a DPLP is described and depicted for ease of understanding, the principles may also be incorporated into an MPLP architecture. These pluralities of linearly independent signals, produced by the plurality of parallel feedback processing paths, may be simultaneously fed back into the resonator after transformation back into domain A. For example, low Q requires a low latency in the DSP which may not always possible. However low latency may be achieved in an analog domain.

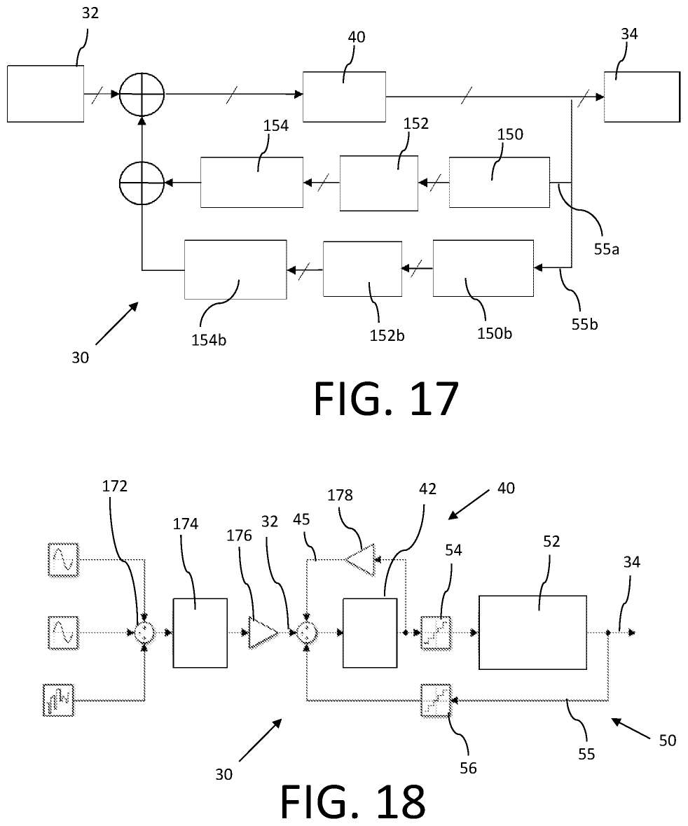

An example of MPLP is illustrated in FIG. 17, which depicts multiple parallel feedback processing paths 55a and 55b. In this example, feedback processing path 170a is similar to that of FIG. 15 and feedback processing path 170b:
Each independent processing path is fed with state information Nj following inner loop 40 in state space domain A;
State information is transformed to domain j in third transformation block 150b;
State information is processed in domain j in second feedback processing 152b;
Processed state information is transformed back to domain A in fourth transformation block 154b;
Post-processing state information in domain A is fed back to inner loop 40 input.

An example of signal processing circuit 30 of FIG. 17 is shown in FIG. 18, representing the processing of a radio processing block where the wireless signal is first received by an antenna 172, processed by an initial BPF 174, then amplified by an initial amplifier 176 and fed into a processing loop that includes inner feedback path 45 with an RF feedback gain 178 and bandpass filter 42 and outer feedback path 55 with an ADC 54, DAC 56, and DSP 52.

The RF feedback gain 178 is for latency mitigation and low Q-enhancement of the received input signal. The loop with DSP 52 is for both higher Q-enhancement and general signal processing for data extraction.

### Resonator and Processing Block

Referring to FIG. 3, in the discussion herein, signal processing circuit 30 may be generally described as having a resonator 42 (in inner loop 40) and a processing block 52 (in outer loop 50) in a dual parallel signal loop 30. As will be understood, the resonator 42 and the processing block 52 may be varied to achieve the desired results. For example, the resonator 42 may be any suitable resonator, such as single pole resonator, a multi-pole resonator, a SAW filer, a BAW filter, an active feedback filter (AFF), a fixed frequency filter, a variable frequency filter (either continuously variable or with discrete frequencies), etc. Alternatively, the resonator 42 may be a complex circuit with multiple resonant components, multiple feedback and/or feedback paths, etc. These design aspects will be apparent to those skilled in the art and will not be described further. The processing block 52 may be separate components, and may not be contained within a common housing, or even on a common substrate. It will be understood that a processing block 52 may be defined as including different components that act upon an output from the resonator 42. In some cases, a particular signal path within the DPLP may be defined as part of the resonator or as part of a processing block. This is primarily one of convenience in understanding and controlling the operation of the DPLP and does not change the operation of the DPLP or the effect of individual components or signal paths on the DPLP as a whole.

Resonator Pole Placement with the DPLP

Let P be the number of poles of the resonator (with positive complex natural mode frequencies). To set the P poles to arbitrary locations represents 2P constraints as each pole has a real and an imaginary component, and the feedback processing has a minimum of 2P degrees of freedom (DOF) when acting on the N inputs to produce the M outputs.

Furthermore, it is assumed that the resonator of P poles may be adjusted by externally setting the natural resonance frequency of the individual poles. Hence this is P DOF which implies that the feedback processing needs P additional DOF.

Regardless of the details of the feedback processor, it will require forming approximate derivatives and integrations of the N observables and the forming linear superpositions of sets of variables to form the M outputs. Such linear operations are trivial to provide if the domain B is DSP. However, if the domain B is analog processing at baseband or RF, then the implementation of linear analog operations quickly becomes unwieldy as P increases beyond P=1. Again, the domain transformation within the DPLP feedback loop between the domains of A and B allows for domain A to be RF and domain B to be DSP. The DSP allows for a practical implementation of the feedback processing such that the P poles may be placed arbitrarily and simultaneously.

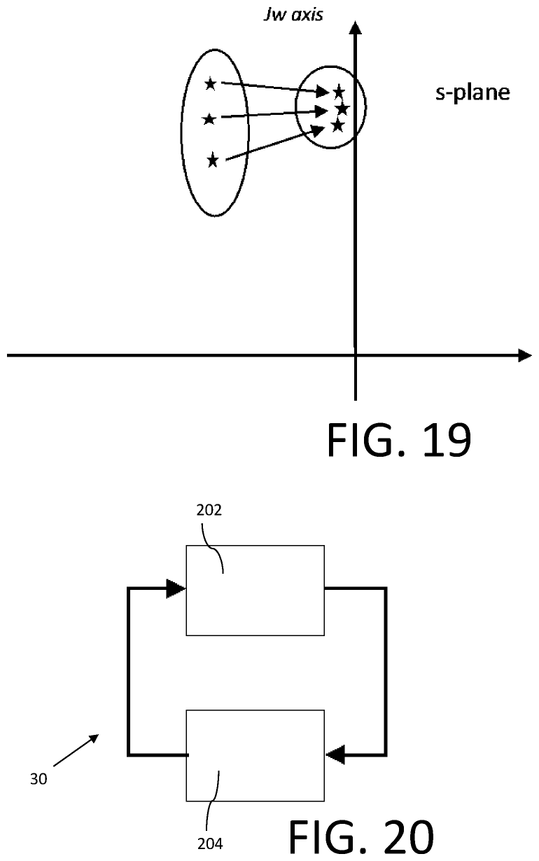

Based on this, there may be, for example, a multipole resonator with P=3 in the DPLP with the feedback processor computing the feedback signal that places these three poles as a Chebyshev bandpass filter of order 3. The Chebyshev poles may be placed close to the jω axis to provide a narrowband filter of high frequency selectivity as illustrated in FIG. 19.

### General DPLP Resonator Analysis Formalism

There will now be provided a discussion of an example analysis of signal processing circuit 30 (or DPLP), shown as a closed loop in FIG. 20.

A resonator has a transfer function in terms of poles and zeros that may be expressed as

$${H}_{res} ( s ) = \frac{N ( s )}{D ( s )}$$

where N(s) is a numerator polynomial in s (which is the complex frequency of continuous time). D(s) is denominator polynomial in s.

In DPLP, an active feedback filter (AFF) is added that has a transfer function of

$${H}_{fb} ( s ) = \frac{A ( s )}{B ( s )}$$

Where H_{fp}(s) may contain active gain elements. The closed loop is illustrated in FIG. 20, where block 202 corresponds to Hᵣₑₛ(s) and some or all of processing done in inner loop 40, and block 204 with transfer function H_{fp}(s) and some or all of processing done in outer loop 50.

The closed loop is given as

$${H}_{cl} ( s ) = \frac{{H}_{res} ( s ) {H}_{fb} ( s )}{1 - {H}_{res} ( s ) {H}_{fb} ( s )} = \frac{NA}{DB - NA}$$

The denominator polynomial (DB-NA) has roots which are the closed loop poles. By design of the feedback polynomials of A and B, the poles may be moved to wherever desired.

Hence the objective of DPLP is to solve for A and B such that the roots of

$$DB - NA = 0$$

are at the desired s-plane locations.

It happens that the implementation of

$${H}_{fb} ( s ) = \frac{A ( s )}{B ( s )}$$

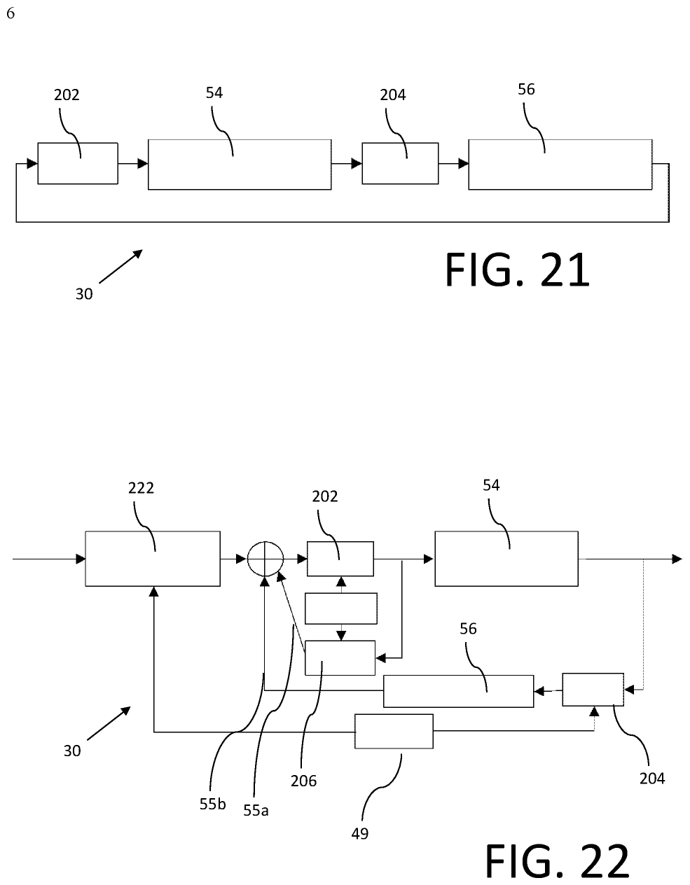

is not easily done in continuous time RF space. However, a domain transformation to discrete time space (generally from RF to digital) may be implemented to achieve an equivalent version of the continuous time H_{fb} (s) in the discrete time H_{fb} (z), where the coefficients A and B may be easily changed for different tuning as it is a digital implementation. This process is shown in FIG. 21, where ADC 54 and DAC 56 are shown in the closed loop, and represent continuous and discrete time domain transformations. Other domain transformations may also be used, as described herein.

Given Hᵣₑₛ(s) the feedback transfer function of H_{fb}(z) may be determined such that the desired closed loop passband response is obtained.

Referring to the DPLP block diagram in FIG. 22, the front end has an antenna 222 that is a matching LNA bandpass filter and some form of variable gain that is set such that the SNR of the eventual output is optimized. That is a compromise between a) the quantization noise that ADC 54 generates, and b) the risk of saturation of ADC 54. Protecting ADC 54 from excess noise is the filter in the front end, which is wideband but may have limited tunability, and Hᵣₑₛ(s) which is tunable with a resonator LC value change. ADC may also be replaced with a standard delta-sigma, which is as an alternate way to move quantization noise out of the passband.

The DPLP 30 has two parallel feedback paths:
1. One feedback path 55a is a direct RF path H_{fbrf}(s) (represented by block 206) in continuous time for feedback that cannot tolerate delay.
2. A slower feedback path 55b is the H_{fb}(z) (represented by block 204) path that is then converted back to analog and loops through Hᵣₑₛ(s) (represented by block 202).

In this way some preliminary Q enhancement of the Hᵣₑₛ(s) block 202 is possible, providing additional mitigation against potential ADC block non-linearities.

### Continuous Frequency Transitions Using DPLP

Inner loop 40 may include a tunable resonator that has a varactor or a switched capacitor bank for resonance frequency tuning based on a resonant LC tank. However, a varactor of high Q-factor and linearity may be difficult to integrate into a chip circuit. There may also be issues with the bias tuning voltage which may be moderately high to minimize distortion effects. Consequently, one implementation for changing capacitance of the analog LC tank may be via switched capacitor banks 233. Other types of resonators with different considerations may be used.

The DPLP domain transformation provides the ability to accommodate a resonator that may only be tunable in discrete steps. An example is a resonator using switched capacitors for tuning.

A switched capacitor resonator with K switches provides 2^{K} discrete natural frequencies of the analog resonator using different combinations of switch positions. As an example, suppose there are capacitors with values of C, 2C, and 4C arranged in parallel with three switches. Then the capacitance values of the set {C, 2C, 3C, 4C, . . . 7C} may be realized by setting the three switches appropriately. A general problem with this switched capacitor resonator is that it does not allow for tuning of the frequency except for 8 discrete steps.

However, with the DPLP domain feedback processing 3, the pole of the switched capacitor resonator may be moved over a small range relative to the capacitor switch settings, but this may be sufficient so that the next switch setting may be used in the RF resonator, enabling continuous frequency changes slightly larger than the frequency band covered by each basic switched capacitor settings.

As will be shown, this may result in continuous frequency tuning over a large range with a continuous change in the DPLP feedback processing.

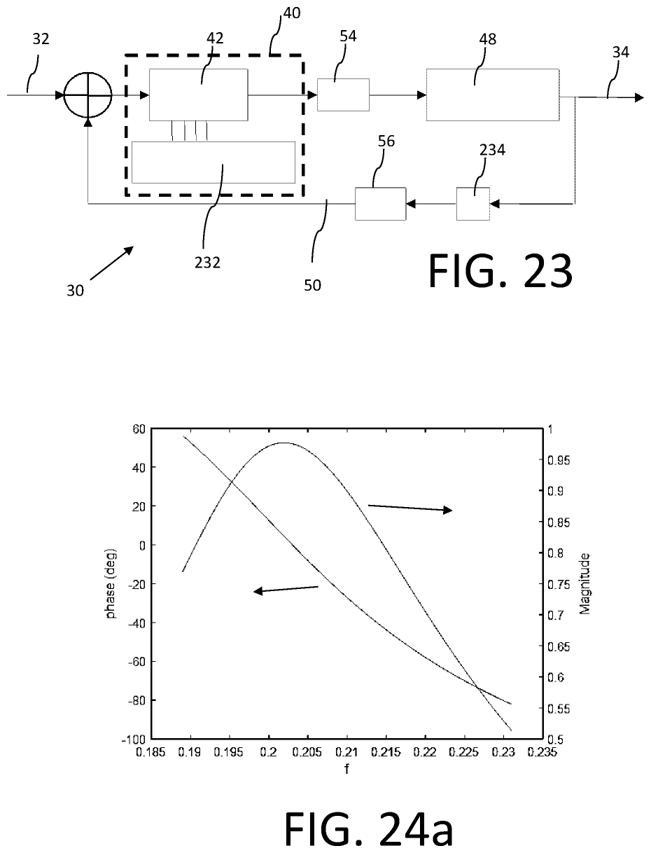

A digital resonator may be used as a phase shifter and shift the resonance frequency slightly, but this may be sufficient so that the next switch setting may be used in the RF resonator. An example of a block diagram of the analog resonator switched capacitor bank 232 with four capacitors and feedback processing 48 and gain block 234 is shown in FIG. 23.

One specific example of feedback processing is a digital resonator. While a digital resonator may be implemented in a variety of ways, the DPLP may provide a digital resonator within outer loop 50. In one example, the DPLP may use feedback processing with digital domain B to produce a feedback signal from the superposition of the state variables in such a way as to tune the DPLP pole continuously in frequency. This may be extended to a resonator consisting of P poles along with the K sets of switched capacitors.

This principle may be further generalized. Consider a resonator of a plurality of poles that has N different switch settings that may attach or detach a reactive component to the multipole resonator at different and arbitrary points in the resonator. There may be 2^{N} combinations of switches and therefore 2^{N} different arrangements of analog resonator pole positions. In principle, a feedback processor function may be determined for every requirement of DPLP pole positions from each of the 2^{N} resonator configurations. However, there may be a specific resonator configuration for which the feedback signal amplitude is minimal. This is the switch configuration that is selected for the desired output DPLP pole position pattern.

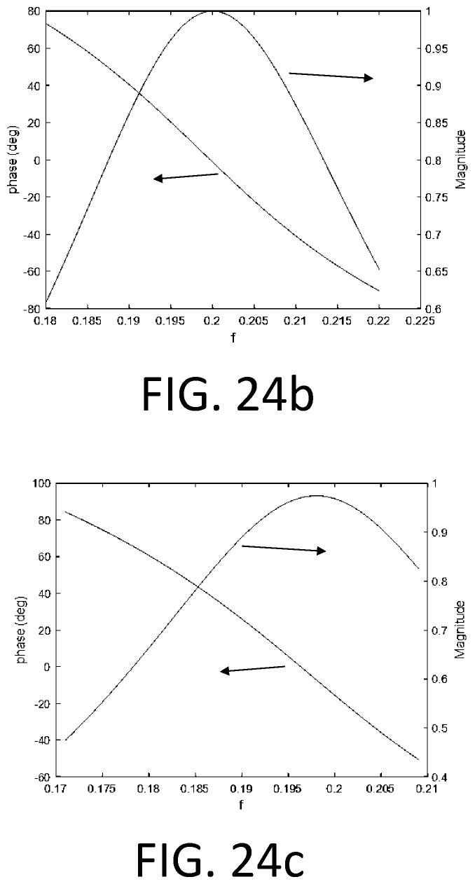

The open loop bode is plotted in FIG. 24a where the digital resonator frequency is five percent lower than the RF resonator frequency. In FIG. 24b the frequencies are the same, and in FIG. 24c the digital is five percent higher. In each case the RF resonator frequency is 0.2 rad/sec. Note that the zero phase crossing is where the DPLP center frequency will be at moderate Q enhancement levels.

The ten percent change in the digital resonator will cause the DPLP center frequency to change about 4 percent. Hence if there are 4 switched capacitors for 16 states, then this is about a 64 percent change in the DPLP tuning frequency.

Finally it may be noted that the amplitude dips slights when the digital resonator is detuned away from the RF resonator. It may be necessary to compensate this with a small increase in G to maintain the precise level of Q enhancement, an adjustment made by the DPLP.

### State-Space Formulation of DPLP Feedback Processing

This section will consider a state space formulation of the DPLP feedback processing of signal processing circuit 30 that will enable simultaneous placement of multiple poles. In the typical case the multi-pole resonator structure is implemented as a two-port subsystem with a single input and a single output (referred to herein as a Single Input Single Output (SISO) network. From the single output, the DPLP processing makes sufficient observations to form the single feedback to Q enhance or place multiple poles at a time. While the single feedback is in principle sufficient to move the multiple poles to desired locations, a practical implementation of the DPLP will allow for the resonators to be adjusted simultaneously. This reduces the amplitude of the feedback signal necessary. However, the resonator frequencies do not need to be tuned precisely or with high resolution. Hence switched capacitors may be used for the tunable resonator.

It is also possible to consider the general resonator with multiple input ports and multiple output ports or a Multiple Input Multiple Output (MIMO) network. However, as SISO works adequately for DPLP, there is little impetus for added complexity. However, MIMO should be considered for the DPLP in the most general form.

Consider the DPLP with N/2 resonators. Converting the resonator transfer function to the Z domain results in an Nth order transfer function as

$${H}_{res} ( z ) = \frac{{\sum }_{i = 0}^{N} {b}_{i} {z}^{- i}}{{\sum }_{j = 0}^{N} {a}_{j} {z}^{- j}}$$

The coefficient b₀ is zero as there is no through connection. Also aⱼ is always normalized to 1. The numerator and denominator are multiplied by z in preparation for the state space notation, giving

$${H}_{res} ( z ) = \frac{{\sum }_{i = 1}^{N} {b}_{i} {z}^{- i}}{1 + {\sum }_{j = 1}^{N} {a}_{j} {z}^{- j}} = \frac{{\sum }_{i = 1}^{N} {b}_{i} {z}^{- i + 1}}{z + {\sum }_{j = 1}^{N} {a}_{j} {z}^{- j + 1}}$$

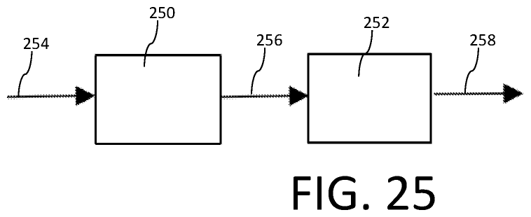

Next this may be considered as a cascade of two transfer functions as shown in FIG. 25 with block 250 corresponding to H_{A}(z), block 252 corresponding to H_{B}(z), input 254 corresponding to uₖ, transition 256 corresponding to yₖ, and output 258 corresponding to vₖ. The first is that all poles transformation and the second is the numerator portion.

The all-pole section given as

$${H}_{A} ( z ) = \frac{1}{z + {\sum }_{n = 1}^{N} {a}_{n} {z}^{- n + 1}}$$

results in a difference equation of

$${y}_{k + 1} = - {\sum }_{n = 1}^{N} {a}_{n} {y}_{k - n + 1} + {u}_{k}$$

The set of state variables are

$${x}_{n , k} = {y}_{k - n + 1} \\ such that \\ {x}_{n + 1 , k + 1} = {x}_{n , k}$$

Consequently, the difference equation may be written as

$${x}_{1 , k + 1} = - {\sum }_{n = 1}^{N} {a}_{n} {x}_{n , k} + {u}_{k}$$

Hence the state space A matrix is given as

$$A = [ \begin{matrix}- {a}_{1} & - {a}_{2} & & - {a}_{N} \\ 1 & & & \\ & 1 & & \\ & & 1 & \end{matrix} ]$$

And the B matrix is

$$B = [ \begin{matrix}1 \\ 0 \\ 0 \\ 0\end{matrix} ]$$

The numerator transfer function is given as

$${H}_{B} ( z ) = {\sum }_{m = 1}^{N} {b}_{m} {z}^{- m + 1}$$

Write the difference equation as

$${v}_{k} = {\sum }_{m = 1}^{N} {b}_{m} {y}_{k - m + 1} \\ Therefore \\ {y}_{k} = \frac{1}{{b}_{1}} {v}_{k} - {\sum }_{m = 2}^{N} \frac{{b}_{m}}{{b}_{1}} {y}_{k - m + 1}$$

The feedback is also given by

$${u}_{f , k} = - {\sum }_{i = 1}^{N} {k}_{i} {x}_{i , k} = - {\sum }_{i = 1}^{4} {k}_{i} {y}_{k - i + 1}$$

The feedback transfer function may be written as

$${H}_{f} ( z ) = \frac{V ( s )}{Y ( s )} = - \frac{{\sum }_{i = 1}^{N} {k}_{i} {z}^{- i + 1}}{{\sum }_{m = 1}^{N} {b}_{m} {z}^{- m + 1}}$$

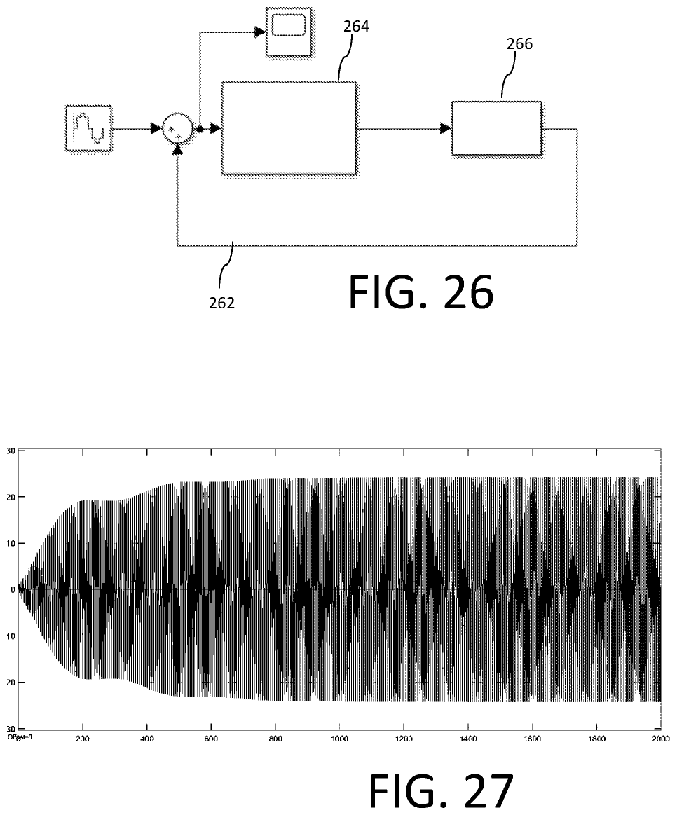

The loop 262 for the general DPLP is now fairly simple consisting only of a filter 264 for the feedback processing 266 as shown in FIG. 26.

FIG. 27 shows the time domain simulation response when the normalized input oscillator is 1 rad/sec and an amplitude of 1 is switched on. The horizontal time axis is in clock cycles. Note that the DPLP is stable after some 800 clock cycles.

### State-Space DPLP of a Single Pole Resonator

The state space formulation of the DPLP feedback processing for a single pole resonator will now be considered. Then this is expanded to the multi-pole resonator.

Start with the ideal single resonator that has a transfer function of

$$H ( s ) = \frac{as}{{s}^{2} + bs + c}$$

The general state space formulation is

$$\frac{dx}{dt} = Ax + Bu$$

where x is the vector of state variables and u is the input. A is the system matrix and B is the input matrix. Let z(t) be the input and y(t) be the output. The state vector is selected to be

$$x = [ \begin{matrix}{x}_{1} \\ {x}_{2}\end{matrix} ] = [ \begin{matrix}y \\ \frac{dy}{dt}\end{matrix} ]$$

which results in the system matrix of

$$A = [ \begin{matrix}0 & 1 \\ - c & - b\end{matrix} ]$$

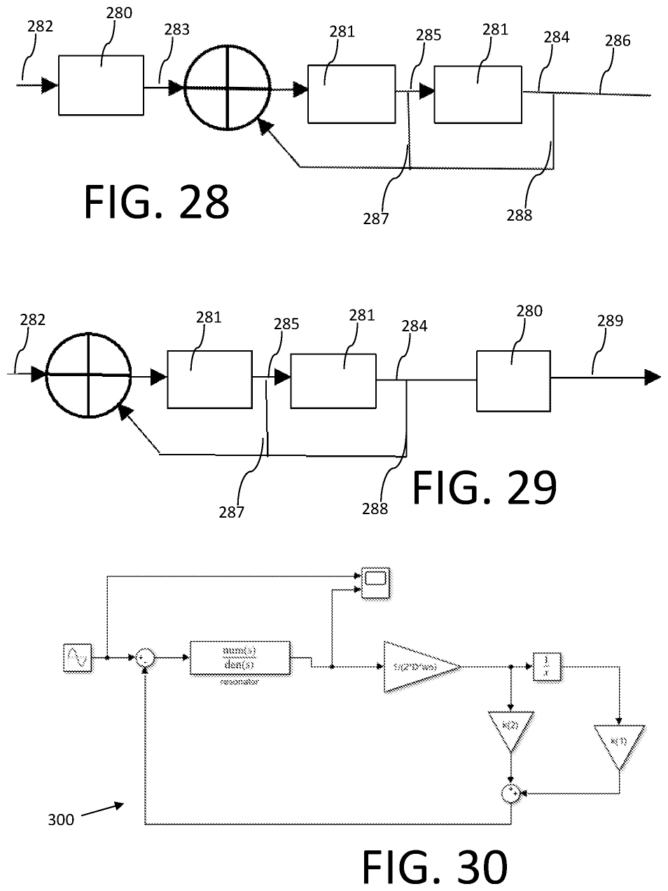

Note that the state variables selected are not unique and that different system matrices may result. However, the system modes are invariant to the choice of the state variables. The choice of state variables allows for a simple signal flow diagram consisting of a pair of integrators as in FIG. 28. In FIG. 28 and FIG. 29, the reference numbers represent the following: 280 to as; 281 to 1/s; 282 to z; 283 to u; 284 to x1; 285 to x2; 286 to y; 287 to −c; 288 to −b; and 289 to ax2.

For simplicity, the derivative operator in the numerator of H(s) is separated out and u(t) is taken as the input. Then the input matrix is

$$B = [ \begin{matrix}0 \\ 1\end{matrix} ]$$

For the system to be controllable the controllability matrix of [B AB A²B . . . ] is determined, which is of full rank. In this case it is as

$$[ B AB ] = [ \begin{matrix}0 & 1 \\ 1 & - b\end{matrix} ]$$

The system is controllable and hence the pole may be fully moved with feedback based on a linear superposition of the two state variables. However, there is only access to the state variable x₁. In this simple example, x₂=\dot{x}₁. Therefore, if x₁ is observed then x₂ may be derived by a linear operation. Therefore, a full state feedback may be provided, and then as the resonator is controllable, place the closed loop poles at an arbitrary desired location. For a higher order system, this may not be so obvious that all the state variables may be observed from the single output. A method of determining if this is possible is to consider the observability of the system. If the state space system is observable, then all the state variables may be derived by linear operations and superpositions of the available outputs. The output of the state space is represented as

$$y = Cx + Du$$

where in this case x₁ is observed at the output such that

C=[1 0]

The observability matrix is

$$[ \begin{matrix}C \\ CA \\ {CA}^{2}\end{matrix} ]$$

which is of full rank. In this case the observability matrix is

$$[ \begin{matrix}1 & 0 \\ 0 & 1\end{matrix} ]$$

which has a rank of 2.

Next, the weighting vector for the feedback may be formed, denoted as k and the input is then

$${u}_{f} = - k x$$

Therefore, the state space of the closed loop AFF is

$$\frac{dx}{dt} = ( A - Bk ) x + Bu$$

The new closed loop poles are given as the eigen values of the matrix (A−Bk). Hence the weight or control law vector of k may be determined, which will set the desired poles. That is, if the pair of {A,B} is controllable, then the eigenvalues of (A−Bk) may be any arbitrary desired set.

As the derivative operator has been separated from the numerator, the feedback may be added to the input so that the feedback is adjusted by (1/as) implying an integration, giving:

$$F ( s ) = \frac{{k}_{1} + {k}_{2} s}{as}$$

and the feedback is F(s)X₁(s). If ωᵣ is adjusted, then k₁ may become zero. Hence what is left is that the feedback to the input is proportional to x₁(t).

The state space formulation is therefore a powerful tool in considering any form of resonator and positing an existence query as to whether all of the poles of a multi-pole resonator may be individually Q modified (enhanced or spoiled) to desired locations in the s plane.

Note also that the resonator ωᵣ may not need to be adjusted for the desired closed loop pole: it may be sufficient to adjust k. As will be shown, it may be possible to adjust ωᵣ after determining k such that the magnitude of k may be minimized. Or it may be possible to set coefficients in k to zero by changing ωᵣ. This is beneficial as the processing to determine the state variables may then be simplified as some are weighted by zero in the feedback.

With switched fixed capacitors for frequency tuning, it is not possible to smoothly tune the capacitor in state space. Hence, the state variables may be approximated from the output. With the controller version of the state space this is straightforward as

$${x}_{2} = \frac{{dx}_{1}}{dt}$$

Consequently, the feedback is:

$$f = {k}_{1} {x}_{1} + {k}_{2} {x}_{2} = {k}_{1} {x}_{1 , k} + \frac{{k}_{2}}{T} ( {x}_{1 , k} - {x}_{1 , k - 1} )$$

It may be better to change the order of the processing such that the derivative x₂ is after the state space processing with a numerator of one in order to have an estimate of x₂ that may be scaled and integrated to form the feedback required for a Q enhanced resonator that is then adjusted in frequency such that k₁=0. This reversal in state space is shown in FIG. 29.

The optimal determination of the weighting vector of k is based on A and B. A caution is that the state variables are now based on this modified transfer function. Note that assuming the numerator derivative to be in front changes B, and hence changes the weighting vector k as well as the state variables. This may be compensated for in the DPLP feedback processor.

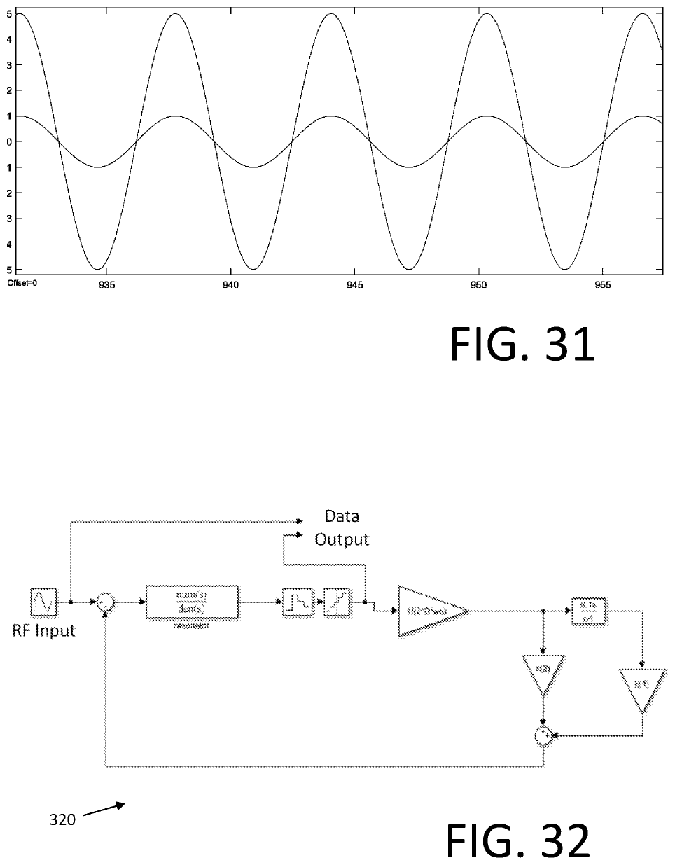

FIG. 30 depicts a Simulink model 300 of the state space Q enhanced single pole resonator with state space feedback showing that the DSP, consisting of 3 gain blocks, an integrator, and a summer, may be used to determine the effect of active feedback in a single pole RF resonator in frequency space. These operations may be mapped into a discrete time DSP formulation. FIG. 31 shows the simulation response of Simulink model 300.

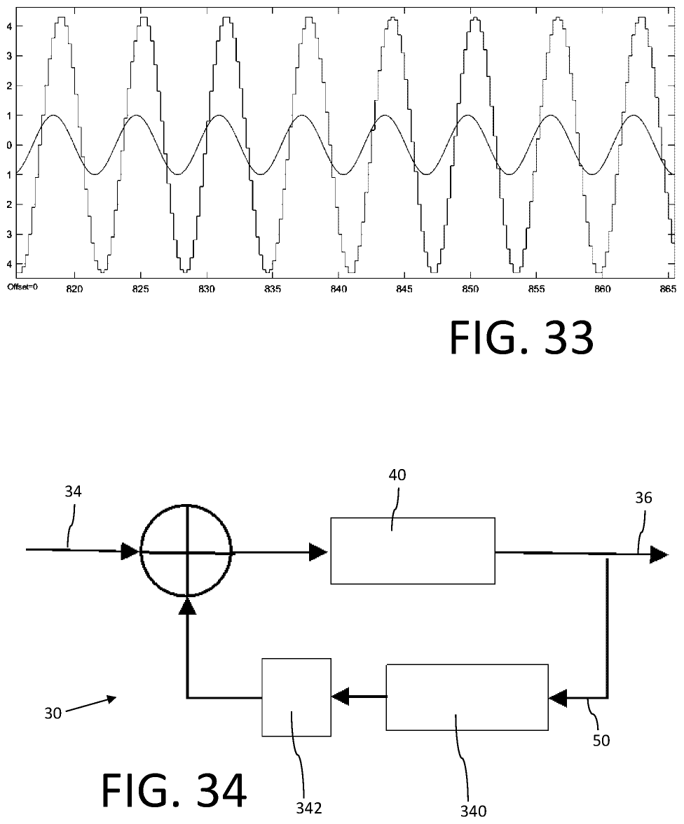

DSP processing may be added as shown in a Simulink model 320 depicted in FIG. 32 and shows similar Q enhancement as in FIG. 33 where the horizontal axis is seconds. Note though that the results are a little off due to the delay in the integrator which is represented by the discrete time accumulator. Note further the time phase lag of the quantized resonator output relative to the input. The quantization step was 0.1 and the time resolution was 0.25.

FIG. 33 shows the simulation response of Simulink model 320.

While this is a demonstration that the DSP processing is both efficient and simple to implement, the conversion from continuous time to discrete time is not the best approach. It is better to model the resonator in Z domain resulting in a more direct DSP implementation.

### Variable Delay Active Feedback Filter Tuning

A relatively simple example of a continuous time AFF implementation of signal processing circuit 30 in state space is shown in FIG. 34. The AFF circuit was discussed and presented above.

Inner loop 40 filter may be a bypass such that H_{LF}(s)=1. There is a variable delay 340 of T_{d} with a gain block 342 with a gain of G. There may be a simple DPLP, based on a single pole resonator, that may provide an arbitrary continuously variable delay in DSP that may be modelled as an infinite series of poles plus a gain factor such that arbitrary tuning may result.

The open loop response evaluated on the jω axis is

$${H}_{ol} ( s ) = {e}^{- j ω {T}_{d}}$$

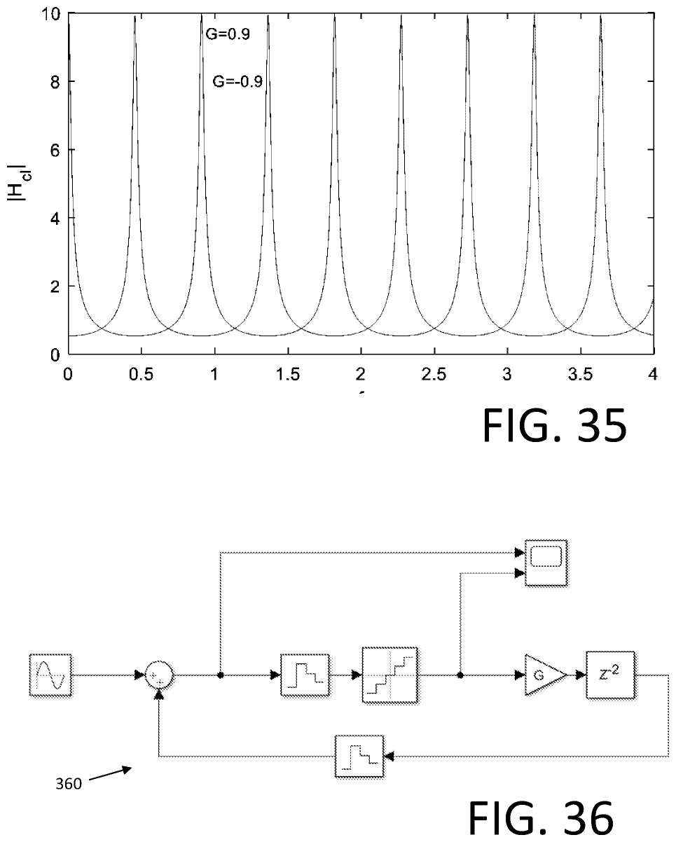

such that the Nyquist resonance curve (NRC) is a closed circuit of unit radius. The operating point is on the real axis at 1/G such that if G>1 then the operating point will be encircled and the AFF is unstable. For the range of −1<G<1 there is Q enhancement of the set of frequencies where ωT_{d}=nπ where n= . . . −2, −1, 0, 1, 2, . . . . Hence there may be a periodic frequency response with multiple Q enhanced poles and multiple passbands. This is shown in FIG. 35 for a delay of T_{d}=1.1.

Next consider a DPLP where the sampling interval is T and the delay is T_{d}=nT. A Simulink model 360 is shown in FIG. 36. The DPLP loop has the sum block for the feedback as before. Then a quantizer which samples in time with a sampling interval of T. The samples are subjected to a delay which in this case is 2 sampling intervals by the z⁻² block. Then the DAC block is another zero-order hold.

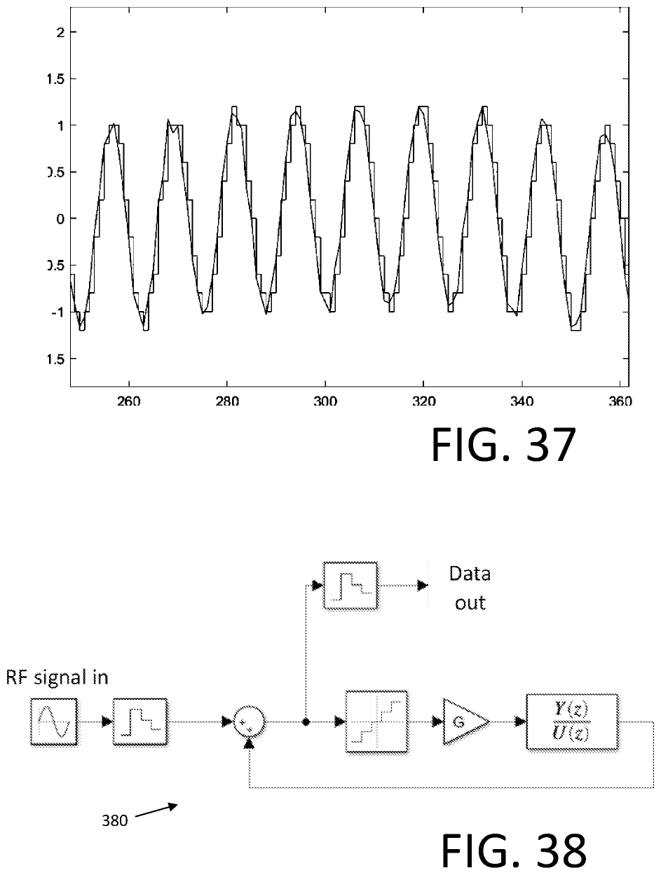

FIG. 37 shows a portion of the analog and digital quantized signal. Difficulties with time domain simulation involve the small amount of transient of multiple frequencies as the source is turned on at t=0, generating several frequency components. The transient takes a long time to die out as the delay DPLP Q enhances multiple frequencies.

The method of analysis is to convert the loop components into Z domain and to approximate the quantization as an independent noise source added at the point of the ADC conversion.

As in the continuous domain there may be an open loop response of

$${H}_{ol} ( z ) = {z}^{- 2}$$

Instead of evaluating on the s=jω axis as in the s-plane the unit circle of z=e^{jωT} may be evaluated in the Z plane. Hence the NRC is a unit circle, and the Nyquist stability analysis may be considered as before. In this case there is no continuous time transfer function in the loop and hence the entire loop may be disregarded as sampled such that the closed loop response is

$${H}_{CL} ( z ) = \frac{1}{1 - {Gz}^{- 2}} = \frac{1}{1 - {Ge}^{- 2 j ω T}}$$

Note the comparison of the continuous time closed loop response of

$${H}_{CL} ( j ω ) = \frac{1}{1 - {Ge}^{- j ω {T}_{d}}}$$

which is equivalent provided that 2T=T_{d}. The difference is that the closed loop response assumes a time sampled signal. Hence an equivalent DPLP Simulink model 380 is shown in FIG. 38.

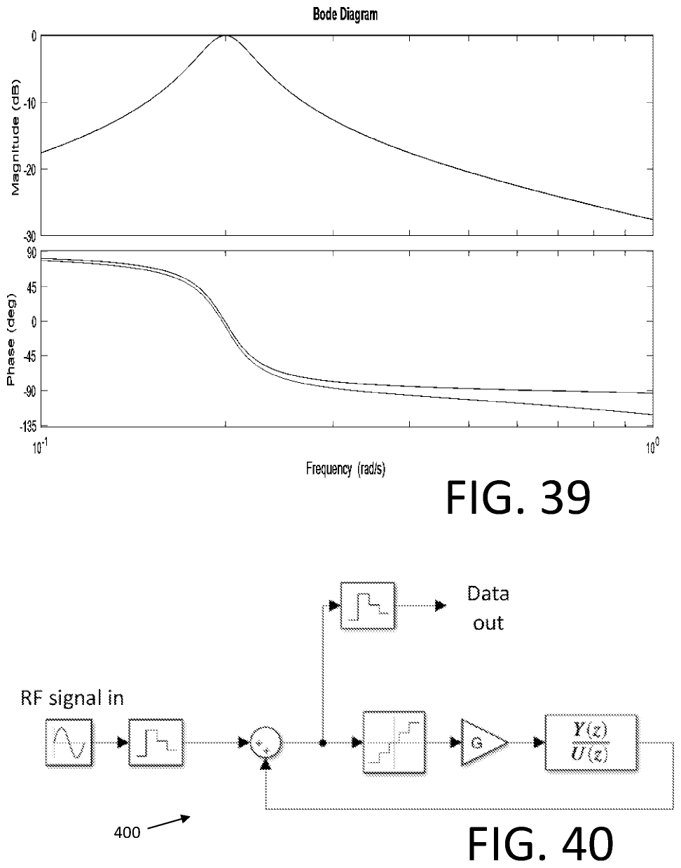

The DPLP considered has a delay that is an integer number of sampling intervals, which is preferably variable. One possibility is to implement a delay with a passband response with wₒ=0.2 (normalized), D=0.1, T_{d}=0.1, and T=1.0. The bode plot of continuous time and discrete time is shown in FIG. 39. The discrete time is calculated from the continuous based on an invariance of the step response when the zero order hold (ZOH) approximation is applied to the sampling operation. The responses are indistinguishable in magnitude and a small phase difference.

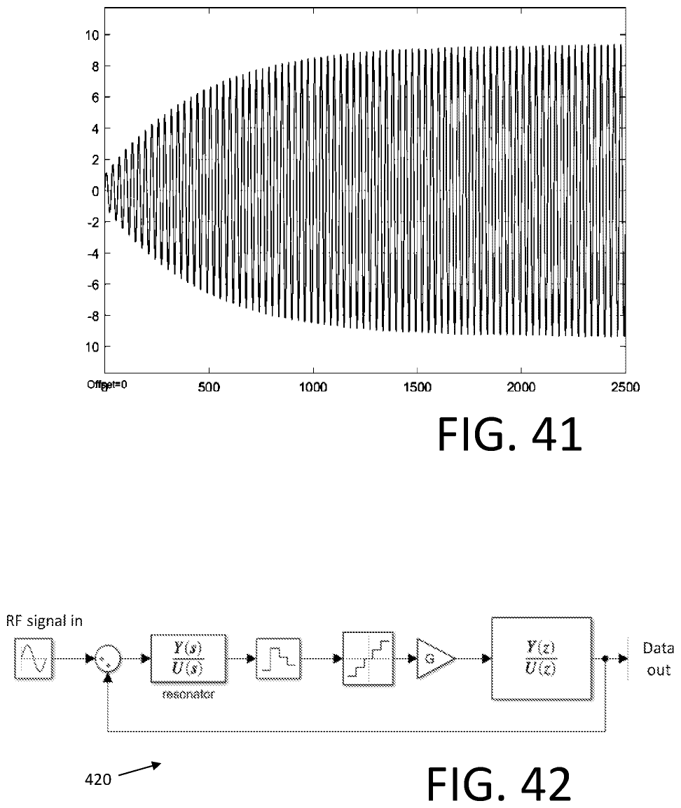

A Simulink simulation model 400 of the discrete filter placed in the loop is shown in FIG. 40. G is 0.9 and hence a Q enhancement of about 10, which is revealed as the sinusoidal frequency of the input is at 0.2 rad/sec and an amplitude of 1. The model's response is seen in FIG. 41, with the horizontal axis in terms of DSP clock cycles, shows that the startup transient is stable and corresponds to the risetime constant, commensurate with the pole Q being implemented. There is a slight loss due to the ZOH of the ‘sin(x)/x’ frequency response.

With the transfer function of Hd(z) given as

$${H}_{resd} = \frac{4.959 * 1 {0}^{- 5} {z}^{3} - 4991 * 1 {0}^{- 5} {z}^{2} - 4.893 * 1 {0}^{- 5} z + 4.926 * 1 {0}^{- 5}}{{z}^{4} - 3.96 {z}^{3} + 5.901 {z}^{2} - 3.921 z + 0.9802}$$

the difference equation may be determined directly. It may be shown that the implementation in DSP involves 5 coefficient multiplications and 5 additions.

### Single Pole (P=1) Variable Delay Discrete Time DPLP

In this example, a single continuous time pole (P=1) resonator, or first order resonator, is considered as a Simulink model 420 depicted in FIG. 42, starting with a simple gain block.

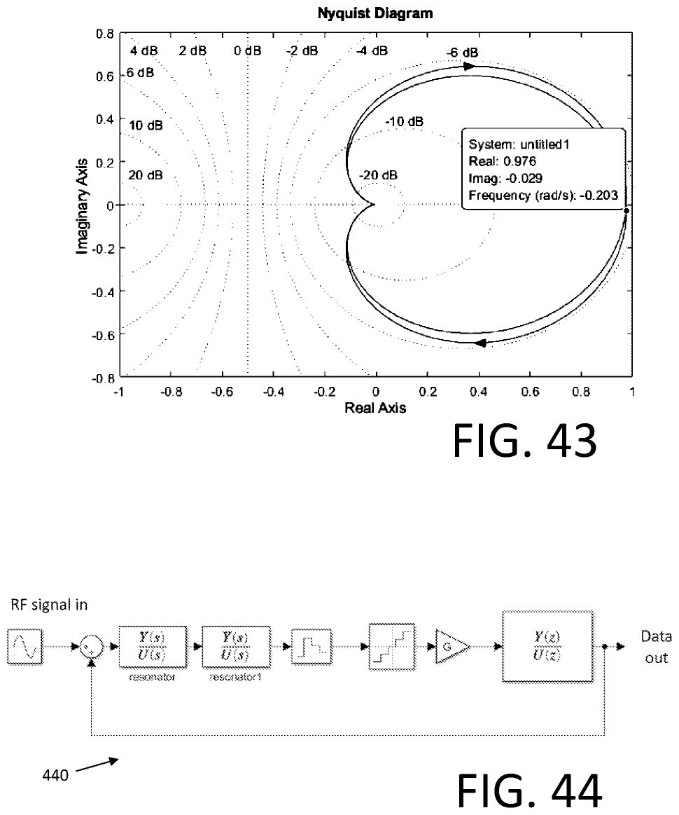

The open loop Nyquist plot is calculated based on converting the resonator into a discrete time sampled transfer function and then cascading this with the discrete time transfer function. The resulting NRC curve is shown in FIG. 43.

This two pole DPLP resonator Nyquist resonator curve (NRC) looks similar to a 2-pole frequency space resonator NRC because there are effectively two poles in this DPLP state space resonator: one as a continuous time resonator and the other as a digital domain resonator.

Clearly the continuous time resonator may be tuned and then the DSP resonator/phase shifter may be determined to provide a desired Q enhanced response.

### Two Pole (P=2) Variable Delay Discrete Time DPLP

A second resonator may be added to make a second order resonator. A Simulink model 440 is shown in FIG. 44.

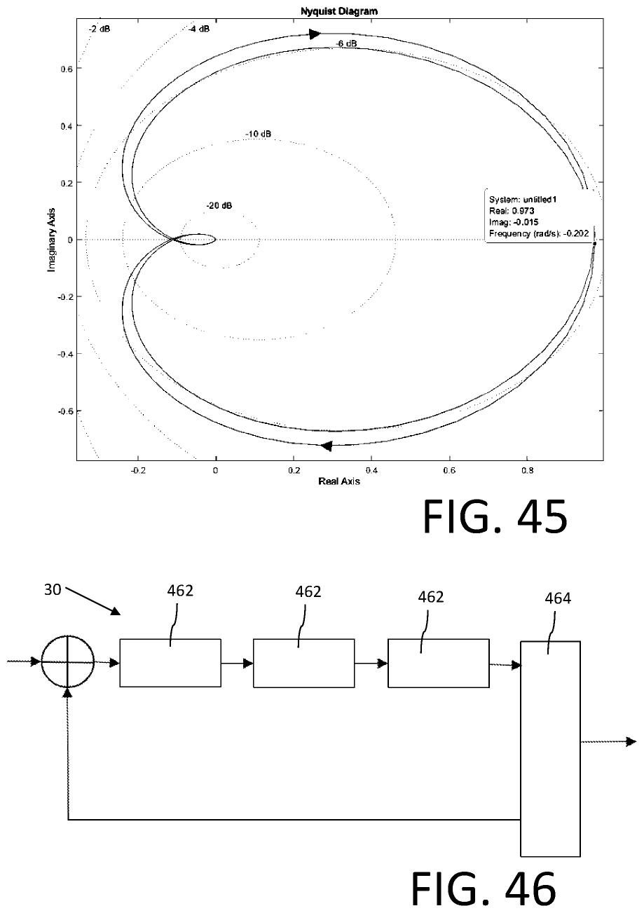

The open loop Nyquist plot is calculated based on first converting the continuous time resonator into a discrete time sampled transfer function, as above, and then cascading this with the discrete time transfer function. The resulting NRC for this P=2 DPLP is seen in FIG. 45.

### Frequency Tuning a Fixed Frequency Resonator

An RF resonator may be chip integrated or implemented with distributed off-chip components. Consider the fixed frequency resonator for certain applications, represented perhaps as a SAW or a BAW device. The generally passive fixed frequency resonators may perform this filtering task effectively with no power requirements and may be designed to tolerate the large interference signals, albeit at a fixed center frequency.

A fixed frequency resonator may be generally a fixed set of poles—poles which may be Q enhanced or Q spoiled as well as frequency shifted as desired following the above principles. A SAW or BAW has a common characteristic of spectral regrowth which may be mitigated following the above principles.

Further, the SAW/BAW may have several passband poles of moderately high Q. However, an issue with the SAW is that it is difficult to control the passband ripple and slope with frequency. Feedback processing necessary for multi-pole placement becomes unwieldy and unreliable if implemented with RF circuitry. Yet such processing is almost trivial to implement in a digital domain where the signals are digitized. Hence the loop should consist of two domains: the RF domain for the resonator, and the digital domain for the feedback processing.

By using the DPLP feedback, the multiple poles of the SAW may be moved to more desired locations to provide an even higher Q passband response with very small passband variation, and in the process, suppress spectral regrowth as well. The feedback signal in the DPLP loop may also be large in comparison to the input signal.

With the development of very high speed digital processing, ADCs, and DACs, such a mixed signal loop may be practical to implement. A potential weakness is that the transition from the RF domain state space A to the state space domain B may involve frequency down conversion, sampling, and ADC quantization. These processes may have a relatively high noise figure (NF) and may be susceptible to out of band noise.

The resonators remove a large amount of the out of band noise and interference as it propagates in the loop prior to the domain A to domain B transformation components. The transformation of domain B to domain A involves up-conversion, and DACs which may generate significant out of band frequency spurs and quantization noise. This is largely removed by the resonators before circling back to the A and B domain transformations.

### Generating a Third Order Chebyshev or Butterworth Response Using DPLP

As a final example consider the practical implementation of signal processing circuit 30 as shown in FIG. 46. The three resonators 462 are set up with the fixed capacitors required for the frequency that is closest to the center frequency of the objective third order Q enhanced filter. In FIG. 46, the resonators output to a block 464 that represents all of the ADC, DSP and DAC.

A DPLP pole placement algorithm may then be used to determine the processing required to get the pole placement that will result in the objective passband response. In the Chebyshev case, the objective is a flat passband response over a desired −1 dB bandwidth.

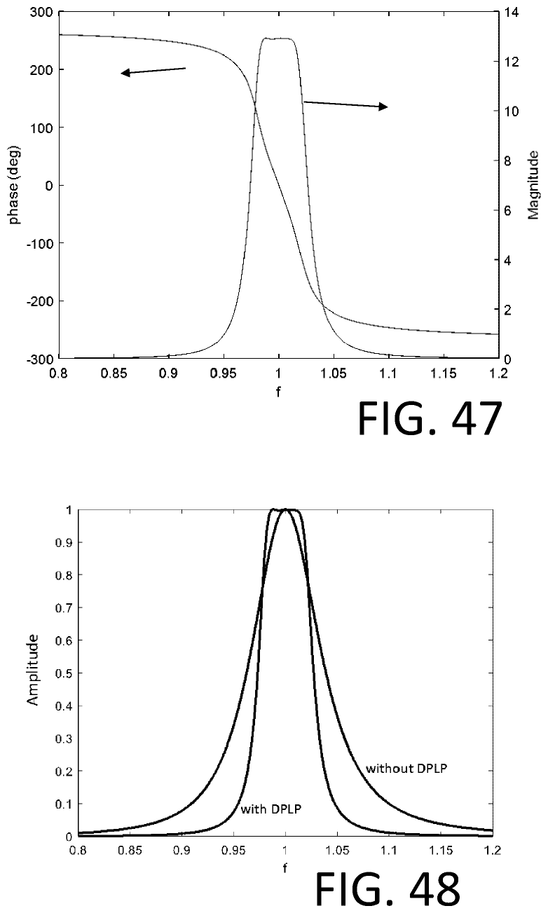

The resulting response is shown in FIG. 47 with phase on the left vertical axis, and magnitude on the right vertical axis.

As another visualization of what the DPLP algorithm is doing for this Chebyshev bandpass filter example, consider FIG. 48. The blue curve is the response of the three resonators in FIG. 46 without any DPLP feedback. For this Chebyshev example, the normalized resonant frequencies of each resonator are set to 1 rad/sec, which is the pass band center of the desired response. The DPLP feedback then moves the three poles of the resonators in the s-plane such that the desired pass band response is obtained.

This response, as shown in FIG. 47, is copied to FIG. 48 and amplitude normalized for direct comparison of the two results.

Identical methods are used to achieve a Butterworth passband response.

### Determining the Positive Feedback Processing Based on Nyquist Stability Criteria

As the number of resonators 462 increases, it may become numerically more of an issue to work with the transfer function in terms of poles and zeros directly. Alternatively, it is possible to work with the Nyquist resonator curve (NRC). The NRC includes all frequency dependent components of the open loop response. Representing the open loop response graphically makes it easier to achieve desired characteristics of the closed loop response by deforming the NRC around the operating point.

Let Hᵣₑₛ(z) be the transfer function of the resonators in the z domain. This may be determined directly from the frequency measurements of the resonator or it may be a pole zero transfer function model of the resonator that is converted into the discrete time domain. H_{fb}(z) is the DSP processing which is an exact representation of what is implemented with the exception of the signal digitization. The NRC is then formed from the open loop response of Hᵣₑₛ(z)H_{fb}(z) which is plotted in the complex z-plane.

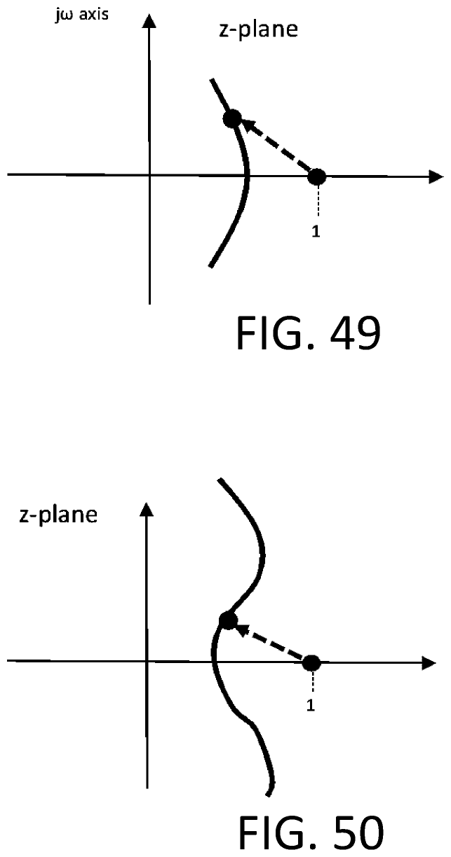

The NRC sketched for a one pole equivalent open loop is shown in FIG. 49. A portion of the NRC is shown for the region around the resonance frequency. The operating point may be to the right of the NSC for stability and on the real axis. If it is on the left side of the NRC, then the DPLP is unstable.

The frequency response is given approximately by the inverse of the phasor connecting the operating point to the frequency point on the NRC. As observed here, the phasor length grows as the frequency moves away from the closed loop resonance point. The closed loop resonance point is defined as the intercept point of the NRC and the real axis.

The objective is to optimize H_{fb}(z) such that the NRC has the desired shape. An example of this is shown in FIG. 50 there H_{fb}(z) has been determined such that the phasor of FIG. 49 has a near constant length over the desired closed loop bandwidth of the DPLP.

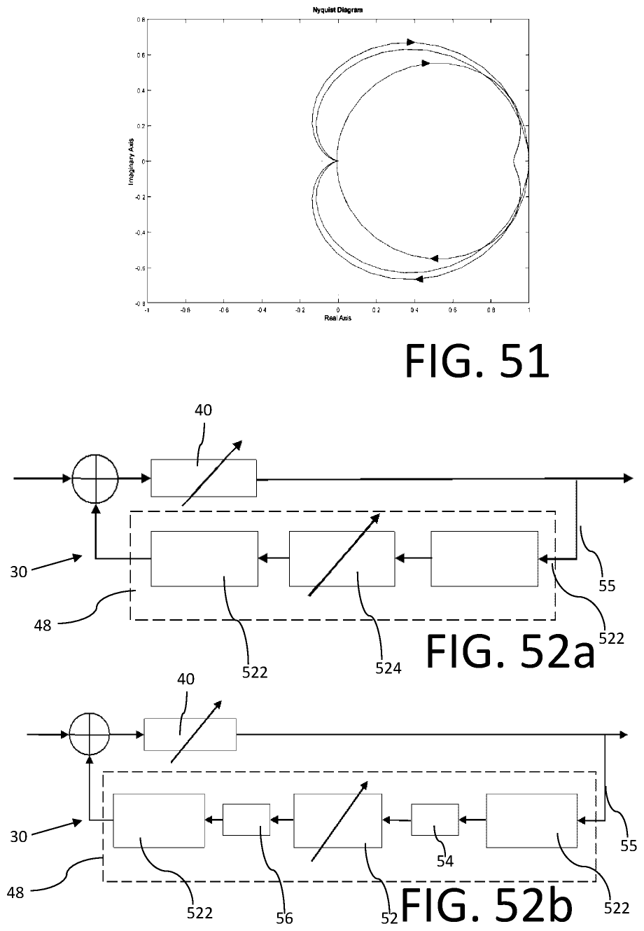

FIG. 51 shows a simulated NRC of a two pole resonator with optimized pole placement based on setting the desired closed loop resonator pole positions. The operating point is on the real axis at a value of 1. The blue curve is the NRC of the two pole resonator. The red curve is the NRC of the open loop transfer function of Hᵣₑₛ(z)H_{fb}(z). Note the indentation of the open loop NRC around the resonance frequency that results in the flat passband response.

Combined Frequency Translation and Signal Digitization with DPLP

The DPLP transformation from domain A to domain B may involve both frequency translation and signal digitization with DSP used for feedback processing 48 as an example of the parallel processing paths indicated in FIG. 52a and FIG. 52b wherein the FIG. 52a shows that feedback processing 48 may involve frequency translation 522 so that the actual feedback processing 524 occurs at a different frequency that may result in a simpler and more practical realization of the feedback processing for a particular application. Actual feedback processing 524, for example, may be baseband analog processing.

FIG. 52b illustrates a domain transformation that includes frequency translation 522 and both discrete time sampling and resulting quantization of the input signal. The feedback processing may then be done in DSP processed state space. The basic DPLP with frequency translation may be incorporated into an SDR, as discussed below

### DPLP Implementations in the Z Domain

### Single Pole DPLP Resonator Response Modeled in the Z Domain

The first step is to create the continuous time model of the resonator that is subsequently converted to a discrete time model as was discussed above and modeled and shown in FIG. 42. It can be shown that this results in a Z-transform model as:

$$H ( z ) = \frac{{b}_{1} z + {b}_{2}}{{z}^{2} + {a}_{1} z + {a}_{2}}$$

Assume uₖ is the input and partition the model into the denominator part and the numerator part.

$$H ( z ) = \frac{1}{z + {a}_{1} z + {a}_{2} {z}^{- 1}} ( {b}_{1} + {b}_{2} {z}^{- 1} )$$

Let yₖ be the output of the first transfer function and define the state variables as

$${x}_{1 , k} = {x}_{2 , k - 1} \\ {x}_{2 , k} = {y}_{k}$$

This then sets up the state space of A and B where vₖ is the output.

Next decide on the Q enhanced poles and determine the k vector. The feedback is given by

$${f}_{k} = - {k}_{1} {x}_{1 , k} - {k}_{2} {x}_{2 , k} = - {k}_{1} {x}_{2 , k - 1} - {k}_{2} {x}_{2 , k}$$

The output is observable as vₖ which is related to the state variable as:

$${v}_{k} = {b}_{1} {y}_{k} + {b}_{2} {y}_{k - 1}$$

which is expressed in terms of the state variables as:

$${v}_{k} = {b}_{1} {x}_{2 , k} + {b}_{2} {x}_{2 , k - 1} \\ From which$$

$${x}_{2 , k} = - \frac{{b}_{2}}{{b}_{1}} {x}_{2 , k - 1} + \frac{1}{{b}_{1}} {v}_{k}$$

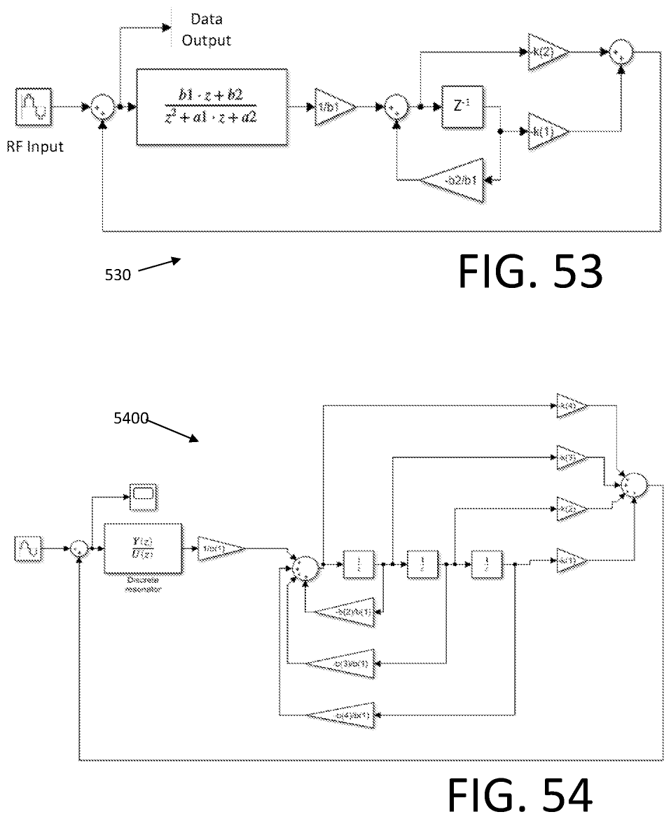

The advantage of the controller state space model is that the state variables are all direct delayed versions. Hence a simple delay tapped line is implemented. This is shown in a Simulink model 530 depicted in FIG. 53. As this is only a single pole, only one delay is needed. Note the operations required are four multiplies and two sums.

### Two Pole Resonator DPLP Response Modeled in the Z Domain

Next consider the DPLP with two resonators. The same steps as before may be followed to determine the DSP processing that is required. The first step is the continuous time model of the resonator, followed by conversion to a discrete time model. This two pole resonator was previously discussed and modeled as previously shown in FIG. 44.

It can be shown that this results in a z-transform model as

$$H ( z ) = \frac{{\sum }_{i = 0}^{3} {b}_{4 - i} {z}^{i}}{{\sum }_{j = 0}^{4} {a}_{5 - i} {z}^{i}}$$

The coefficient of ai is always 1 this may be pulled out, rewriting the transfer function as

$$H ( z ) = \frac{{\sum }_{i = 0}^{3} {b}_{4 - i} {z}^{i}}{{z}^{4} + {\sum }_{j = 0}^{3} {a}_{5 - i} {z}^{i}}$$

Now multiply by z⁻³ to get

$$H ( z ) = \frac{{\sum }_{i = 0}^{3} {b}_{4 - i} {z}^{i - 3}}{z + {\sum }_{j = 0}^{3} {a}_{5 - i} {z}^{i - 3}}$$

Assume uₖ is the input and then partition the model into the denominator part and the numerator part as

$$H ( z ) = ( \frac{1}{z + {\sum }_{j = 0}^{3} {a}_{5 - j} {z}^{j - 3}} ) ( {\sum }_{i = 0}^{3} {b}_{4 - i} {z}^{i - 3} )$$

Let yₖ be the output of the first transfer function and define the state variables as

$${x}_{1 , k} = {x}_{2 , k - 1} \\ {x}_{2 , k} = {x}_{3 , k - 1} \\ {x}_{3 , k} = {x}_{4 , k - 1} \\ {x}_{4 , k} = {y}_{k}$$

This then sets up the state space of A and B, where vₖ is the output. Next decide on the Q enhanced poles and determine the k vector. It can be shown that the feedback is thus given by

$${f}_{k} = - {\sum }_{i = 1}^{4} {k}_{i} {x}_{i , k} = - {\sum }_{i = 1}^{4} {k}_{i} {x}_{4 , k - i}$$

The output is observable as vₖ which is related to the state variable as:

$${v}_{k} = {\sum }_{i = 1}^{4} {b}_{i} {y}_{k - i + 1}$$

which is expressed in terms of the state variables as

$${v}_{k} = {\sum }_{i = 1}^{4} {b}_{i} {x}_{4 - i + 1 , k} \\ from which \\ {x}_{4 , k} = \frac{1}{{b}_{1}} {v}_{k} - \frac{1}{{b}_{1}} {\sum }_{i = 2}^{4} {b}_{i} {x}_{4 - i + 1 , k} = \frac{1}{{b}_{1}} {v}_{k} - \frac{1}{{b}_{1}} {\sum }_{i = 2}^{4} {b}_{i} {x}_{4 , k = i + 1}$$

The advantage of the controller state space model is that the state variables are all direct delayed versions. Hence a simple delay tapped line is implemented. This is shown in a Simulink model 540 depicted in FIG. 54. As this is only a single pole, only one delay is needed, and the DSP becomes an easily implemented simple filter structure. Note the operations required are four multiplies and two sums.

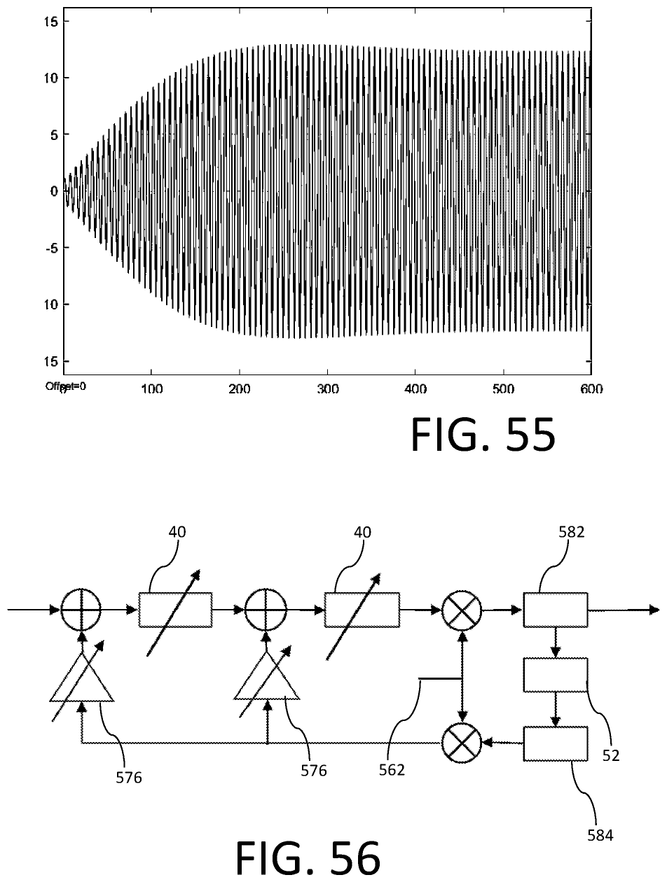

FIG. 55 shows the simulated output of this 2-pole DPLP resonator where the two poles are placed simultaneously. The horizontal axis is in terms of DSP clock cycles and shows that the startup transient is stable and corresponds to the risetime constant commensurate with the pole Q being implemented.

### Dual Loop Extension to Bandpass Delta Sigma

The design principles discussed above can be extended to other architectures that involve a down conversion, such as a bandpass delta sigma circuit. Delta Sigma (DS) is a digital signal processing technique that is incorporated into ADC architectures to reduce the quantization noise in generic receivers. Bandpass DS (BDS) is an extension of DS that may be used to suppress the intrinsic noise of the down conversion process in addition to the quantization noise. A chip integrated version of BDS, such as those that operate above 1 GHz, may be difficult to implement as a resonator with a sufficiently high Q is required, which is difficult to produce using conventional integrated circuitry. Using the variable filter technology of this disclosure, a high Q, stable resonator, such as a resonator with a Q over 1,000, that may be integrated onto a chip.

In the case of a circuit that involves a down conversion, the down conversion may be a significant source of noise. A tunable dual loop implementation for frequency up and down conversion noise mitigation is shown in FIG. 56, with inner loops 40, a negative loop with gain blocks 576, ADC 582, DSP 52, DAC 584, and a LO input 562.

### Tunable Notch Filter

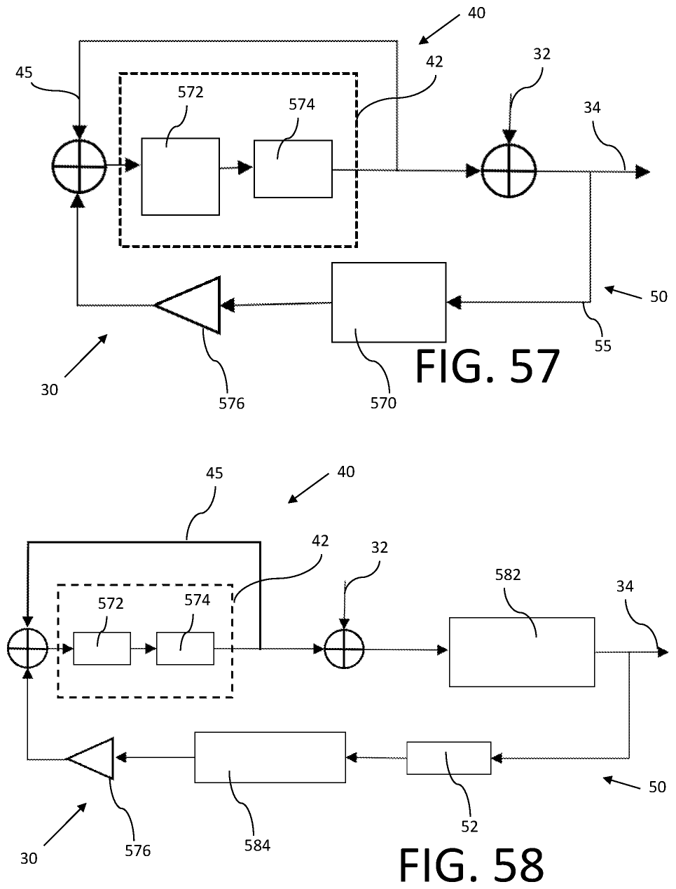

Signal processing circuit 30 can provide a notch filter but with input 34 applied at a different point in the loop. This is shown in FIG. 57 and has a phase shifter 570 in outer loop 50.

Note the transfer function from input 32 g(t) to output 34 port is the same as that of the downstream noise that was considered before. The transfer function will have a notch at the location of the dominant pole of the Q enhanced bandpass filter 42 with filter block 572 and gain block 574. Negative feedback gain 576 will determine the depth of the notch. Note this version is in RF.

There may also be a version that is a baseband processing variant with quadrature sampling as shown in FIG. 58. The downstream may have quadrature down-conversion and sampling ADC 582, DSP 52, and quadrature DAC and up-conversion 584. Down conversion and up conversion is optional.

A notch filter can be used to null out a narrow band interference. It can also be used to form a zero of a complex filter using both poles and zeros, such as an RF elliptic bandpass filter.

### Numerical Example of a Notch Filter Using a Catalogue Bandpass Filter

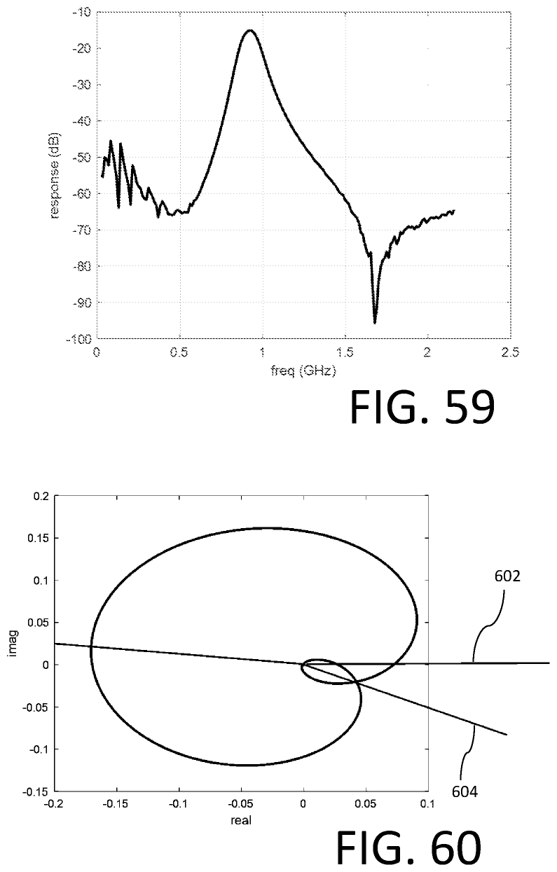

As a numerical example, first consider a catalogue variable bandpass whose response is shown in FIG. 59. The NRC at this setting is shown in FIG. 60 with an optimal axis for inner loop Q enhancement represented by line 602 and an optimal axis for outer loop bandpass delta sigma represented by line 604.

Note that the optimum bandpass delta sigma axis is coincident with the trough of the NRC at s=0 such that the feedback gain can be larger (to separate the pole from the zero). However, it is difficult to determine this angle so that a practical implementation would have the delta sigma axis at 180 degrees from the peak. That is, the peak may be determined for further Q enhancement easily, but the bandpass delta sigma axis is more difficult. In that case, the maximum delta sigma negative outer loop feedback is less.

Given the NRC, there is a point on the outer encirclement boundary of the trajectory that has maximum modulus referenced to the origin, and a point that has minimum modulus as referenced to the origin. For the NRC of a SAW that is Q enhanced, these points are roughly on opposite sides. The maximum is suitable for positive inner loop feedback Q enhancement, and the minimum is suitable for Q spoiling in the negative feedback outer loop.

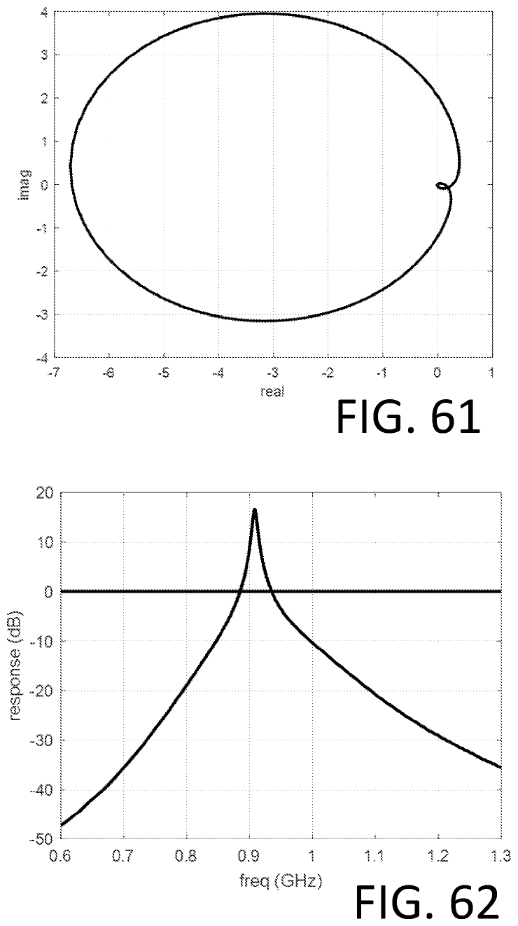

Next a modest Q enhancement is applied by a factor of Qₑₙ=10. The closed loop NRC is shown in FIG. 61. Note now that the outer loop negative gain can be much larger.

FIG. 62 shows the transfer function of the quantization noise (QNTF) with a tunable bandpass delta sigma feedback gain of 0 (that is, does nothing) and the Q enhancement of the reinforcement loop is 10. The flat line at 0 dB is the QNTF. The peaked Q enhanced signal transfer function (STF) is as expected with the signal enhancement positive feedback of the inner loop.

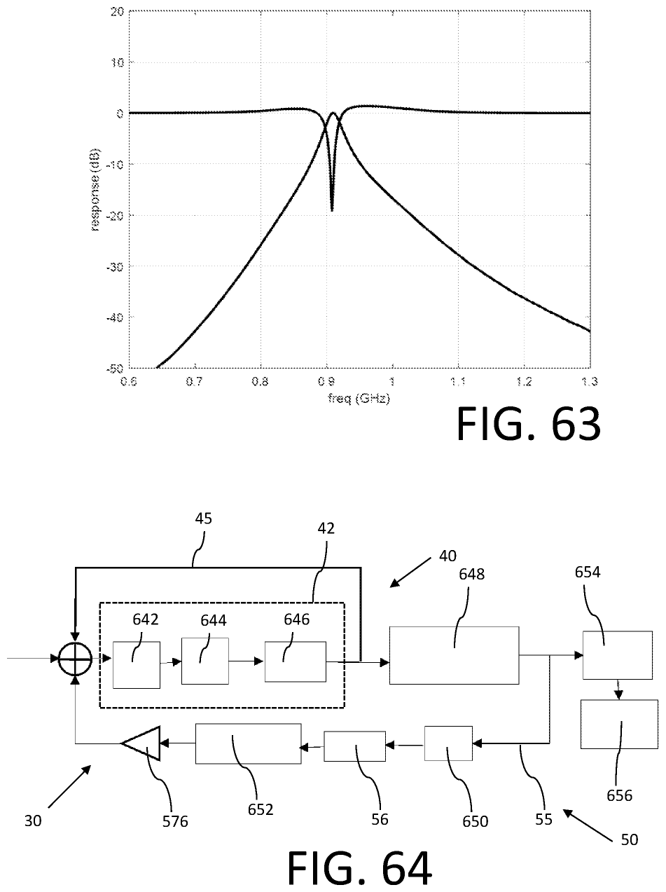

FIG. 63 shows the effect of the tunable bandpass delta sigma modulation with the dip in the quantization noise transfer function that was flat in FIG. 62. Here the outer loop negative feedback may be adjusted such that the QNTF has a loss of about 19 dB. The signal bandwidth of the STF has broadened as the negative feedback removes some of the positive reinforcement feedback gain of the inner loop.

The bandwidth of the STF can be restored by increasing this signal reinforcement gain of the inner loop. However, the zero gets pushed toward the jω axis for a narrower notch. To widen the notch bandwidth, a second order bandpass delta sigma may be implemented providing two poles and two zeros. Further widening of the notch bandwidth is achieved by implementing a higher order bandpass delta sigma.

The loop can be expanded to two poles such that there are two signal-reinforcement Q enhanced poles that can be realized in the upstream receiver. The negative feedback loop can have two loops also as described above.

### Fixed Frequency Bandpass Filters

As discussed above, the bandpass filter 42 of inner loop 40 (or resonator A(s) or block 92 of upstream processing 91 shown in FIG. 9) may be a number of different things. Many RF/microwave receivers have a fixed filter of high frequency selectivity in the FEM. Bandpass filter 42 may be a surface acoustic wave (SAW) filter or a bulk acoustic wave (BAW), a microstrip filter cavity filter, and so on. They are narrowband and not tunable. In a cell phone there may be a set of these filters that can be individually selected to demodulate a given signal band.

### Acoustic Wave Filters

Acoustic wave SAW/BAW devices will now be discussed, and in particular the SAW which is analogous to a BAW.

For the dual loop, this SAW filter network is part of bandpass filter 42 and may include a saw filter 642, a gain block 644, and a phase shifter 646. A positive reinforcement feedback loop 45 may be provided around this which will do two things:
1. Q enhance a sub-band within the narrow bandwidth of the SAW (or other) filter.
2. Change the shape of the closed loop bandpass filter 42 of inner loop 40 (upstream receiver plus reinforcement feedback path) such that the negative feedback of outer loop 50 can frequency shape the noise injected by the down stream receiver.

To achieve a deeper notch of the downstream receiver noise transfer function a higher negative feedback gain is required. By shaping the NRC of the closed loop upstream receiver stability can be assured.

An acoustic resonator, such as a SAW, may provide high frequency selectivity as bandpass filter 42. The NRC of the SAW is generally not suitable for outer loop 50 noise shaping as there are several poles. However, the SAW response can be Q enhanced with an inner loop 40 and then the NRC will change sufficiently such that the negative feedback can be applied with arbitrary gain for an arbitrary level of suppression. A block diagram of a SAW implementation as the resonator in the upstream receiver is shown in FIG. 64, and includes a Down-convert LPF, quadrature ADC 648, complex scaling factor 650 that corresponds to A(z), DAC 56, upconversion 652, negative feedback gain 576, sample storage 654, and post processing 656.

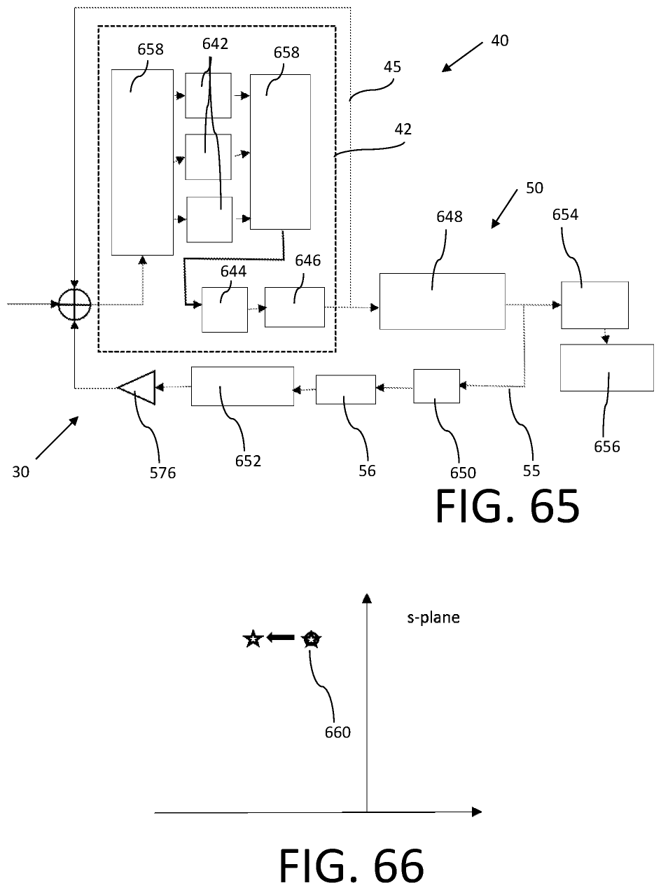

SAW filter 642 can be any bandwidth SAW filter where the passband includes the passband of the desired signal. Referring to FIG. 65, signal processing circuit may also be have set of SAW filters 642 that are switched in and out of the signal path of the bandpass filter 42 by switches 658 as shown in FIG. 65. It is important to note that the outer loop 50 negative gain may be complex, while the inner loop 40 signal reinforcing gain is real.

In the quadrature sampling, the signal phasor of real and imaginary components is extracted. This is multiplied by a complex number with a real and an imaginary component. The resulting phasor is changed in both angle and magnitude which is regarded herein as complex scaling. The resulting phasor is then converted back to RF with a quadrature DAC 56 and frequency upconversion 652.

The system in FIG. 64 can be modified to a second order system with two SAW resonators that are reinforced and one or two negative feedback loops. In the bandpass delta sigma, the movement of the poles in the delta sigma is illustrated in FIG. 66. The bandpass pole is indicated by the star and forms also the zero of the QNTF (transfer function of the downstream quantization noise to output). This zero cannot be moved by feedback. The pole 660 of the QNTF starts in the same position as the zero and thereby cancels the effect. However, with negative feedback of the outer loop, the pole can be moved to the left hence separating it from the zero. The effect is that the QNTF zero now reduces the response in the middle of the passband. As also observed, it is necessary that the pole has a high Q prior to forming the feedback loop. This requirement for a high Q pole is what limits the application of delta sigma processing. However, with the upstream signal loop, the Q can be increased such that the QNTF zero becomes relevant.

The concept of a tunable bandpass sigma delta will be described in detail below.

### Catalogue SAW Filter Enhancement Example

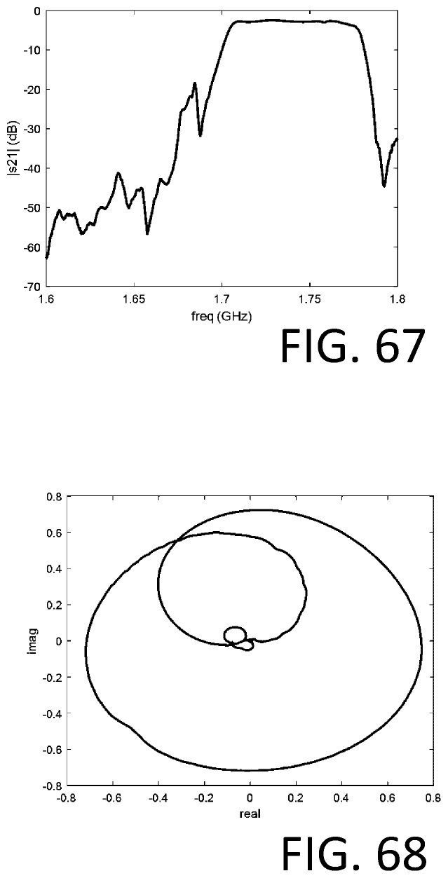

By way of an example, a Taiwan Semiconductor Manufacturing Company (TSMC) SAW will be considered. FIG. 67 is the frequency response of a TSMC SAW showing a passband of about 1.71 to 1.77 GHz. Note that the passband is flat while the edges are steep indicative of multiple poles within the passband.

FIG. 68 is the Nyquist resonance curve (NRC) of the SAW. As noted, the NRC can be Q enhanced but cannot be used directly for the negative feedback as the modulus of the NRC outer encirclement is too large. This limits the amount of negative feedback that can be applied.

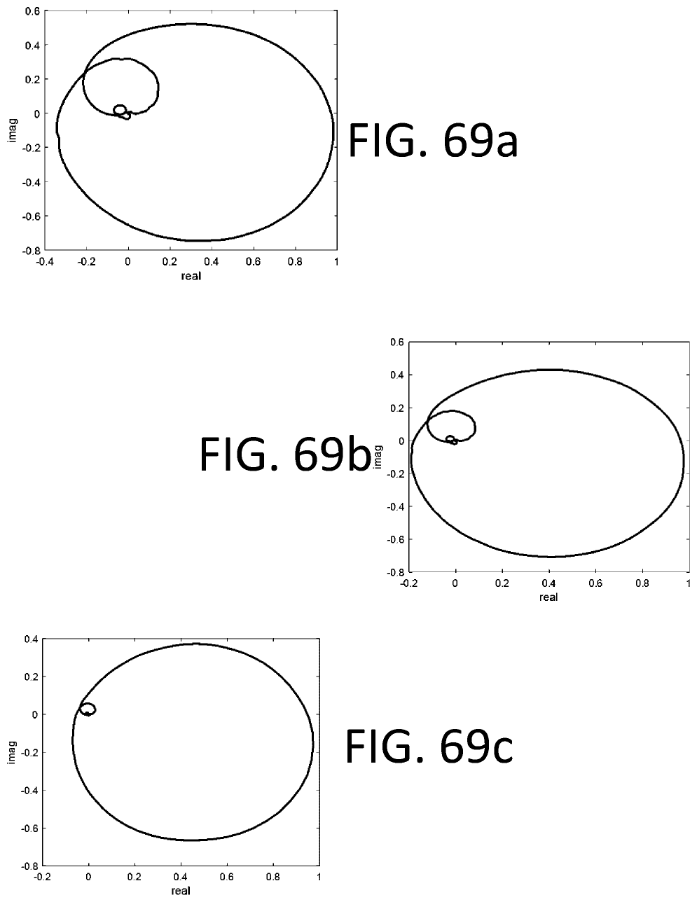

Next consider the signal reinforcement applied to the SAW filter in the positive feedback inner loop at the frequency of maximum modulus. The inner loop gain is denoted as G and is real. This corresponds to the loop gain when all the other components in the loop have unity gain at the frequency corresponding to the maximum modulus of the open loop NRC. In FIG. 69a, FIG. 69b, and FIG. 69c G is increased from 0.5 to 0.7 to 0.9, respectively, showing that the NRC becomes more circular, and that the origin moves closer to one side of the outer encirclement of the NRC.

### Specific Frequency Selection and Bandwidth Adjustments to the SAW

### Adjustments to the Inner Loop of the Dual Loop Architecture

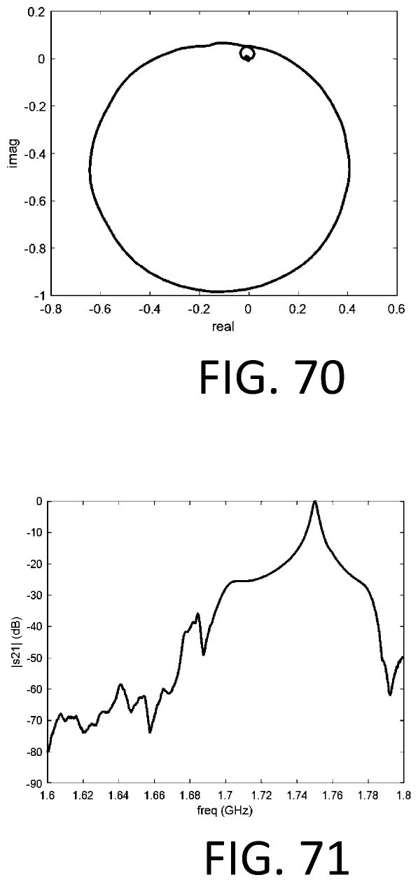

The NRC may be adjusted to be more circular and with the origin moving closer to one side of the outer encirclement of the NRC for a specific frequency within the general passband of the SAW. In FIG. 70, a target frequency of 1.75 GHz is selected by adjusting the inner loop phase for zero phase error (or a multiple of 360 degrees phase shift) at 1.75 GHz. Essentially the only change is that the NRC rotates with a phase rotation such that when the negative feedback of the outer loop is applied, this phase rotation is accounted for. Note however that the shape of the Q enhanced SAW filter converges to this circular shape with the s=0 origin moving toward the outer encirclement of the NRC. This is expected as the Q enhancement results in an approximate equivalence of a single dominant pole which has this general NRC shape.

The frequency plot of the Q enhanced SAW is shown in FIG. 71 indicating the emergence of a narrow passband at 1.75 GHz.

### Adjustments to the Outer Loop of the Dual Loop Architecture

Next, the outer loop of the negative feedback is added in, and in particular, the signal transfer function (STF) from the input to the output of the outer loop, and the noise transfer function (NTF) that is from the output of the inner loop Q enhanced SAW to the output of the outer loop.

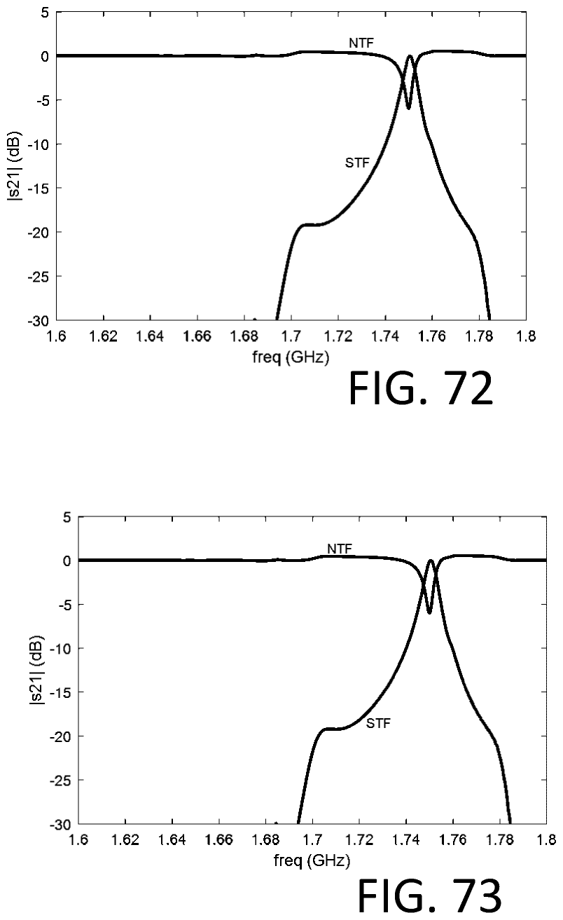

FIG. 72 shows the result of the outer loop with a complex negative feedback of Gₒ=1j. Shown is the STF and the NTF superimposed. Note that complex gain feedback is required to achieve the 90 degree phase shift that depends on the rotation of the NRC.

In FIG. 73 the negative feedback gain is increased to G₀=2j. Note that the rejection of noise is now about 9 dB but this is at the cost of a wider signal passband.

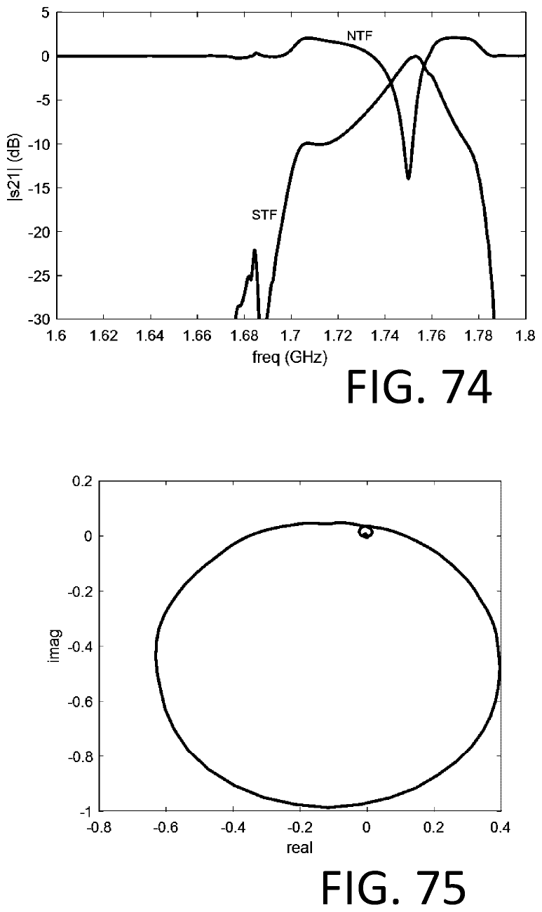

In FIG. 74 the complex negative feedback gain is increased to G₀=4j. Note that the rejection of noise is now about 14 dB, but the passband is increasing.

To narrow the signal passband, the inner positive feedback loop gain can now be increased. In this case it is increased to G=0.93. The NRC of this further Q enhanced SAW is shown in FIG. 75.

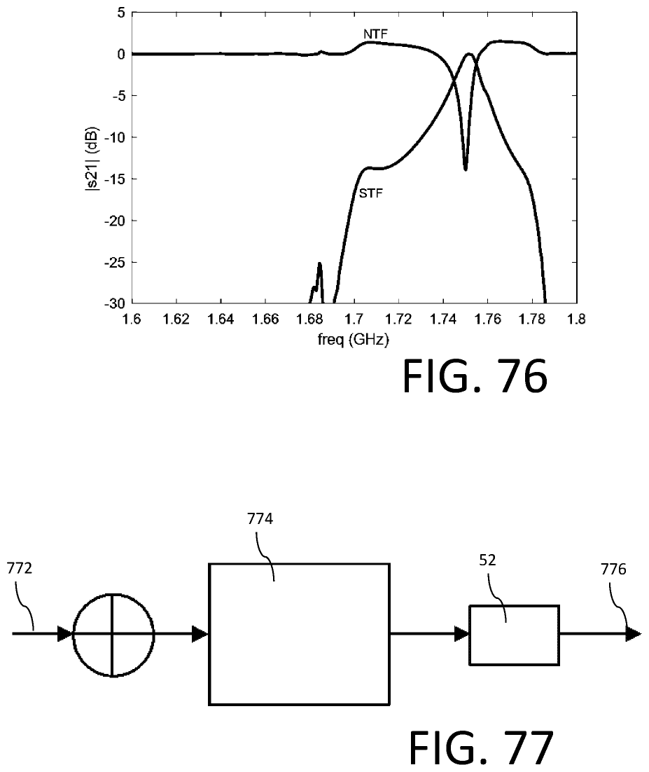

FIG. 76 shows the result in the signal transfer function (STF) and the noise transfer function (NTF), showing that the STF is narrowed for the same 14 dB suppression of the noise.

A point of emphasis is that both loops can be jointly and collaboratively adjusted to achieve the desired reduction of noise, as well as the desired narrow passband for the STF.

### Application of Dual Loop Mixed Signal Processing to a Software Defined Radio (SDR)

### SDR Processing Overview: Receive Mode

The desired signal is referred to herein as S with the interference and noise as N. As shown in FIG. 77, these are summed at the receiver input 772. Next, there is subcircuit block 774 (block A) that digitizes the combined signal such that DSP 52 can be used to extract the information at output 776. S is assumed to occupy a passband of finite width and centered at f_{c}. N has large interference signals but these are outside of the bandpass of S and the additive noise component of N is spectrally uniform.

A problem is that the digitizer block A has
1. Finite sampling frequency
2. Saturates with large signal inputs
3. Introduces quantization noise

Hence some of the information of S is destroyed as it passes through the transformation of the digitization A.

In more abstract terms, the input to the digitizer A is a continuous signal of an infinite number of different states. The output is a finite number of discrete states. With large N, most of these states are used to map the variability of N with only a few effective output states of A for mapping S. Hence much of the information of S is lost. As a tangible example consider the digitizer A to be an ADC that samples the signals with N_{q} quantization levels. The mapping is of the input continuous signal of S+N to the output discrete category. The mapping of the infinite number of continuous states to the finite N_{q} categories represents a loss of information. To see this, if N>>S then the entropy or uncertainty of the mapping of S to the output category is large. Therefore, the mutual information between the input S and the ADC output is low. Herein, mutual information refers to a 1:1 correspondence between sender and receiver on a bit level—sender and receiver mutually agree that the bit sent is identical to the bit received.

In the digitization process, there is a mapping of a region of the continuous signal space to the quantized output that is irreversible. Once the region has been collapsed into one output category this cannot be undone and there is loss in the mutual information. This loss in mutual information can be quantized.

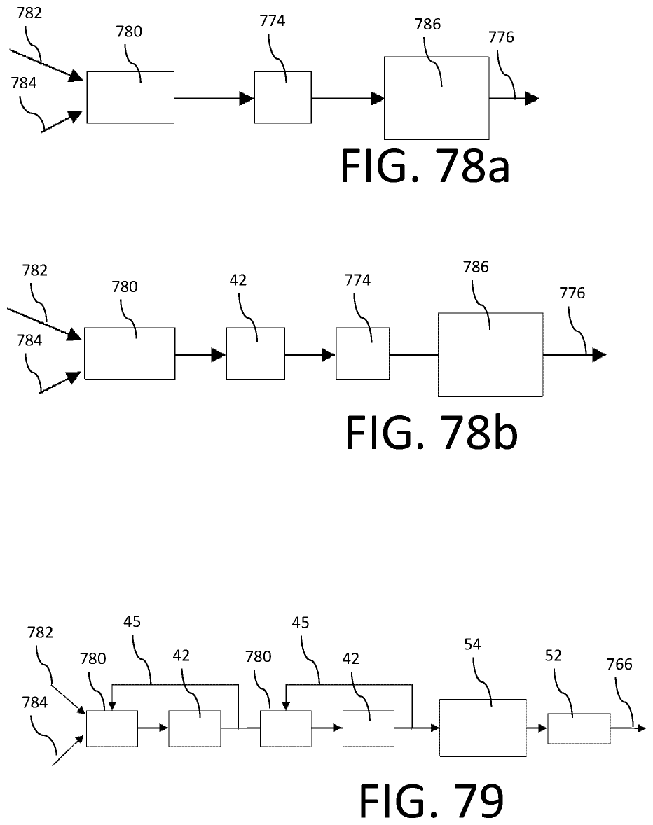

To illustrate this, consider the difference in the receivers in FIG. 78a and FIG. 78b, where the inputs include the desired signal 782 (S) and in-band interference 784 (N) which are shown being input into sum block 780. This in-band interference could be intentional, as in jamming, or could be unintentional noise from any general RF source with in-band energy. In FIG. 78a, S+N is digitized followed by a digital BPF 786 that removes any N outside of the bandwidth of S. In FIG. 78b, S+N is first filtered by bandpass filter (BPF) 42 removing the N outside the bandwidth of S and then sampled by A. In both cases the S, N, and the quantizing of A is the same.

In both circuits, A is responsible for the information loss because of quantization noise. After the quantization of A, it is possible to construct a DSP wherein further loss in mutual information is negligible.

For FIG. 78b, the quantity N is minimized by the BPF 42, resulting in a low loss of mutual information. For the top receiver, N is large leading to a large amount of irreversible loss in mutual information. Thus, the bottom receiver preserves the mutual information better than the top receiver.

The argument being made is that the process that does the mapping from the continuous valued signal to the discrete valued signal is the key component where mutual information is irreversibly lost. Generally, the quantizer may be thought of as an ADC with N_{q} levels. However, it can be more:
a. It can be quadrature sampling
b. It can be sampling after a frequency conversion
c. It can consist of a set of samples that become complex to analyze.

However, the concept is straight forward: take a signal in continuous time and continuous amplitude and map this into a finite number of discrete categories in the digitization process.

The objective is to apply this abstraction to the signal processing circuit 30 such as shown in FIG. 3. The objective of the processing upstream from the ADC may be to ‘protect the ADC’. What is meant by this is conditioning the continuous time signal into the ADC such that the ADC mapping operation results in the minimum loss of mutual information. For the concept of signal processing circuit 30 this is a useful way of thinking about it as the DSP that follows the ADC does not need to be considered. In principle one can quantify the relative performance of the signal processing circuit 30 with other schemes by how much loss in mutual information occurs in the ADC.

The best that can be achieved is a continuous time matched providing a filter output symbol that corresponds perfectly to the symbol of the incoming signal. As an example, consider BPSK that is uncoded and a single bit ADC used. The mutual information loss of the ADC can be zero in this case (depending on the probability density function PDF of S and N). The matched filter provides the signal conditioning, or the ‘protection of the ADC’, such that there is no loss of mutual information in the ADC, and this is for an ADC that is only a single bit.

The ADC may be fixed with a given sampling rate and a fixed number of quantization levels. The BPF resonator may be of fixed modest Q with a bandwidth that is broader than that of S.

Consider that the signal out of BPF 42 can be recirculated back to the beginning for a number of times as shown in FIG. 3 and FIG. 8. The purpose is to reinforce S and to further reduce the out of band components of N.

The effect is to reinforce S with the positive feedback so that it grows in amplitude at the output of the BPF while N only grows where it is in-band. By controlling the amplitude gain of the feedback signal the effective number of times that S goes through the BPF may be effectively controlled. Hence into the quantizer A S is added to S that has gone through the BPF twice and S that has gone through the BPF 3 times and so on up to the effective number of circulations. This is roughly equivalent to the Q enhancement of the feedback resonator BPF that will be denoted as Qₑ. Note that N is limited to about one pass through the BPF as the subsequent passes contribute much less. However, the spectral portion of N that is within the BPF close to f_{c} will become enhanced just as S is.

The benefit is then that the quantization levels of A can be adjusted to best accommodate the larger S. With the reinforcement, S has grown relative to N such that the quantization is dominated by S. Note the limit of this can be that the passband narrows as Qₑ increases to the point that some of S is lost at the outer band edges of S. For an isolated symbol of S there is actually no loss of having an arbitrarily high Qₑ implying a very narrow bandwidth that can be less than the bandwidth of S. However, when a consecutive stream of symbols is considered, this is no longer true as the symbols will begin to mutually interfere. This conflates adjacent symbols leading to information loss.

To avoid this loss, multiple BPF resonators may be used.

An issue is that the recirculating BPF requires gain which comes with noise. Also, the loss through the BPF represents a NF (“noise factor”) due to the thermal noise affecting the components in the loop. This in-band thermal noise is amplified in the same way by reinforcement as S. Hence the NF may be minimized so as not to erode the mutual information of the filtered version of S.

Nonlinearities are interesting as they do not directly lead to information loss. Hence, gain compression that is just a new mapping of S to the output can be had. However, the compression does not result in a conflation of states by itself. However, if the compressed signal is such that quantizer results in conflation of states then there is a loss in information. Also, different frequency components of the signal can be considered. As these are mixed due to a nonlinearity then this is equivalent to conflation of states again leading to information loss

A limitation is that S also sees the feedback path which spoils some of the gain such that the bandwidth of the BPF is effectively broadened. However, it is a balance of the Qe and positive feedback gain G. This can be quantified by evaluating the transfer functions.

This may be extended to having more than one resonator in the loop. Consider two BPFs in series. If the BPFs are at the same center frequency, then one frequency will be emphasized slightly more than any other frequency. After Qe times through the loop then this frequency component will be strongly emphasized, and the overall Q enhance response will appear as a single pole.

If the BPFs are the same then this is roughly equivalent to going through one BPF 2×, 4×, 6× . . . Qₑ2× as opposed to 1×, 2×, . . . Qₑ×. Roughly this is equivalent to having a single BPF but with twice the Q.

If the BPFs are tuned differently, they will still not differ that much as the BPF bandwidth is assumed to be much broader than the Q enhanced bandwidth. Hence there is still going to be one frequency with slightly higher gain that the rest.

If a two pole response is desired, two loops may be used, one around each BPF 42 as in FIG. 79. Two signal enhancing loops are referred to as second order herein and may be inner loops 40. Digital data 792 is extracted from ADC 54 and DSP 52

Now assume that this second order filtering with first and second BPFs 42 are such that the feedback loops favor two different frequencies. Now it can be seen that the Q enhanced response will result in a two pole response. The poles can be placed favorably as described above.

For now, just assume that the two loops are identical. S going through effectively (roughly) Qₑ BPFs in series and then will go through Qₑ BPFs in the second. Again, roughly equivalent to the single BPF having twice the Q. By this approximate equivalence it can also be seen how the overall response can be a two pole response if the BPF loops are tuned slightly differently.

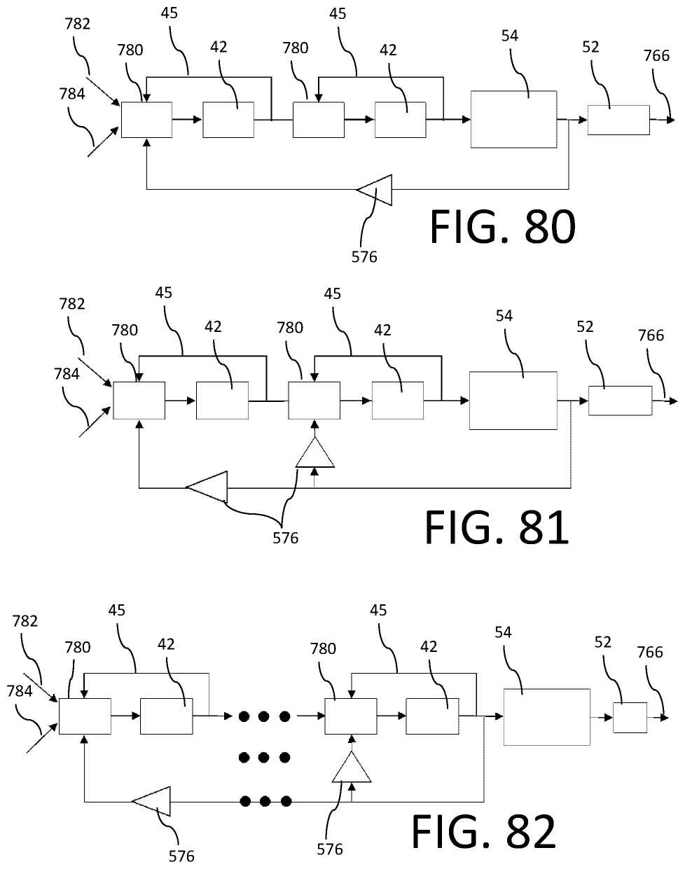

Now consider the negative feedback of the error signal shown in FIG. 80, where a negative feedback 576 of G<0 in feedback loop 55 means a negative feedback which is the opposite of a signal reinforcing feedback.

This gives effectively a double integration of the error signal as the negative feedback goes through the two BPFs 42. To get better control of the negative feedback, the negative feedback 576 can be input at both sum blocks 780 as shown in FIG. 81.

This architecture can be generalized into N BPFs 42 with positive feedback and the N negative feedbacks 576 as shown in FIG. 82.

For the higher order loops, the feedback analogy still applies as it is evident that N passband poles can be placed arbitrarily with tuning. The concept of the negative feedback of the quantization error can be seen to cancel the injected quantization error with a rough equivalence of N integrations. Hence the more BPF poles that are transformed into zeros, then the more control may be had over where the quantization noise is nulled in frequency.

### Receive Side RF Signal Processing Generalization

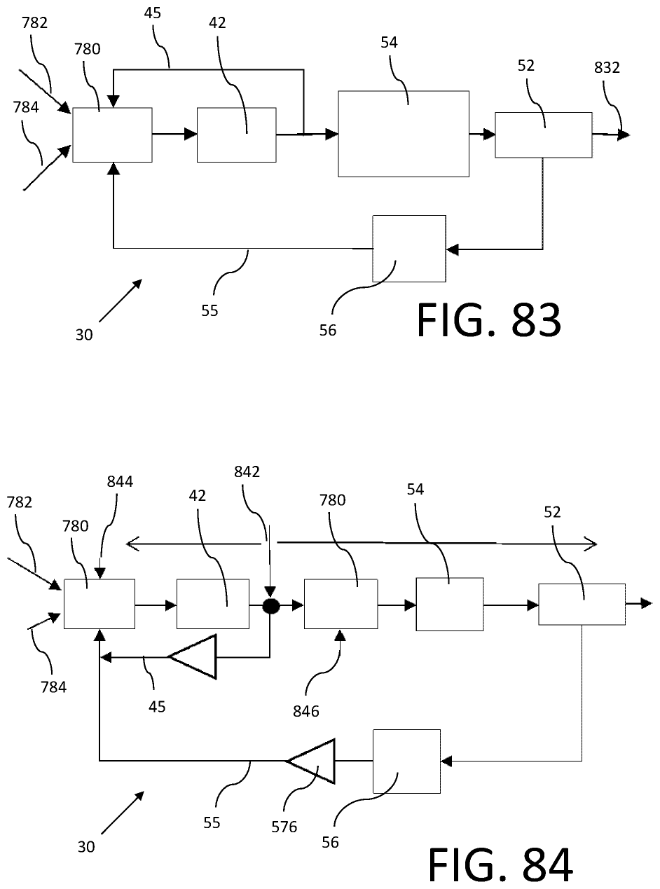

Redrawing FIG. 3 to focus on the different aspects of the dual loop architecture, FIG. 83 is shown.

Here the input is the sum of the desired signal 782 denoted by S which is assumed to reside within the passband of the bandpass filter. The interference and noise signal 784, denoted by N which is assumed to be distributed over a broader range of frequency that S. These signals propagate through band pass filter (BPF) 42. The output of BPF 42 is digitized in the ADC 54, which may contribute quantization noise, and then there is DSP 52 to extract the information from desired signal 782.

The only purpose of the receiver is to process the combination of S and N such that information 832, denoted by I, can be extracted. This information I is related to what is unknown about S that is of interest. For example, in a communications signal sending a sequence of symbols. The symbol carrier frequency fc, symbol shape (and hence its frequency bandwidth) is known. The amplitudes of the symbol corresponding to different bit values are also known. What isn't known is the bit value of the symbol which carries this information. Hence all the processing of the receiver is about abstracting I from the receiver input sample of N+S and I in this case is the bit value.

Given {S+N} there is the theoretical mutual information of I_{M} which is less than I. That is, I is the information of S that could be extracted if there was no N. However due to N there is residual uncertainty in the information abstracted from S which is I_{M}. Note that I_{M} is independent of the receiver processing and that the actual information abstracted from S by the receiver, denoted by I_{R} is less than I_{M}. The optimum receiver is one in which I_{R}=I_{M}. The inefficiency of the receiver is the loss in the information such that could form a FOM of the receiver as FOM=I_{R}/I_{M}. It is necessary to consider the impairments of the receiver components as they contribute to the degradation of the FOM. This leads to the impairment budget for the receiver that lets to tangible specifications for the receiver components. However, the receiver architecture and processing should be evaluated based on the degradation of the FOM and not on an individual specification such as linearity and noise figure.

The performance or merit of the signal processing circuit 30 architecture of FIG. 83 can only be considered as a whole with S+N at the input and IR at the output. Briefly, the concept of signal processing circuit 30 is that the positive feedback loop (inner loop 40) enhances S relative to the out of band components of N such that ADC 54 can digitize the filtered signal such that the information loss of ADC 54 is minimized. A portion of the uncertainty of ADC 54 (due to the quantization noise) can be correlated from one digitizing sample of ADC 54 to the next and therefore be reduced by feeding this back to the front of the receiver through the negative feedback loop (outer loop 50). In this way some of the uncertainty of the ADC can be mitigated which in turn partially restores the information that would otherwise have been lost.

Note that for a practical realization of the positive and negative feedback loop, the loop gain and frequency response has to be designed and managed. Hence positive feedback and negative feedback are concepts related to signal enhancement or reinforcement and loop noise suppression respectively. The output of ADC 54 also goes to a processing block, such as DSP 52, that extracts the information of the signal. Also, BPF 42 is general in that it could be a resonator, multipole filter, filter with poles and zeros. The only real requirement is that it does not have a null within the passband of the desired signal of S and it has some amplitude and phase variation with frequency. It could be for example a delay line with only variation in phase with frequency and no amplitude variation.

In FIG. 84 there is summer 780 in which the signals into the input ports are superimposed at the output port. This is an idealized combining function that is an approximation of what can be realized in a physical RF circuit. Hence it should be understood as a concept of superposition of signals. The physical summer 780 would have some signal losses that need to be accounted for as well as partial signal reflection at the ports of the summer. FIG. 84 also shows a loop tap point 842 after BPF 42 wherein the feedback signal is tapped off. This is an idealized splitter in which the input signal and the two output signals have the same signal amplitude. In the actual splitter the output signals will be of lower amplitude than the input signal such that power is conserved. Also, the realizable splitter will have an additional loss and some signal reflection associated with the signal ports.

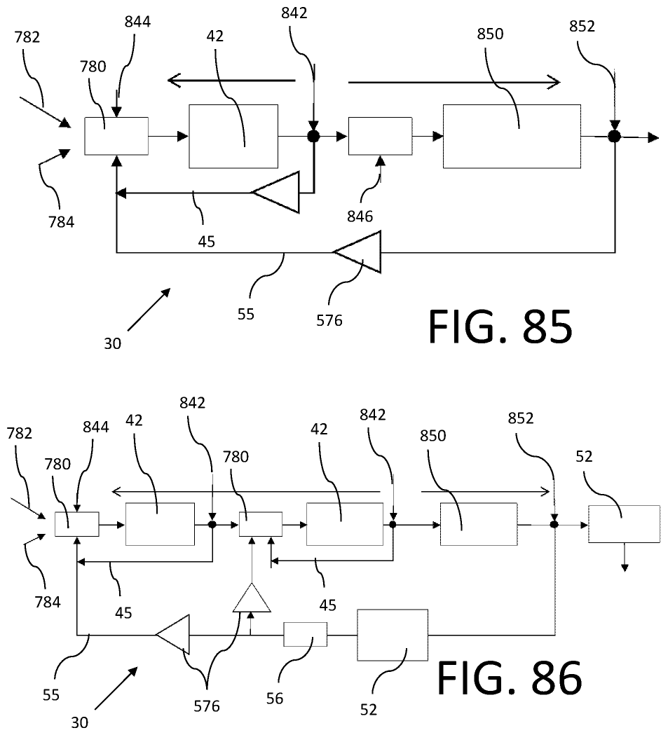

The dual loop concept can be generalized such that there are two types of receiver self-noise that affects the degradation of the FOM. These two types will be denoted here as the upstream and the downstream self-noise. Noise that is generated upstream from the tap point of the positive feedback loop is upstream noise 844 (Nᵤ). Noise that is generated downstream of the tap point of the positive feedback loop is downstream noise 846 (N_{d}). The Nᵤ noise that is outside the bandpass of S can be reduced by the positive feedback loop. The N_{d} noise that is within the bandwidth of S can be suppressed based on the negative feedback loop. This is illustrated in FIG. 85.

This can be generalized further as BPF 42 can be any of the filter components prior to the loop tap point 842 or upstream from the loop tap point 842. It may therefore be assumed an upstream receiver that encompasses BPF 42. Again, as long as the upstream receiver has some phase variation with frequency it can respond appropriately to the positive feedback loop. The upstream noise is N+Nᵤ and Nᵤ can be absorbed into N which will be assumed moving forward. Downstream components 850 can be the remaining receiver components which can consist of further filtering, ADC, frequency translation and so forth. N_{D} is the equivalent noise source being the superposition of all of these sources of downstream noise 846. This is shown in FIG. 85. Note that a DAC may be necessary to include in the negative feedback loop to convert the digitized feedback signal back into analog. The DAC is general and may include a frequency translation.

Signal processing circuit 30 may have a general architecture that has an upstream receiver portion and a downstream receiver portion separated by tap point 842. A signal reinforcing positive feedback path 45 is around the upstream portion and a negative feedback path 55 is around the upstream and downstream portions with a downstream tap point 852 at the output of the downstream components 850.

A further generalization is that the DSP processing block 52 operating on the digitized signal can have two general outputs: one optimized for the negative feedback path 55, and the other being the output leading to the information extraction of the signal S. The equivalent downstream tap point 852 may therefore be within the DSP processing block.

However, the operation of the negative feedback loop is to suppress noise generated within the downstream receiver. The subsequent DSP that takes advantage of the noise suppression also has to pass through downstream tap point 852 of where the feedback signal is taken.

However, there may be additional processing between downstream tap point 852 and the DAC that is not necessarily shared with the processing for the extraction of the information. Therefore, the DSP processing becomes split into two portions. There may be two separate DSP elements incorporated herein. It is possible to perform both functions within a single physical DSP, but the logic would be doing two different functions.

A final generalization realizes that the upstream portion of signal processing circuit 30 may be subdivided with multiple tap points 842 and a sum block 780 at the tap points 842 where portions of the positive and negative feedback loops can be fed back to the input signal loop. This is shown in FIG. 86 by an example with two positive feedback path 45 around bandpass filters 42. The bandpass filters 42 can be signal networks that have at least a phase variation with frequency. Note that N is the noise of the input to the receiver in addition to the equivalent noise of the upstream receivers. The two paths of the negative feedback path 55 may have different gain.

The mixed signal processing may rely upon both positive and feedback loop, with the BPF sharing a common leg of both loops:
1. The plurality of positive feedback loops is for the progressive enhancement of S with reinforcement feedback.
2. The purpose of the negative feedback loop is for suppression of the self-noise that originates in the downstream receiver that is within the bandwidth of S.

The essence of the disclosure is the apparatus of these two nested mixed signal processing loops and the methodology of how to use them. By balancing these two loops the information of the desired signal can be optimally preserved.

### Anti-Aliasing

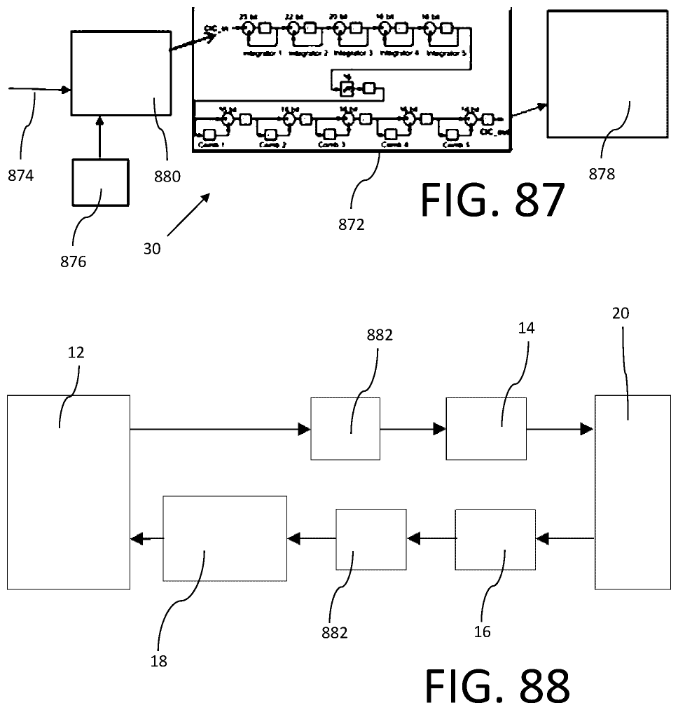

An efficient anti-aliasing filter (AAF) 870 with decimation is the cascaded integrator comb (CIC) filter 872, an optimized class of finite impulse response (FIR) filters combined with an interpolator or decimator. An example of a CIC 872 implemented architecture is shown in FIG. 87, which has an input from an ADC 874, a numerically controller oscillator 876, and further filtering, data symbol correlation 878, and down-conversion 880.

The advantage of anti-aliasing filter 870 is that the integrators are simple to implement and require no overload logic. The CIC 872 implementation can be generic as there are few configuration parameters to vary. However, the few configurable parameters also implies that the filter is not very tunable for specific RF signal modulations. Additionally, it is located after the ADC 54 which does not reduce the ADC 54 processing load. Hence this is limited to the AAF implementations which have to be highly efficient and are generally followed with an equalization filter post-decimation. As will be discussed below, the complexity of this CIC implementation may not be warranted.

### Rudimentary Anti-Aliasing

To implement rudimentary receive side anti-aliasing in current DSDR architectures, one can add low pass filters (LPF) before the ADC of the DSDR architecture of FIG. 2. A fixed LPF 882 acts as an anti-aliasing filter based on a bandwidth of half the sampling rate of the ADC. A block diagram for a direct sampling high giga-samples/sec architecture 880, showing the LPF 882 is seen in FIG. 88.

Note that antenna 12 is not effective for low frequencies and hence the combination of the antenna and LPF in the receive side provide a broad bandwidth filter prior to digitization. In the transmit side of FIG. 2, DAC 16 takes the signal samples and converts these to an RF signal. LPF 882 removes DAC 16 high frequency artifacts. This signal is amplified and transmitted.

Additionally, on the transmit side, the system DSP 20 of FIG. 2 generates a bandpass signal incorporating the input information, converts this to analog, provides a bandpass RF filter to clean up the signal, and then the filtered RF signal is amplified and transmitted. It is the high Q narrow bandwidth tunable response of the positive feedback loop, and extensions thereof, that allows for this anti-aliasing implementation.

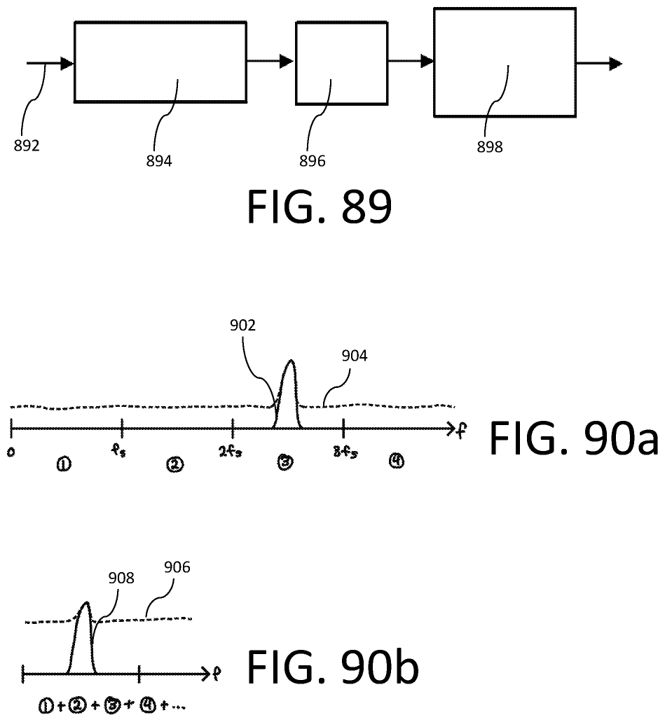

The positive feedback loop of FIG. 2 may be redrawn as a simple line-up of three components on the receive side as shown in FIG. 89, which has signal source input 892, which might be an antenna or a connection into an RF system wherein the desired signal is to be processed, a narrowband filter consisting of a network of filter components 894, a sampling device (ADC) 896 and a DSP 898 for post detection processing.

It may be advantageous to have the anti-aliasing filter at baseband as complex coefficient multiplication is not required and it is the pre-decimation operations that generally dominate the overall DSP related power requirements, although the CIC integrators are very efficient and can be used in general. However, this is not always possible due to band mapping in the down conversion that can be a significant contributor to overall noise. The final decimation ratio can be high enough that subsequent DSP is at a much-reduced clock rate and hence less of a concern in terms of power dissipation.

### Frequency Band-Folding in the Positive Feedback Loop

An attribute of the positive feedback loop is that it can form the stable high Q pole necessary for avoiding all aliasing noise and reducing the band mapping complexity prior to down conversion using an anti-aliasing filter, is the use of band-folding illustrated in FIGS. 90a and 90b, a method to eliminate aliasing with negligible spectral regrowth while conserving power.

Band folding is based upon the Nyquist frequency N_{f}=1/Δt, where t is the time increment between observations. Note that the Nyquist frequency is a property of a discrete-time system, while the Nyquist rate is a property of a continuous-time signal.

Any accumulation of excess noise in the folding can be looked at. In the ADC sampling where frequency bands that are multiplies of the sampling frequency are folded, the sampling output is a superposition of the aggregate of these folded bands. However, as only one of the folded bands contains signal, there is no accumulation of excess noise.

To avoid aliasing noise, it is necessary that:
1. The RF filter have negligible out of band spectral regrowth, and
2. The RF filter frequency selectivity is sufficiently tight around the desired signal.

FIG. 90a shows the presence of both the frequency aliases and noise 904 that may overlay the desired signal 902.

FIG. 90b illustrates the impact of the filter resulting in removal of spectral content in the folded bands except for the band that contains the desired signal. Line 906 is the folded bands without the filter, and line 908 is the folded bands with the filter. The filter can be sufficiently narrowband with no spectral regrowth, as a result of high frequency selectivity, such that there is no aliasing distortion in the ADC samples.

Hence the ADC does not have to expend additional quantization and dynamic range on these unwanted signals.

### Dynamic Range Considerations

The limitation with FIG. 3 is that the digitization, in both the receive and transmit directions, may have sufficient dynamic range to digitize the broad bandwidth of the input signals. All the noise and interference signals may be digitized along with the desired signal. The quantization noise in digitizing the desired signal may not be a main contributor to the limitation of the achievable SNR. For this reason, the ADC may have a moderate number of bits of quantization as well as high sampling rate. Additionally, dynamic range in the DSP may be preserved.

Every DSP operation prior to bandpass filtering to remove the out of band frequency content will add quantization noise and will degrade the dynamic range. Hence these initial DSP processing steps can be very intensive.

On the transmit side, the signal samples are generated at the RF passband and converted to analog. This is a highly intensive DSP process because the DAC only has the subsequent LPF to remove conversion artifacts. Hence the DSP and DAC may process samples of low quantization noise which again implies a moderate number of bits. This limits the processing of FIG. 3 to applications where such high speed conversion and intensive DSP, with concomitant DSP power consumption, can be tolerated.

For the objective SDR to become a reality, without excessive performance required of the ADC, DAC and DSP, typically a dynamic range, a tunable narrow passband filter architecture is desired which provides active Q enhancement that is robust and stable to enable desired signal extraction and mitigate nearby interferers.

The upstream signal loop may be programmed and controlled to provide an arbitrarily high Q of several thousand. Hence, all the filtering can be done in this tunable high Q bandpass filter to isolate the desired signal and eliminate all of the out of band interference, prior to band digitization and the DSP.

### Positive Feedback Loop Timing Jitter Reduction

The distortion of the SH and gate clock jitter become very critical in realizing an SDR of acceptable performance. The matched filter output will have a high rate of change of signal voltage with time (dv/dt) during the aperture time. This requires a very short aperture time for adequate sample definition which significantly restricts the clock jitter that can be tolerated. For instance, take a GPS signal wherein the bandwidth is about 1.2 MHz, and the data is at a 50 Hz rate such that T is 20 msec. With a suitable SH capable of operating at the carrier of 1.5 GHz, the ADC and DSP can be provided by a very slow processor such as an Arduino as the symbol rate is only 50 Hz. However, if the signal were to be sampled at the rate of 1/T, the dv/dt at the sampling point is related to a signal with a bandwidth of 1.2 MHz. Hence the aperture time of the ADC sampling the baseband GPS chip level matched filter output can only be several 10s of nsec. But this requirement pales in comparison with the 1.5 GHz carrier rate in the DSDR that changes significantly in a few tens of psec. It is the aperture time jitter that ultimately limits what can be achieved with reduced rate sampling.

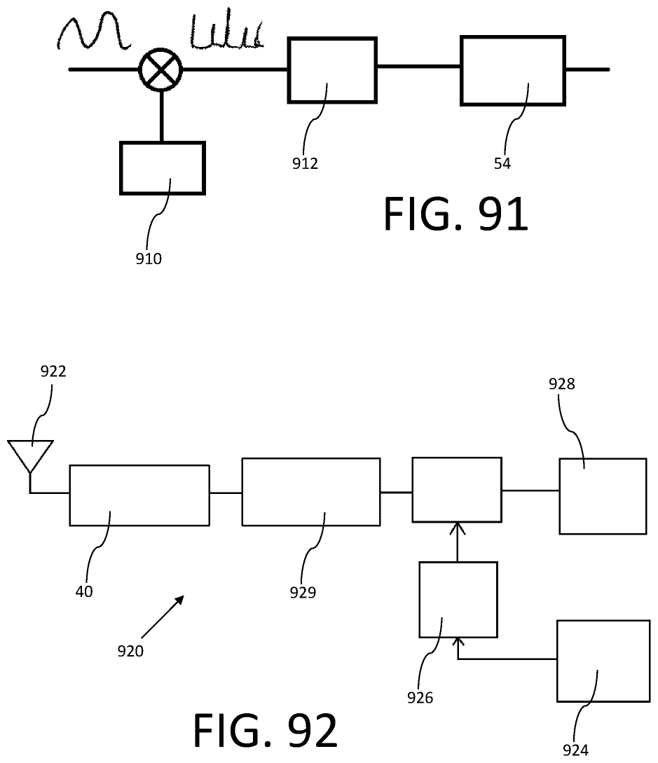

Referring to FIG. 91, consider the scheme where the carrier is down converted prior to the ADC sampling using a local oscillator 910. After the down conversion there is a LPF 912 that has a bandwidth of the signal which roughly averages the samples within a time constant that is the reciprocal of this bandwidth. Then the ADC sampling at the Nyquist rate of twice this LPF bandwidth. The down-conversion by the carrier can be considered and the LPF as sampling the initial bandpass signal once per cycle and then short-term averaging these samples with a time constant that is consistent with that of the LPF. Then the output of this short-term averaging is sampled.

The LO shown is an impulse train at the same rate as the carrier. The jitter is independent from one LO impulse to the next which leads to voltage noise in the samples of (dv/dt)dt. However, as these are independent then in the LPF following the downconversion, the jitter is averaged out. As an example, consider a carrier of 10 GHz and a LPF bandwidth of 10 MHz. Then the down conversion is equivalent to an averaging of 1000 jitter sourced noise samples leading to virtually an elimination of the sampling jitter issue. The remaining noise is the low frequency phase noise of the LO clocking.

Jitter reduction may also be achieved by oversampling the ADC. This is the same function as the frequency down conversion. Say the 10 GHz carrier signal is sampled at 10 GHz and then average the ADC samples and decimate. Again, there are 1000 samples of jitter sourced noise that is averaged for an elimination of the jitter noise.

But an over-sampling ratio of 1000 is generally excessive in terms of eliminating jitter noise. Instead a reduced ADC sampling rate of say 1 GHz for a 100 sample averaged may be considered. Hence the RF BPF can be set to only include the 10 MHz bandwidth of the desired signal. This eliminates any excess noise due to band folding. The ADC sample rate can be set as low as 1/T if the upstream signal loop may be a sufficient matched filter and if sampling jitter is not a problem. If jitter is a problem, then the ADC rate can be increased such that sufficient averaging of the jitter can be achieved to meet a specification. This specification is going to be loose for simple modulations such as BPSK (Binary Phase Shift Keying) and QPSK (Quadrature Phase Shift Keying) but tight for complex QAM constellations of high order.

Consequently, the upstream signal loop may potentially provide an adequate matched filter response such that the sampling rate can be as low as 1/T. For cases where sampling clock jitter is an issue, the ADC sampling rate can be increased beyond 1/T to allow for sample averaging. Also, the upstream signal loop may be used in conjunction with an LO down conversion prior to the ADC sampling which achieves a similar effect. As an example, the LO down conversion to a baseband signal and commensurate ADC sampling is equivalent to high-speed sampling at once per RF cycle and then averaging with a ratio of the carrier frequency to the bandwidth of the desired signal. In other words, the inclusion of the upstream signal loop in the DSDR allows for setting the ADC sampling rate depending on the clock jitter reduction required to help meet overall SNR requirements, more typically expressed as the Eb/No requirement.

There is more to the matched filter concept in that the quantization requirements of the ADC can be significantly reduced. Consider BPSK as an example where it is of interest if the symbol amplitude is positive or negative. Referring to FIG. 92, a BPSK receiver 920 is shown with signal 922 filtered with the upstream signal loop 40 configured as a matched filter. The ADC is a simple comparator with a carrier track 924, a clock 926, data output 928, and sample and hold 929 The sample time is based on a clock output controlled by a carrier and symbol clock synchronization scheme. As the BPSK is relatively robust to jitter, it is likely that the ADC sampling rate only needs to be 1/T. No excess sampling is required to reduce the jitter.

In more sophisticated receiver processing, coding would be applied over a set of BPSK symbols. For higher performance it is necessary to use schemes such as soft decoding and in this case the ADC may be needed that has a few quantization levels. An AGC feedback is required in this case. However, the number of ADC levels is no larger than the advantage gained by the soft decoding. That is 4 levels of quantization may be sufficient and that adding more is diminishing returns. Also, if jitter is excessive then a down conversion can be added in front of the ADC eliminating this issue, or simply sampling the comparator faster and averaging.

Next consider QPSK which is just two orthogonal channels of BPSK. A 2/T aggregate sampling rate may be used to provide for the quadrature sampling required. This can be conveniently implemented with a hybrid device at the output of the upstream signal loop that gives the in-phase and quadrature phase components. For the QPSK comparators can still replace the ADC as the base signal is BPSK. Extending this if an N by N QAM constellation is considered then only an N level ADC is need of log₂(N) bits.

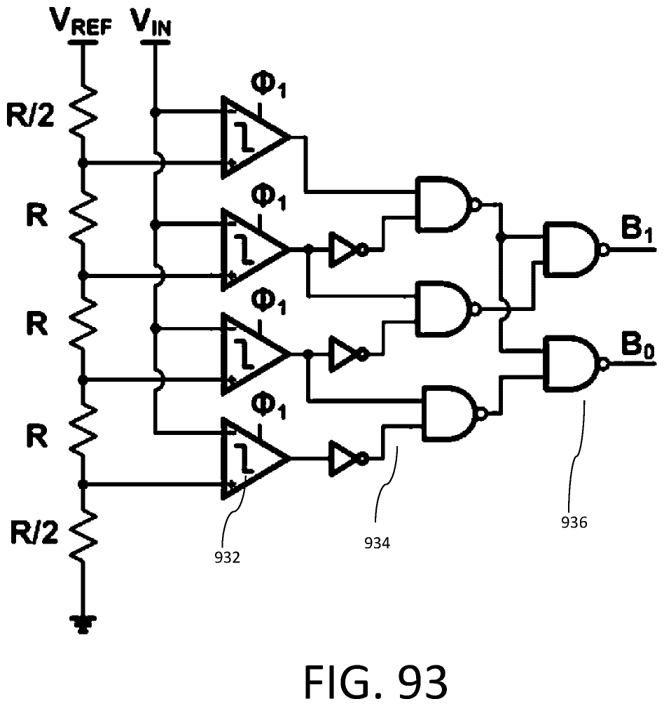

QAM modulation is very common for high rate communications signals. For such schemes there is information impressed into the amplitude and single bit quantization is not sufficient. However, the ADC can be implemented for a QAM scheme wherein the number of ADC levels is equivalent to the number of QAM levels. Hence for 64 QAM only an 8 level ADC and DAC is necessary with is 3 bits. This can be achieved with a high speed flash convertor, an example of which is shown in FIG. 93 and has input quantization 932, bubble error correction 934, and digital encoding 936.

A key point is that the upstream signal loop may be a resonator that is sufficiently narrow that only the desired signal, with some in-band noise and interference, makes it to the quantizer. The symbol decoder is therefore the output of the quantizer/accumulator/decimation process. If equalization is required for minimizing ISI and providing a matched filter response, then the upstream signal loop can be tuned directly. In this case, an additional DSP based equalizer may not be required.

There exist modulation signals where such an ADC/DAC with few fixed quantization levels is not sufficient. For example, consider the LTE modulations where multiple signals are superimposed, and the signal amplitude sample has more of a gaussian distribution. For such signals, more quantization levels may be necessary especially if the SNR in-band is quite high. In this case the quantization noise may become a dominant contribution to the overall noise and unrecoverable distortion which is undesirable.

In summary, the reduced sampling rate of 1/T has been considered while the carrier frequency can be arbitrarily high. The Jitter issue with the noise sensitivity of (dv/dt)dt has been considered as a limitation. A further limitation that needs consideration is the sample and hold (SH) device. There are practical limitations in the SH as the ratio of the sample hold time to aperture time cannot be arbitrarily large. Advanced SH devices use a cascade of switches and holding capacitors to increase this ratio but with the penalty of contributing to the overall sampling noise and distortion. As the ratio becomes large it may be necessary to use a faster ADC with an aperture time that is commensurate with the limitations of the SH.

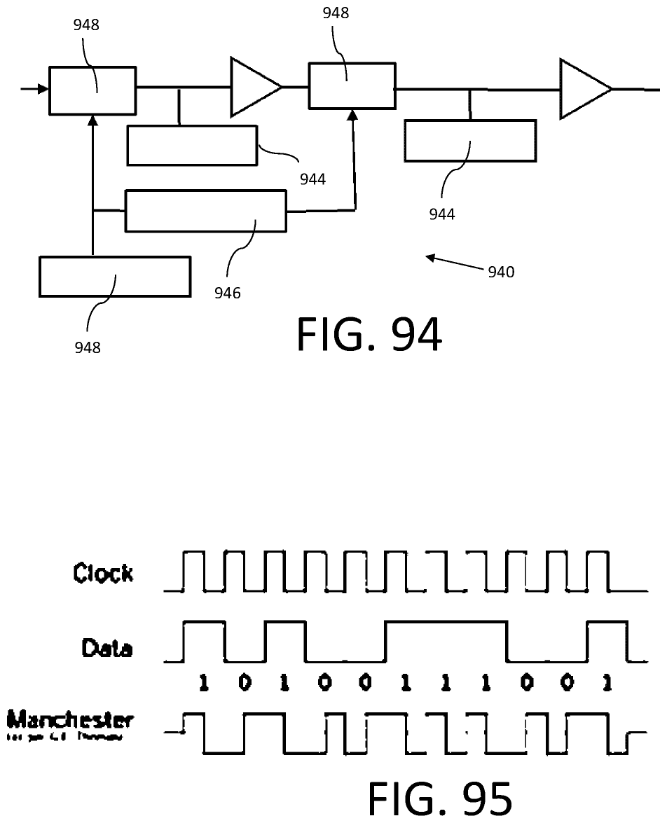

Once the faster ADC is included then the sampling rate can be increased at the modest expense of a faster DSP clock. A multi-stage circuit 940 for increasing the ratio of hold time to aperture time is shown in FIG. 94, which has switches 942, holding capacitors 944, pulse stretcher 946, and clock gate signal 948.

While the matched filter can in principle be achieved with a set of poles of the upstream signal loop, there may be limitations. Creating an all-pole approximation to the root raised cosine filter is achievable but creating a barker code impulse response of a spread spectrum signal is not possible without zeros. Zeros can be generated in the upstream signal loop by placing some components in parallel. However, controlling the position of the zeros may be difficult. Hence the matched filter may be split into an analog and a digital component. Take the Barker code as an example. The matched filter corresponding to the chip is done in the upstream signal loop and the barker correlation is done in the DSP. The sampled bandwidth in this case is the chip rate and not the symbol rate.

Consider the spread spectrum code as consisting of a small segment convolved with a larger segment. A simple example is the Manchester code which is often used to guarantee a zero average value regardless of the data. An example is shown in FIG. 95 the sub-code element is (1,−1). Note that the upstream signal loop may be arranged to provide an impulse response that would reproduce the (1,−1) segment. An implementation may consist of two arms, one with a bandpass filter in it and another with a cascade of a bandpass filter and a delay. The outputs of the two arms are combined. Note that the poles of this circuit remain the same but the combination of the outputs of the two arms leads to a manipulation of the zeros.

Consider a communications receiver where there is an incoming data modulated symbol which is subjected to noise and interference. The receiver needs to process this signal by aligning to the symbol component of the incoming signal while remaining ideally orthogonal to the noise component. This is easily visualized in the signal space where the processing of the receiver is along the symbol basis function. The noise is assumed to be equally distributed over all the orthogonal signal basis function of the signal space. This leads to symbol correlation in the time domain and a frequency matched filter in the frequency domain perspectives.

The most complex symbol of phase and amplitude data modulation of duration T implies the minimum sampling rate of 1/T. Note that the symbol time is not necessarily inversely related to the bandwidth of the individual symbol pulse shape signal and can, in fact, be less. For example, a spread spectrum coded symbol as used in CDMA can have a significantly larger bandwidth than 1/T.

An additional utility of the disclosed architecture is that the poles of the upstream signal loop may be positioned such that the frequency response or impulse response of the filter is matched to the data symbol resulting in a matched filter as discussed above. The ADC can sub-sample at the lowest possible rate of the data signal symbol rate. Note that the symbol rate of 1/T can be lower than the actual Fourier bandwidth of the data symbol itself. However, this low sample rate is only possible if the RF filter is precisely centered on the desired signal. Such accuracy is achieved with the upstream signal loop through calibration and run-time adaptive feedback tuning.

Removal of Self-Generated Processing Noise from RF Signal Processing Using a Negative Feedback Outer Loop

There will be considered a dual loop architecture as described above and depicted in, for example, FIG. 3.

The positive feedback loop (or upper loop 40), which may consist of multiple resonators, may act as a tunable bandpass filter based on active feedback. Loop components may have a high linearity when based on switched reactive components, in comparison with varactors that may introduce non-linearity effects. The resonators are placed upstream of the down conversion and ADC which are vulnerable to large out of band signals and broadband noise. The resonators may be operated to provide poles of moderate Q of around 100 that provide for very effective bandpass filtering to suppress most of the undesired noise and interference entering the down conversion and ADC.

Turning to the negative feedback loop of FIG. 3, the implementation of DSP 52 within the FEM module enables the following features:
1. Independent placement of the positive feedback loop resonator poles as discussed above
2. Moves quantization noise out of the signal passband

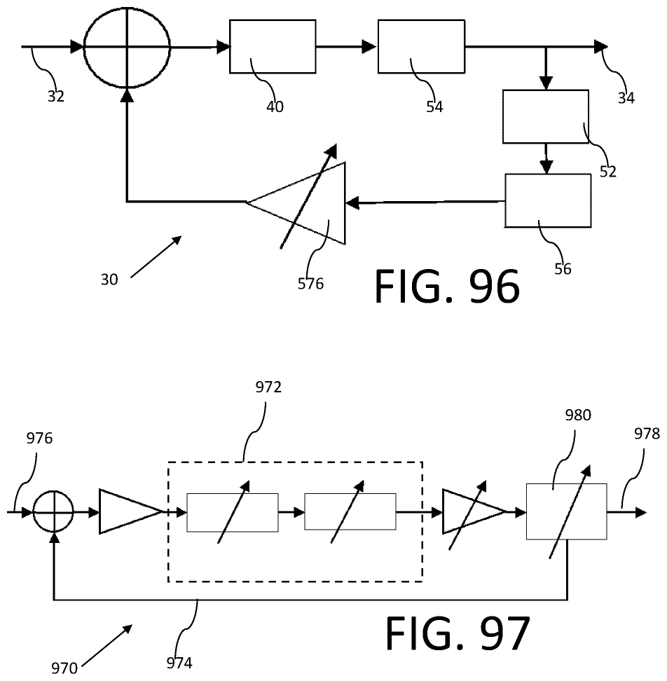

For reference, signal processing circuit is shown in FIG. 96.

The key aspect of quantization noise removal may be to implement a variable bandpass delta-sigma modulation approach which moves the quantization noise out of the signal frequency band. Delta-sigma modulation (DSM) is a well-known fixed frequency scheme.

Down converting the signal+noise input to baseband yields the baseband delta-sigma with an integrator providing a pole at s=0 is prior art. When operation of the direct sampling is shifted using a bandpass filter with a center frequency of fc, the integrator is now replaced with a resonator centered at frequency fc. This results in a bandpass delta-sigma modulator (BP-DSM).

A problem for a broadband BP-DSM to get a tunable resonator with sufficient Q. Because current BP-DSM implementations are at fixed bandpass center frequency and thereby not tunable, the BP-DSM is not currently used at RF/microwave frequencies. However, the upstream loop changes this when provided with a tunable resonator that can change frequency while providing a high and stable Q independent of the frequency change. In this implementation, the resonator may be shared by both the positive feedback and the negative feedback loop, creating a variable bandpass frequency delta-sigma modulation (VBP-DSM) scheme 970.

Referring to FIG. 97, the diagram of VBP-DSM 970 may be drawn as a resonator with an analog positive feedback loop (upstream signal loop 108), a negative feedback outer loop 974, which may be digitized, input 976, output 978 and phase shifter 980.

### Variable Bandpass Delta-Sigma

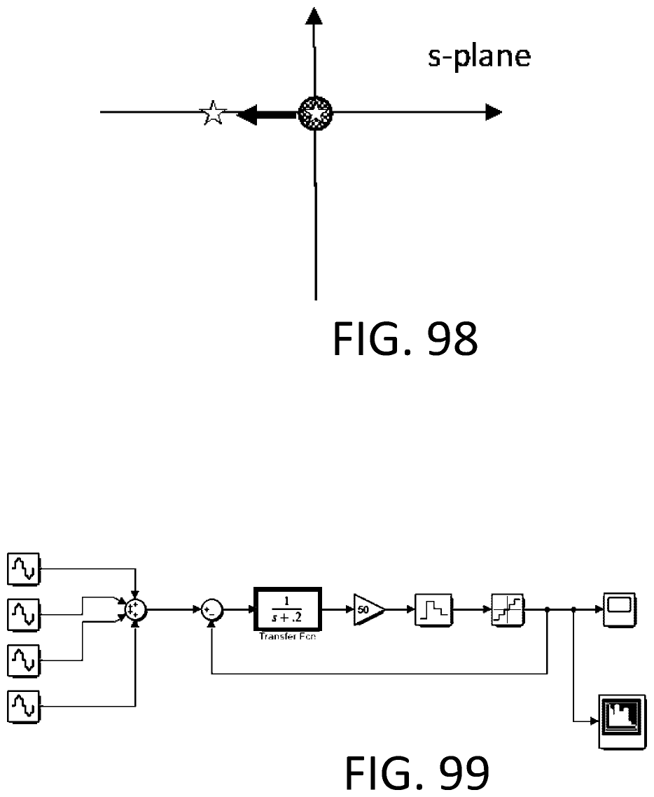

A feedback path may be used for implementing a variable bandpass delta-sigma. In this case the pole of the upstream signal loop becomes a zero of the QNTF. The movement of the dominant resonator poles in the VBP-DSM is illustrated in FIG. 98. Important notes relative to FIG. 98 are:
1. The filter pole is indicated by the star and also forms the zero of the QNTF.
2. This zero (dashed line circle) cannot be moved by feedback.
3. However, the pole of the QNTF starts in the same position as the zero and thereby cancels the effect.
4. The pole may be moved away from the zero in order for the zero to have any effect.

It is important to note that with negative feedback (Q spoiling) the pole may be moved to the left, hence separating the upstream signal loop pole from the zero. The system effect of the negative feedback loop will be further discussed later.

The effect is that the QNTF zero now reduces the response in the middle of the passband. As also observed is that it is necessary that the pole has a high Q prior to forming the feedback loop. This is what limits the application of delta-sigma. However, with the upstream signal loop, the Q may be increased such that the QNTF zero becomes relevant.

Consider the VBP-DSM with a general bandpass filter of

$${H}_{f} ( s ) = \frac{{N}_{f} ( s )}{{D}_{f} ( s )}$$

The closed loop response of the filter is given as

$${H}_{CL} ( s ) = \frac{\frac{{N}_{f} ( s )}{{D}_{f} ( s )}}{1 + G \frac{{N}_{f} ( s )}{{D}_{f} ( s )}} = \frac{{N}_{f} ( s )}{{D}_{f} ( s ) + {GN}_{f} ( s )}$$

where G denotes the feedback. The transfer function of the quantization noise is given as

$${H}_{QNTF} ( s ) = \frac{1}{1 + G \frac{{N}_{f} ( s )}{{D}_{f} ( s )}} = \frac{{D}_{f} ( s )}{{D}_{f} ( s ) + {GN}_{f} ( s )}$$

which shows the poles of the filters being mapped into the QNTF zeros as discussed before. However, consider the ratio of the closed loop signal to the quantization noise:

$$\frac{{H}_{CL} ( s )}{{H}_{QNTF} ( s )} = \frac{{N}_{f} ( s )}{{D}_{f} ( s )}$$

which is just the filter transfer function that is independent of the feedback level G. It can be seen that increasing G decreases both a) the level of the signal reaching the ADC as well as b) the quantization noise. Hence the important result that the VBP-DSM allows a reduction of the signal level into the ADC without an increase in the effective NF of the receiver.

The negative feedback loop will nominally have a very narrow passband. Hence the analysis can be simplified as an equivalent complex envelope analysis. The integrator pole is shifted from the origin along the real axis into the LHP.

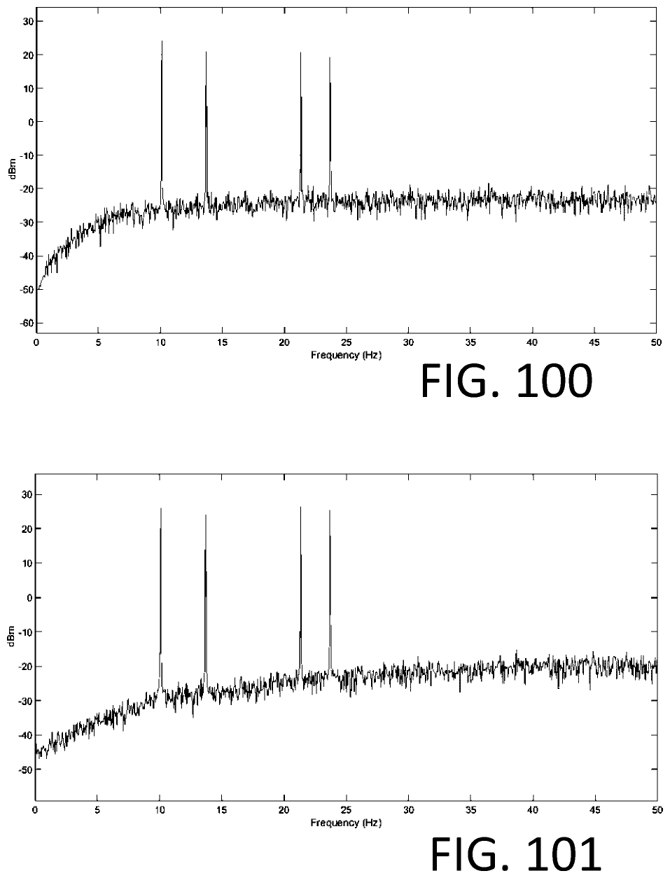

FIG. 99 represents a Simulink model 990 of a bandpass VB-DSM with an equivalent resonator pole at s=−0.2, which may be considered to represent the response of a a leaky integrator, with the performance shown in FIG. 100 with:

$${H}_{res} ( s ) = ( \frac{2}{s + 0.2} )$$

As the upstream signal loop pole is moved more to the left with the negative feedback, then the efficacy of the delta-sigma in terms of reducing the quantization noise is reduced. In this case:

$${H}_{res} ( s ) = ( \frac{2}{s + 10} )$$

with simulation results shown in FIG. 101.

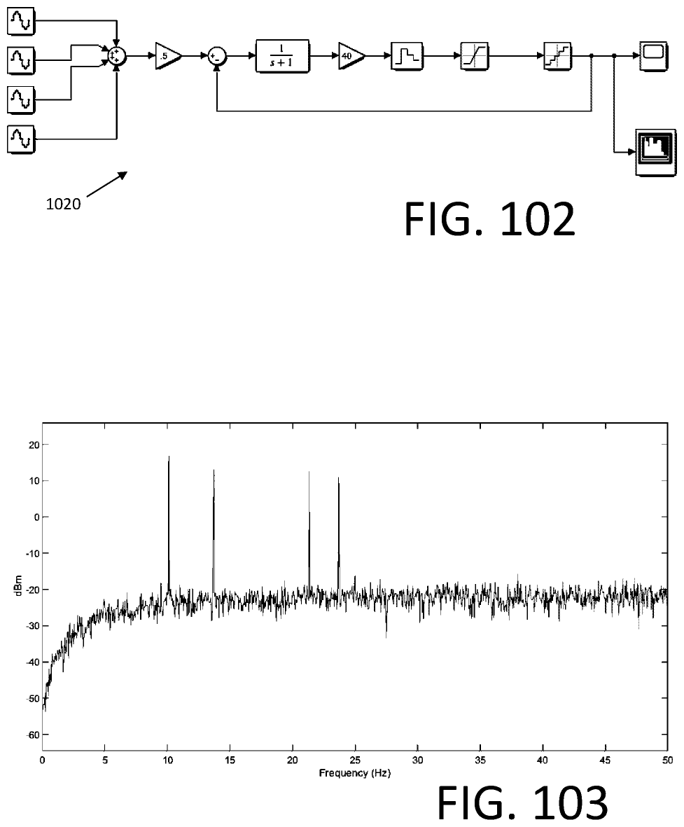

Adding in saturation of the ADC mitigation, as discussed below, there is a Simulink model 1020 of FIG. 102, with simulation results shown in FIG. 103.

### First Order Negative Feedback Loop Implementation

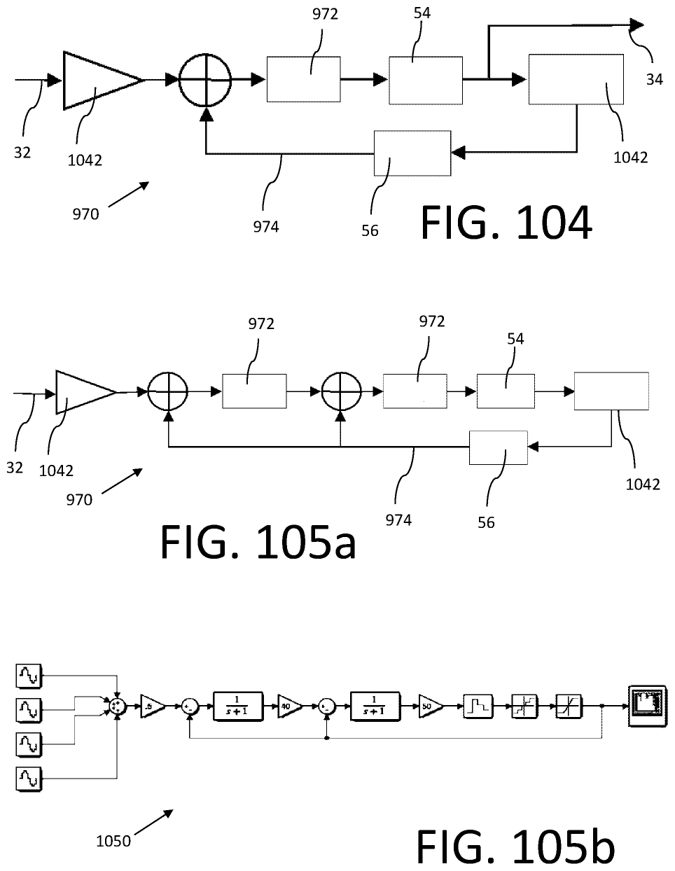

Next consider how the negative feedback loop is implemented to realize a first order VBP-DSM 970 with one upstream signal loop 972 as shown in FIG. 104. Upstream signal loop is Q enhanced to form a pole with a Q of about 100. This is in a feedback loop 974 with ADC 54, DAC 56 and a discrete filter transfer function 1042 of H(z). H(z) may only include the gain and perhaps some delay to model the pipeline delay of ADC 54 and DAC 56. Signal input 32 may pass through a low noise amplifier 1042.

Clearly the ADC/DAC do not have to be direct sampling and may include frequency translation, with the following considerations:
If direct sampling is implemented, then upstream signal loop 972 may be used to protect the down conversion mixer from the out of band interference. An LPF may be added in this case to provide arbitrary poles needed for the delta-sigma.
The chip integrated down-conversion mixer may have a vulnerability in that the NF is generally high at about 14 dB. This comes from the way the LO in the mixer switches the FETs. During the transition there is a quasi-linear period where the output is essentially linearly amplified LO noise. The mixer noise adds significantly to the quantization noise as described above. However, the combined mixer and quantization noise can be approximated as being statistically independent from the desired input signal and can therefore be reduced with VBP-DSM processing.

### Second Order Negative Feedback Loop Implementation

A second order loop with two upstream signal loops 972 is possible as shown in FIG. 105a, with a Simulink model 1050 shown in FIG. 105b.

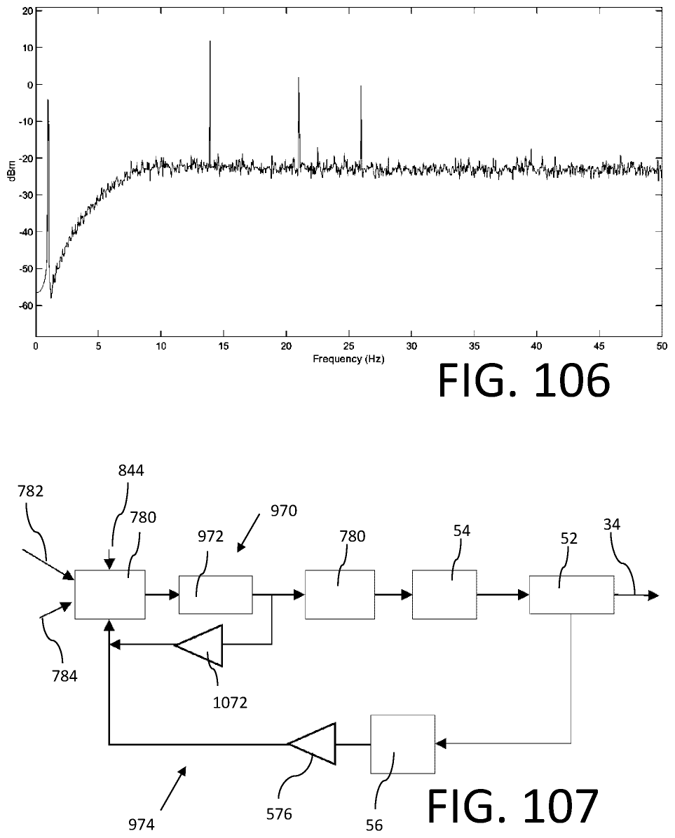

With the saturation at 0.5 and −0.5, and the input gain set at 0.5, the second order loop provides good attenuation of the quantization noise as shown in FIG. 106. Again the quantization is with an interval of 0.2 such that the levels are {−0.5,−0.3,−0.1,0.1,0.3,0.5}.

Add an AGC-like control that that operates to reduce the gain if saturation of the ADC is sensed. As before, the gain is reduced ahead of the ADC which has the same effect as increasing the quantization step but allowing the saturation level to increase.

### Adding Additional Poles to the Delta-Sigma

Next consider the possibility of adding additional poles in H(z) in the ΔΣ. Let

$${H}_{d} ( s ) = \frac{{N}_{d} ( s )}{{D}_{d} ( s )}$$

be the delta-sigma filter that is mapped into the s domain. Now the signal path is given as

$${H}_{CL} ( s ) = \frac{\frac{{N}_{f} ( s )}{{D}_{f} ( s )}}{1 + G \frac{{N}_{d} ( s )}{{D}_{d} ( s )} \frac{{N}_{f} ( s )}{{D}_{f} ( s )}} = \frac{{N}_{f} ( s ) {D}_{d} ( s )}{{D}_{f} ( s ) {D}_{d} ( s ) + {GN}_{f} ( s ) {N}_{d} ( s )}$$

Now the QNTF is given as

$${H}_{QNTF} ( s ) = \frac{1}{1 + G \frac{{N}_{d} ( s )}{{D}_{d} ( s )} \frac{{N}_{f} ( s )}{{D}_{f} ( s )}} = \frac{{D}_{f} ( s ) {D}_{d} ( s )}{{D}_{f} ( s ) {D}_{d} ( s ) + {GN}_{f} ( s ) {N}_{d} ( s )}$$

From this it is clear that additional zeros in the QNTF can be contributed by the VBP-DSM filter. Also, the ratio is

$$\frac{{H}_{CL} ( s )}{{H}_{QNTF} ( s )} = \frac{{N}_{f} ( s )}{{D}_{f} ( s )}$$

as before. Hence, additional poles may be added in the VBP-DSM filter that will provide different closed loop responses without affecting the ratio of the input signal level to the quantization level. This provides additional design flexibility.
Delta-Sigma Modulator with Variable Frequency and Q

The dual loop circuit may be represented by upstream signal loop 970 acting as a BPF with a positive feedback gain 1072 (G>0) in the feedback path 1074, and a negative feedback loop 974 as shown in FIG. 107. From the input signal perspective, the signal sees a bandpass pole of net Q resulting from the Q enhancing the resonator in the positive feedback loop, and Q spoiling in the negative feedback loop. From the quantization noise perspective in the negative feedback loop, it is a pole and a zero that are slightly separated such that the zero is what does the work of the baseband delta-sigma.

The ADC may optionally be direct sampling which does not require down conversion. In this discussion, direct sampling ADC has been assumed for most of the analysis. However, this can imply a down-conversion prior to the ADC. There are several variations possible that may also be included in the analysis and development of a dual loop architecture. As discussed, the principle of the dual loop may be considered independently of how the down conversion and digitization is done. Therefore, what is considered for direct sampling may also be applicable for a general down conversion and digitization scheme.

Upstream signal loop 972 also provides the required bandpass poles of moderately high Q that are necessary for implementing a VBP-DSM 970 loop. The main objective of VBP-DSM 970 is to suppress the quantization noise of the digitization process within the narrow band of the desired signal. This is achieved by actually shaping the noise spectrum of ADC 54 quantization noise to frequencies outside of the band of the desired signal.

In an ideal case, an effective VBP-DSM 970 with further Q enhancement of the resonator poles would simultaneously result in higher frequency selectivity of the desired signal. However, to achieve the desired noise spectrum shaping, Q spoiling of the upstream signal loop components may be required. Hence the proposed VBP-DSM implementation may be considered a compromise with a primary objective of achieving the highest SNR output of the digitization process possible. The dual loop may use the negative feedback loop DSP filtering to achieve the final passband shaping of the desired signal, as will be discussed.

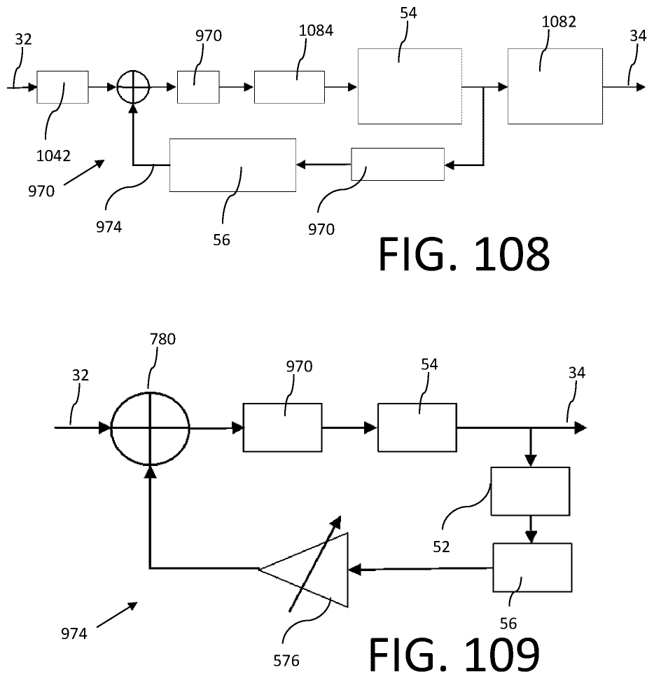

The generalized dual loop architecture 1080 may be as shown in FIG. 108. LNA 1042 may be beneficial where a NF of less than about 5 dB is required as the gain of LNA 1042 will compensate for the loss of the summing block and the NF of upstream signal loop 972. The diagram only includes one upstream signal loop 972, but for implementing a higher order VBP-DSM, two upstream resonator components may be used. The down conversion and up-conversion may not be necessary in cases where a direct sampling ADC is used. Dual loop architecture 1080 has a DSP passband filter 1082, a scaling block 1084, and a VBP-DSM 970 in negative feedback loop 974.

VBP-DSM 970 may be used to shape the noise of the components after upstream signal loop 972 so that they are outside of the bandwidth of the desired signal. This may result in a much lower NF of this section of the circuit. With this, the signal level into this portion of the circuit may be reduced by scaling the overall signal. This is the function of scaling block 1084 in FIG. 108. With reduced signal amplitude into the down conversion and digitization block the linearity of the overall receiver is improved, allowing larger out of band interference signals to be accommodated.

The analysis of VBP-DSM 970 may be difficult due to the mixed signal modelling required. This is simplified by approximating the bandpass operations as equivalent baseband below. This allows for efficient time domain simulation. Secondly, the nonlinear behavior of the digitization process can be linearized allowing for Laplace LTI analysis. This is the first step is to justify the baseband modelling as representative of the variable bandpass dual loop system. Then the baseband VBP-DSM can be described by introducing the simultaneous transfer function of the signal and the noise and considered as a first and second order VBP-DSM in the negative feedback loop of the dual loop architecture.

### Baseband Variable Delta-Sigma Formalism

In this section the equivalence of a bandpass pole as a first order low frequency pole will be considered to justify the baseband model as being used to represent the bandpass system of the variable bandpass delta-sigma. Consider the input impedance of a parallel RLC resonator which is given as

$${Z}_{in} = \frac{1}{\frac{1}{R} + \frac{1}{j ω L} + j ω C}$$

Specifically consider the expansion around ω=ωₒ+Δω. This may be written as

$${Z}_{in} = \frac{1}{\frac{1}{R} + \frac{1}{j ( {ω}_{o} + Δ ω ) L} + j {ω}_{o} C + j Δ ω C} = \frac{R}{1 + \frac{R}{j {ω}_{o} ( 1 + \frac{Δ ω}{{ω}_{o}} ) L} + j {ω}_{o} CR + j Δ ω CR}$$

which can be approximated as

$${Z}_{in} \approx \frac{R}{1 + \frac{R ( 1 - \frac{Δ ω}{{ω}_{o}} )}{j {ω}_{o} L} + j {ω}_{o} CR + j Δ ω CR} = \frac{R}{1 + j \frac{R \frac{Δ ω}{{ω}_{o}}}{{ω}_{o} L} + j Δ ω CR}$$

which is valid provided that

$$\frac{Δ ω}{{ω}_{o}} ≪ 1$$

Hence this approximation only refers to operating around resonance and not the Q of the pole itself. Using since

$$Q = \frac{R}{{ω}_{o} L} = RC {ω}_{o}$$

which can be simplified as

$${Z}_{in} \approx \frac{R}{1 + j 2 Q \frac{Δ ω}{{ω}_{o}}}$$

Finally normalize this as

$$\frac{{Z}_{in}}{R} \approx \frac{1}{1 + j 2 Q \frac{Δ ω}{{ω}_{o}}}$$

which is only dependent on the bandpass pole parameters of {ωₒ, Q}. Hence the bandpass pole at

$$j {ω}_{o} - \frac{{ω}_{o}}{2 Q}$$

is equivalent to the low pass pole at DC. Consider the expression of

$$\frac{1}{1 + j 2 Q \frac{Δ ω}{{ω}_{o}}} = \frac{\frac{{ω}_{o}}{2 Q}}{\frac{{ω}_{o}}{2 Q} + j Δ ω}$$

Hence the pole is on the negative real axis at

$$s = - \frac{{ω}_{o}}{2 Q} = - {ω}_{o} D$$

which is expected.

### First Order Baseband Variable Delta-Sigma

Referring to FIG. 109, a first order VBP-DSM 970 may include a single negative feedback loop 974 with a single upstream signal loop 972, ADC 54, DSP 52, DAC 56, negative feedback gain 576 and sum-block 780. The pole of the negative feedback loop within the VBP-DSM is slightly Q spoiled with the negative feedback.

From the perspective of the ADC quantization noise, the transfer function is H(s)=s/(s+G), and from the input signal perspective, the transfer function is H(s)=1/(s+G). Hence the ratio of the signal to noise transfer functions is 1/s. Note that this ratio is independent of G. This hides the fact that the signal bandwidth increases with a decrease in the VBP-DSM negative feedback loop G as the negative feedback loop BPF pole moves away from the jω axis.

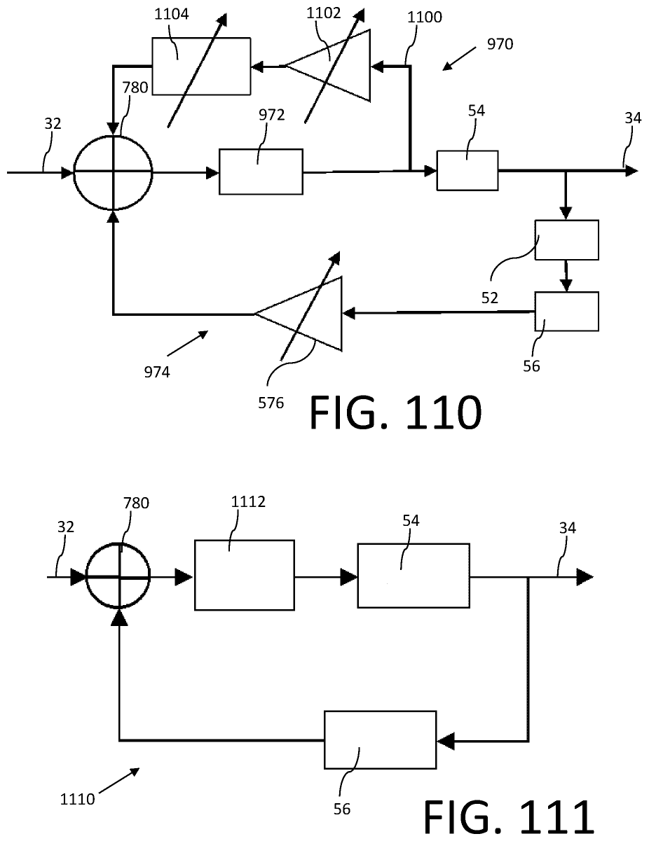

In an example shown in FIG. 110, the dual loop architecture combines a positive feedback loop 1100 with a negative feedback VBP-DSM loop of FIG. 109 and adds a variable phase shifter. Positive feedback loop 1100 has a positive gain block 1102 and a phase shifter 1104.

The limit of G<0 can be seen when delay is included in positive feedback loop 1100. To analyze this, it is necessary to switch into discrete time analysis where the pole trajectory would eventually cross the unit circle and the positive feedback loop becomes unstable.

Positive feedback loop 1100 provides a narrow band Q enhanced pole for input signal 32, thus protecting ADC 54. For the quantization noise of ADC 54, it provides a zero close to the jω axis which is effective in reducing the quantization noise around the band of the desired signal.

Consider what this means for input signal 32. There is positive feedback loop 1100 at the top in parallel with negative feedback loop 974 at the bottom. Therefore, the net Q enhancement can remain the same if the feedback loop 1100 is compensated for the gain of negative feedback loop 974. It is the total feedback gain that is of significance as the pole is being pushed toward the jω axis. This becomes the zero for VBP-DSM 970 and negative feedback loop 974. In other words, the dual loop allows for independent control of the position of the pole and the zero.

The positive feedback loop 1100 gain can now be greater than 1. Without negative feedback gain 576, a positive feedback loop gain G>1 would become an unstable feedback loop and oscillate. The outer negative feedback loop gain can be increased from a low value to a higher value such that the oscillation ceases. This provides a zero that can be close to the jω axis and a pole that is moved away from the jω axis giving the required and stable bandwidth for the desired signal.

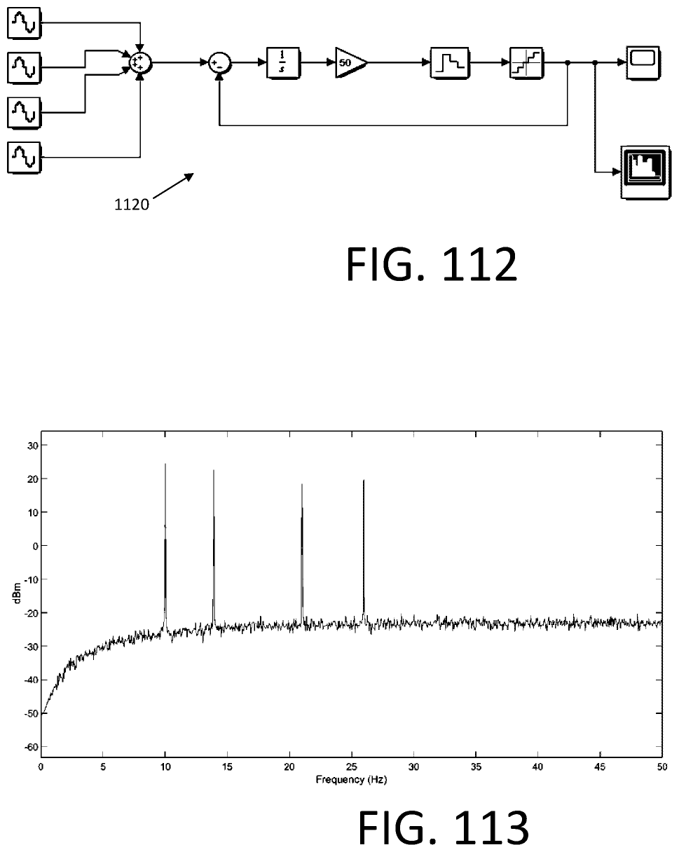

The outcome of the previous section was justification for modelling VBP-DSM 970 as the baseband delta-sigma module (BB-DSM) provided that the Q of the bandpass pole is sufficiently high. This is convenient as the BB-DSM is easier to develop and analyze. Consider first a continuous time loop 1110 as shown in FIG. 111 with a transfer function block 1112 of G/s. The conventional BB-DSM has an integrator which represents a resonator with infinite Q. Later the effect of a pole with a negative real part will be considered.

Let the Signal Transfer Function (STF) denotes the transfer function from the input to the output and let the Quantization Noise Transfer Function (QNTF) denote the transfer function from the source of the quantization noise at the output of the ADC to the output port.

There may be considered an arbitrary mapping in the ADC and DAC from analog to digital and digital to analog each with a gain of 1. There is then an additional loop gain associated with the integrator such that the transfer function is G/s. Based on this the transfer functions can be written as.

$${H}_{STF} ( s ) = \frac{G / s}{1 + G / s} = \frac{1}{\frac{s}{G} + 1}$$

$${H}_{QTF} ( s ) = \frac{1}{1 + G / s} = \frac{s / G}{\frac{s}{G} + 1}$$

Hence the STF is a first order low pass filter with a pole at s=−G and the QNTF is a high pass filter with a pole also at s=−G. The important bit is that the QNTF has a zero at s=0 (refer to FIG. 98). Hence for low signal frequency such that frequency<<G then the quantization noise is suppressed in the output while the desired signal passes through.

This is the central concept of VBP-DSM which is simply that at low frequency the signal passes through with no loss while the quantization noise is suppressed.

At higher frequency though, this desirable characteristic fades. Therefore VBP-DSM is applicable where the ratio of the ADC sampling rate to the Nyquist rate of the bandpass signal is large.

In the STF and QNTF for continuous time given above, if G increases then the pole moves along the real axis into the LHP and the cut-off frequency increases. Hence the frequency region over which the VBP-DSM is effective increases. However, the limitation is the ADC sampling frequency.

Now consider a signal g(t) at a frequency of ωₛ<<G and interference v(t) at ωᵥ<<<G such that both components are passed through the loop with unity gain. Hence the output will be approximately g(t)+v(t). The noise added is q(t) but this is attenuated by approximately ωₛ/G at the signal frequency and ωᵥ/G at the interference frequency. It may be assumed that there is subsequent filtering after the VBP-DSM loop to remove the higher frequency interference.

The point here is that the VBP-DSM is not about suppressing the interference relative to the desired signal. Rather it is about suppressing the quantization noise at the frequency of the desired signal. The actual form of the quantization noise at the interference frequency may be disregarded as it can be assumed that a subsequent DSP band pass filtering around the desired component suppresses the interference.

Next the approximate equivalence of the integrator may be considered as being replaced by the discrete time accumulator. This is done with the mapping as

$${H}_{i n t} ( z ) = \frac{G T}{1 - {z}^{- 1}}$$

### Then the STF is

$${H}_{STF} ( z ) = \frac{\frac{GT}{1 - {z}^{- 1}}}{1 + \frac{GT}{1 - {z}^{- 1}}} = \frac{GT}{1 - {z}^{- 1} + GT} = \frac{GT z}{( 1 + GT ) z - 1}$$

which has a pole at

$$= \frac{1}{1 + GT}$$

For the QNTF the zero remains at z=1. In a real ADC, there is a latency with the conversion such that an additional z⁻¹ may be included in the open loop transfer function:

$${H}_{int} ( z ) = \frac{GT {z}^{- 1}}{1 - {z}^{- 1}}$$

### Then the STF is

$${H}_{STF} ( z ) = \frac{\frac{GT {z}^{- 1}}{1 - {z}^{- 1}}}{1 + \frac{GT {z}^{- 1}}{1 - {z}^{- 1}}} = \frac{GT {z}^{- 1}}{1 - {z}^{- 1} + GT {z}^{- 1}} = \frac{GT}{z - ( 1 - GT )}$$

which has a pole at z=1−GT.

When GT exceeds 2, the pole exits the unit circle and the VBP-DSM at that point becomes unstable. Also, it should be clear that the effect of the zero in the QNTF at z=1 only has effect for frequencies that are low in frequency relative to the sampling frequency.

First Order Delta-Sigma Example with Signal Sampling at 100 Hz

The following is an example of a first order VBP-DSM with a sampling rate of 100 Hz and an ADC that quantizes at a resolution of 0.2. Four input sinusoidal signals are used at different frequencies in Simulink model 1120 as shown in FIG. 112. This is necessary as there is a difficultly with modelling quantization noise in that it is not really a noise but rather a deterministic function of the combined input. If there was only a small input desired signal, then the quantization noise would behave unrealistically. Hence, one sinusoid represents the signal and three sinusoids at higher frequency represents the interference. In plotting the resultant power spectrum, it is easy to sort out what is the noise floor due to the quantization noise and what is the interference signal. This provides a clear picture of the benefit of the VBP-DSM resulting from noise shaping.

The spectrum is shown in FIG. 113 showing the 4 frequency components. The amplitudes of all of the sinusoids are one. The noise floor in the spectrum is entirely due to the quantization noise. Note the decrease in the noise floor at low frequencies which is the desired noise shaping. Hence, the desired signal is placed in this low frequency region and the effects of quantization noise are greatly reduced.

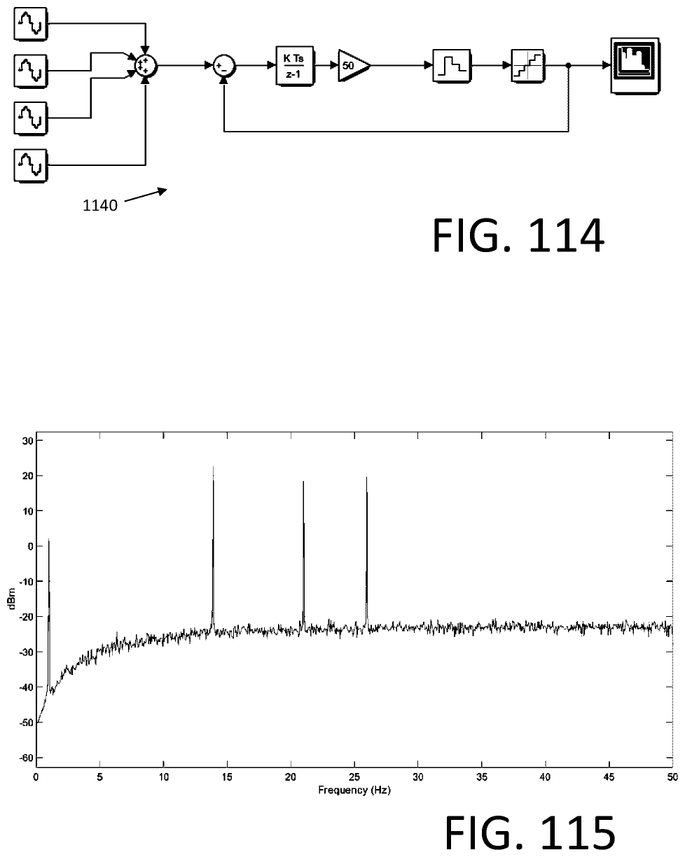

A note is that it may seem that the gain required is significant which is an issue in a closed loop. However, this gain is associated with an integrator and therefore the gain is illusory and more about how fast a capacitor integrator can be charged by a current source as in a physical circuit. Note that making the capacitor smaller is equivalent to increasing the gain. The integrator can also be replaced with a discrete time accumulator, as shown in a Simulink model 1140 as depicted in FIG. 114, and get the same results.

First Order Delta-Sigma Example with Weak Tone Signal at 1 Hz

In the next simulation, the signal is at 1 Hz and an amplitude of 0.1 and some higher frequency interference with amplitudes of 1 each. Results are shown in FIG. 115. Note how the VBP-DSM significantly improves the SNR of the signal by roughly 18 dB.

### Second Order Delta-Sigma Provides Additional Quantization Noise Suppression

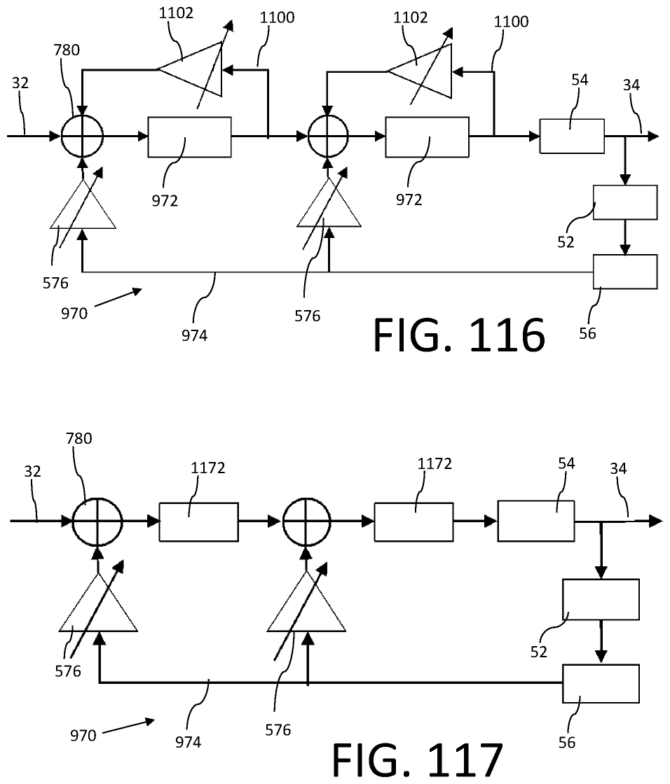

Turn now to the second order VBP-DSM 970 as shown in FIG. 116 showing two upstream signal loops 972.

The advantage of the second order is that it provides a second zero in the passband of the desired signal for the quantization noise. In the complex baseband this can be modeled with a pair of integrators 1172 (representing 1/s1 and 1/s2) as in FIG. 117.

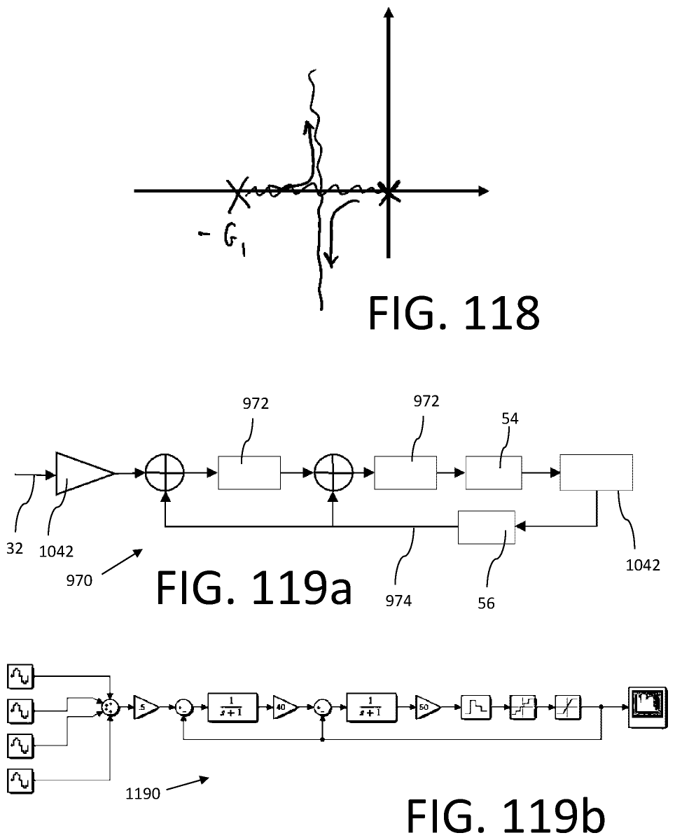

If the movement of the closed loop poles of this circuit is analyzed, the result is the locus as in FIG. 118.

The utility of the additional positive feedback loops of the second order VBP-DSM 970 is that the bandpass poles can be placed anywhere in the LHP, providing significant design flexibility. For example, the gains G₁ and/or G₂ may be adjusted such that the two positive feedback loops are unstable and oscillate. G₃ and/or G₄ may then be increased until the oscillation ceases. In this way there may be more control of the positions of the poles, and they may be placed arbitrarily close to the jω axis. This gives flexibility in configuring the VBP-DSM for both the desired signal passband and the VBP-DSM noise suppression.

Further suppression of the quantization noise can be had with a second order system. This has two 1/s integrators as shown in FIG. 119a. A Simulink model 1190 is shown in FIG. 119b.

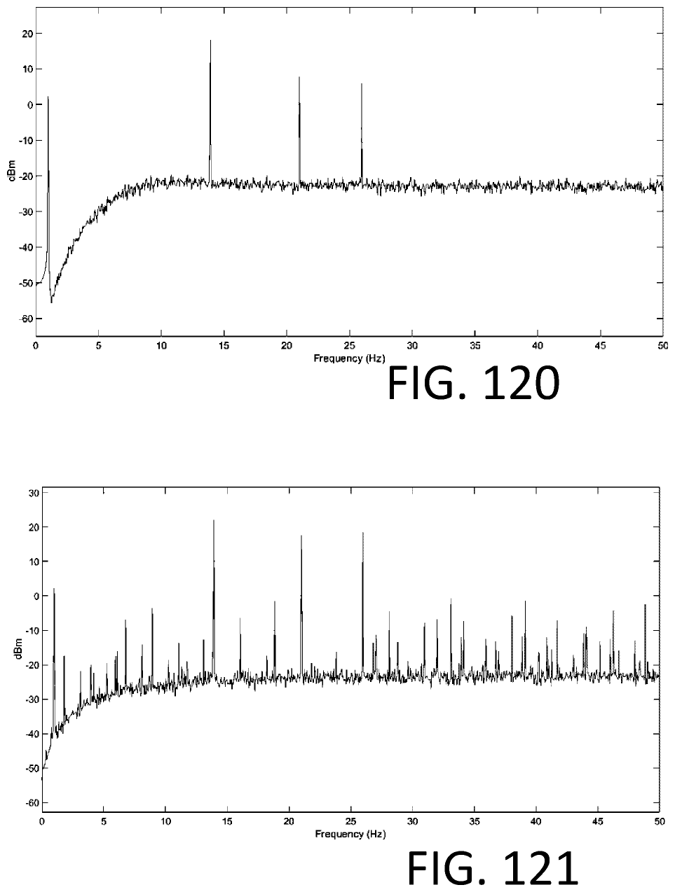

Remarkable results, with an ADC that only has six quantization levels of {−0.5,−0.3,−0.1,0.1,0.3,0.5}, are seen in FIG. 120, showing an improvement in SNR of 28 dB resulting from the second order delta-sigma movement of quantization noise out of the signal frequency band.

At this point, saturation of the ADC has been avoided by reducing the input gains to the ADC but add scaling at the output of the ADC.

To aid in visualization of the signal flow in negative feedback loop 974, consider outer loop 50 of FIG. 3 at a high level. For this linear superposition has to be considered such that for the categories at the output of the quantizer, there is a random confusion between neighborhood states. This is just stating that in an ADC output, noise will result in a randomness between adjacent mapped values. For quantization noise, this may be regarded as a confusion between a given state and its immediate neighbor states.

### ADC Considerations

### ADC Sampling Rate

Next, the sampling rate of the ADC will be considered. Let the sampling interval be T such that the sampling frequency is 2π/T (rads/sec). If this frequency is much higher than ωₛ or ωᵥ then the effects of frequency folding need not be considered. Then G can be increased such that quantization noise becomes negligible. This is equivalent to a high oversampling ratio. Typically, it may be assumed that there is some up-front fixed filtering that is commensurate with the ADC sampling rate such that frequency folding does not occur.

Next, the saturation effects of the ADC are considered. If the input signals are large such that the ADC saturates then the SNR is reduced significantly. Saturation negatively impacts the SNR and is to be avoided. It can never be avoided completely as a number of interference signals are generally superimposed at the input with the combined amplitude being statistical. It is more that the backoff of the signal into the ADC is based on the RMS of the composite signal and then the SNR degradation can be determined by approximating the probability density function of the combined amplitude to be Rayleigh. However, managing the saturation with a backoff of the input signal implies an increase in the equivalent noise figure (NF) for this portion of the receiver. As the receiver is a careful balance of NF and linearity this is an issue. To calculate this, the step size of the ADC in relation to kTB thermal noise may be considered.

If the input is scaled by a ratio of (1/R), then it follows directly that 20 log(R) higher interference power can be tolerated with the same probability of ADC saturation. In the VBP-DSM it is considered that the transfer gain of the quantization noise is ωₛ/G. It follows therefore that R=G/ωₛ can be set and then the level of quantization noise to the desired signal level is the same as if there was no scaling (R+1) and no VBP-DSM loop. However, an increase of the interference power level of 20 log(G/ωₛ) dB can be tolerated which can ameliorate the issue of ADC saturation.

Stating another way, if ADC has a fixed sampling interval of T, the power spectral density of the quantization noise will be proportional to 1/T. Furthermore, if a VBP-DSM loop is implemented then the input can be scaled by a factor of R=G/ωₛ with no degradation in the output SNR due to the quantization noise of the ADC. For the first order VBP-DSM, G is not limited. All that happens is that the pole moves towards the center. However, if the delay of the ADC is added then G will have a limit, but it is not overly significant.

In one example, the dual loop architecture may involve A VBP-DSM to take advantage of the oversampling rate of the ADC to reduce quantization noise that subsequently allows for a signal reduction into the ADC that then results in a higher tolerance for interference.

Why does this benefit not result with Q enhancement? With Q enhancement the pole at ωₛ would be placed closer to the jω resulting in a larger gain at the desired frequency. At the interference frequency there is no enhanced gain. But this means that while the desired signal is grown relative to the interference signal, it is not the case that the interference signal is suppressed. Hence at the input to the ADC there is now a larger desired signal and the same size interference signal. But now it would seem that the input to the ADC can be reduced, but this just reduces the loop gain which may be maintained for Q enhancement. Having the signal scaling outside of the loop triggers an increase in the NF which can be seen by taking the quantization noise and replacing it with an equivalent noise source at the input to the loop. Here now the quantization noise competes directly with the desired signal which is now attenuated due to the scaling.

ADC Saturation Effects with Scaling Following Tone Input Mixing

Next consider the effect of ADC saturation. Here the saturation of the ADC is set at ±1. The effect is shown in FIG. 121 where intermodulation mixing of the four sinusoids is seen due to the hard saturation of the ADC. The mixing tones are in the vicinity of the desired signal which is clearly an issue.

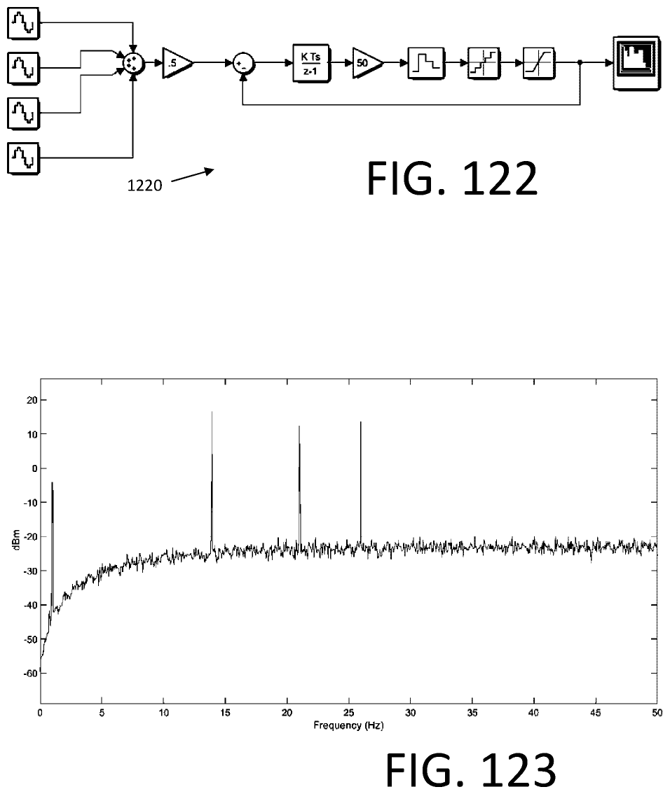

To fix this, a scaling can be applied prior to the loop as in the following simulation. 6 dB of attenuation, as shown in a Simulink model 1220 depicted in FIG. 122, solves the problem of the ADC saturation as seen in FIG. 123.

However, this is not a viable solution as the NF of the integrator will have a moderate NF and the 6 dB of loss will add directly to the integrator NF.

ADC Saturation Effects with Scaling Before ADC

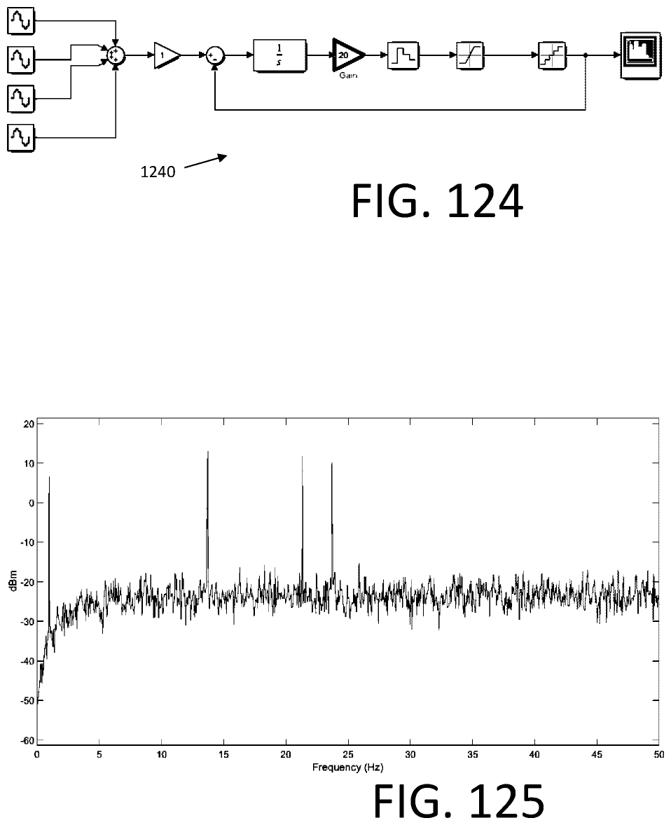

A better approach is to apply the scaling in front of the ADC as shown in a Simulink model 1240 depicted in FIG. 124, where the gain is reduced to G=20. Simulation results are shown in FIG. 125, where removal of spurious saturation effects can be seen.

The delta-sigma loop gain can be obtained again by adding a larger scaling after the ADC. If a feedback gain of 2.5 is added after the ADC, then the equivalent of the loop gain back to 50 is received and the quantization noise improves as ‘G’ has increased from 20 to 50.

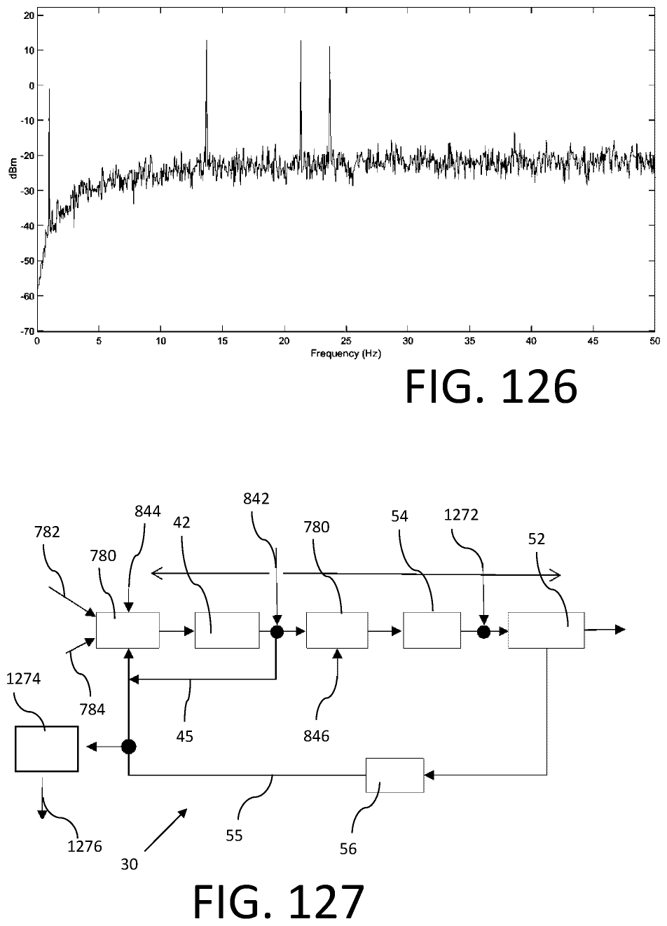

6 dB of the desired signal is lost into the ADC due to the attenuator required to eliminate the saturation. However, 20 dB is gained due to the VBP-DSM and hence the noise floor is improved by about 14 dB. If the input frequency was even lower, then the SNR could be further improved as evidenced in FIG. 126.

### Other Details of Software Defined Radio (SDR) Application of Dual Loop Mixed Signal Processing

One utility of the DPLP processing is direct frequency translation discussed above that may also be achieved in a DSP which additionally provides signal digitization using discrete time sampling and quantization discrete time sampling of the signal and subsequent reconstruction where the feedback processing may be precisely implemented.

For application of signal processing circuit 30 to the SDR, additional taps may be added to signal processing circuit 30 discussed above, as shown in FIG. 127. A transmit DSP input tap point 1272 and a transmit output tap point 1274 which outputs to an antenna 1276 are added.

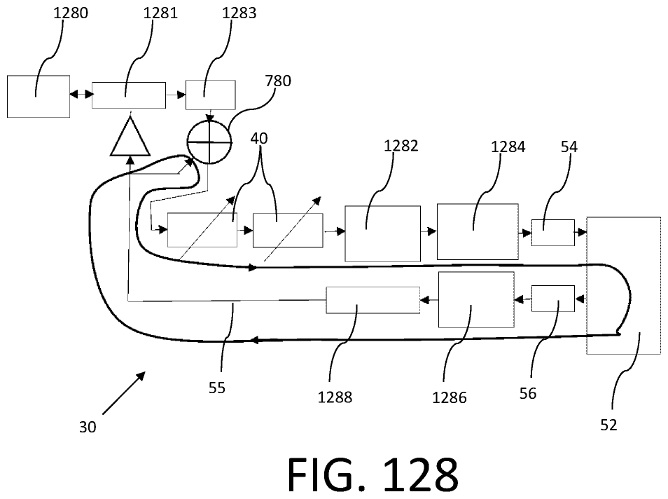

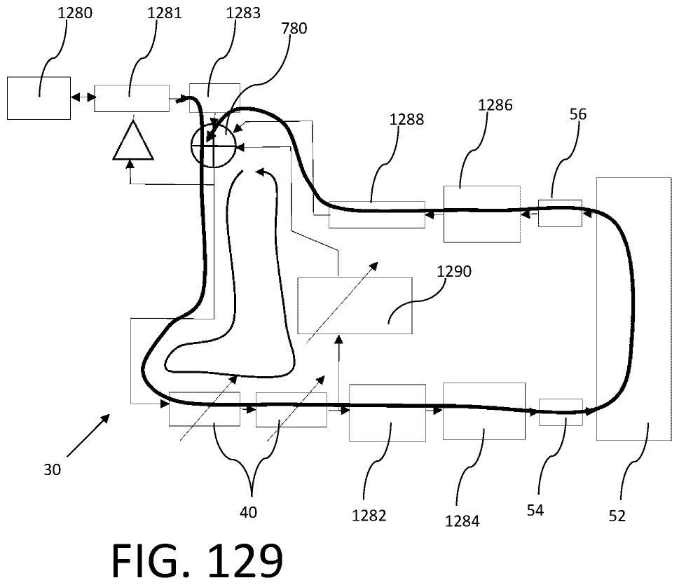

A more detailed view of the dual loop mixed signal processing architecture in the transmit mode is seen in FIG. 128 which shows a signal processing circuit 30 that consists of three partitions:
1. A forward path from sum block 780, through inner loops 40, down conversion 1282, an anti-aliasing LPF 1284, and ADC 54 to DSP 52
2. Feedback processing in the DSP
3. A reverse path 55 from DAC 56 through up conversion 1286 and a bandpass filter 1288 back to sum block 780

The loop is connected to an antenna 1280, a T/R switch 1281, and an LNA 1283 as shown. The forward signal path, digitization, and DSP may be existing components of an SDR as shown in FIG. 128. Hence the DPLP may be implemented in an SDR with conventional transmit and receive channels.

In FIG. 129, antenna 1280 feeds into T/R switch 1281 with the receive port going into LNA 1283 and the DPLP forward path with a plurality of inner loops 40. DPLP loop processing is completed in DSP 52, and the SDR feedback passes through the DAC 56, up-conversion 1286 and then the summer 780 as before.

In the standard SDR transmit mode, DSP 52 generates the transmit baseband signal with the DAC 56 and up-conversion 1286, but now the signal is passed to the power amplifier T/R switch 1281 and to the antenna 1280. In this way there is little additional hardware required for the DPLP function. Bandpass filter 1288 after up conversion 1286 is a broad bandwidth designed to remove some of the spurious DAC components such as the noise components of DAC 56. However, this is hampered as DAC 56 is within the loop and contributes noise.

For this an additional active RF feedback 1290 may be required as shown in FIG. 129. Note that the transmit filtering may be achieved with adding a modest amount of additional hardware.

Many SDR options are relevant here, some of which include:
In a direct sampling SDR there may be no down conversion
Frequency translation may be optionally handled in DSP
Sub-sampling is applicable.

As an example, three single-pole resonators may be provided with an active feedback signal loop with a variable gain block to form a bandpass filter in the RF domain. When the feedback gain is increased, the center pole of the three resonators moves toward the jω axis, while the flanking poles move a smaller amount away from the jω axis, thus creating Q-enhancement.

Inversely, if the feedback gain is reduced, the center pole of the three resonators moves away from the jω axis, while the flanking poles move a smaller amount toward the jω axis, thus creating Q-spoiling.

With the DPLP state space feedback, however, each of the three s-plane poles may be independently moved toward the jω axis simultaneously for Q-enhancement or away from the jω axis for Q-spoiling. As long as no single pole moves across the jω axis into the right hand s-plane from the left-hand plane, then this active feedback 3-pole BPF is always stable.

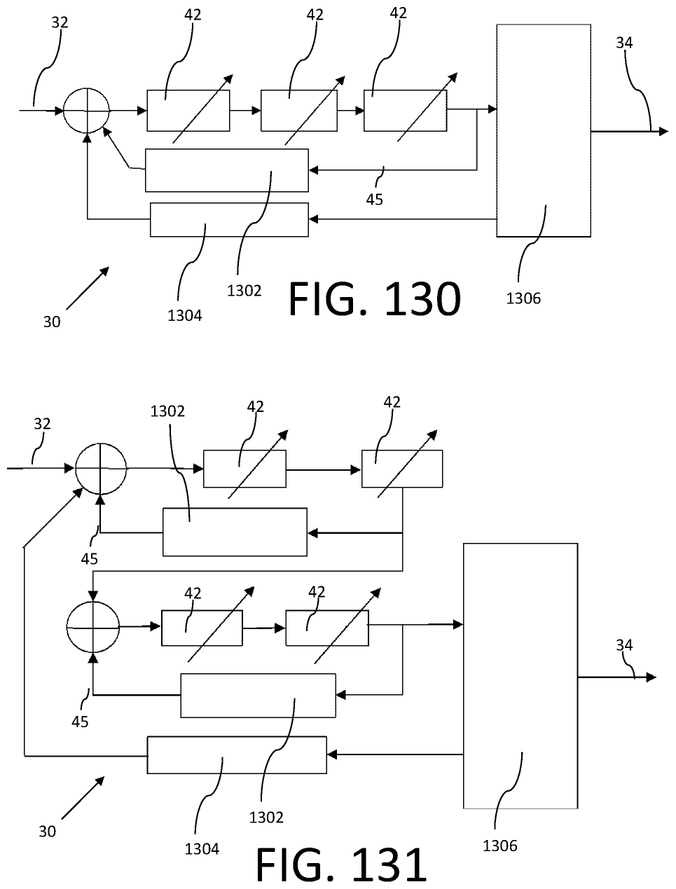

One could have the active feedback BPF enabled, and then disable this active feedback BPF path and enable the DPLP state space feedback path. Additionally, referring to FIG. 130, the signal processing circuit 30 may include both the active gain modifying feedback processing 1302 in inner feedback path 45 and DPLP feedback processing 1304 in the state space feedback path. Active gain feedback control is useful for modest Q enhancements where the resulting pole Q is modest. In FIG. 130 the ADC, DAC, and DSP are represented in combined block 1306.

The DPLP feedback processing may include up-conversion for use with a slower rate DAC or may be at the signal frequency for a high sampling rate DAC. While DPLP is capable of Q enhancing all three poles simultaneously, latency in DSP processing may be introduced if the BPF bandwidth is too broad.

Referring to FIG. 131, with a cascade of band pass filters 42, more resonator poles may be Q enhanced. These may be Q enhanced for a two-pole bandpass filter between the input port and the ADC port. Alternately, the DPLP may be used to Q enhance all four resonators simultaneously for a four-pole bandpass filter as shown in FIG. 131.

In this patent document, the word “comprising” is used in its non-limiting sense to mean that items following the word are included, but items not specifically mentioned are not excluded. A reference to an element by the indefinite article “a” does not exclude the possibility that more than one of the elements is present, unless the context clearly requires that there be one and only one of the elements.

The scope of the following claims should not be limited by the preferred embodiments set forth in the examples above and in the drawings, but should be given the broadest interpretation consistent with the description as a whole.

1. A signal processing circuit, comprising:
a first signal loop comprising a first signal processing block and a first feedback path that extends around the first signal processing block, the first signal processing block having a frequency dependence that causes the first signal loop to generate a passband;
a second signal processing block downstream of the first signal loop; and
a second feedback path that extends from downstream of the second signal processing block to upstream of the first signal processing block;
wherein, in operation, the first feedback path reinforces a signal in the passband and the second feedback path conditions the signal at an output downstream of the first signal processing block.

2. The signal processing circuit of claim 1, wherein the first feedback path is a positive feedback path, the second feedback path is a negative feedback path, and wherein the negative feedback path suppresses internal noise generated downstream of the first signal processing block.

3. The signal processing circuit of claim 1, wherein the first signal processing block comprises a resonator.

4. The signal processing circuit of claim 3, wherein a central frequency, a frequency selectivity, or both a central frequency and a frequency selectivity of the resonator is tunable.

5. The signal processing circuit of claim 4, further comprising an adjustable scaling block in the first feedback path, the second feedback path, or both the first feedback path and the second feedback path.

6. The signal processing circuit of claim 3, wherein the second signal processing block applies a first domain transformation, and the second feedback path comprises a third processing block that applies a second domain transformation that is an inverse of the first domain transformation.

7. The signal processing circuit of claim 6, wherein the second signal processing block comprises an analog-to-digital converter (“ADC”), and the third processing block comprises a digital-to-analog converter (“DAC”).

8. The signal processing circuit of claim 7, wherein the internal noise comprises quantization noise from the ADC.

9. The signal processing circuit of claim 7, further comprising a digital signal processor that conditions a signal in the second feedback path.

10. The signal processing circuit of claim 7, wherein an output of the ADC is connected to a digital signal processor as a receive channel of a software defined radio.

11. The signal processing circuit of claim 1, wherein the first signal processing block, the second signal processing block, or both the first signal processing block and the second signal processing block comprises at least a phase control element.

12. The signal processing circuit of claim 3, comprising a plurality of bandpass filters connected in series, each bandpass filter comprising a corresponding first feedback path.

13. The signal processing circuit of claim 12, comprising one or more further second feedback paths connected in parallel from downstream of the second signal processing block to between adjacent bandpass filters of the plurality of bandpass filters.

14. The signal processing circuit of claim 13, wherein the first feedback path is a positive feedback path, the second feedback path is a negative feedback path, and further comprising a controller programmed with instructions to adjust a positive gain block of the positive feedback path to cause the bandpass filter to self-oscillate, and then adjust a negative gain block of the negative feedback path to stabilize the bandpass filter.

15. The signal processing circuit of claim 1, wherein the second signal processing block is controlled by a controller.

16. The signal processing circuit of claim 1, wherein the first signal processing block comprises an acoustic wave resonator and an adjustable phase control element.

17. The signal processing circuit of claim 1, wherein the first signal processing block comprises a plurality of acoustic wave filters and a switch that selects a desired one of the plurality of acoustic wave filters.

18. The signal processing circuit of claim 1, comprising a signal input upstream of the first signal loop.

19. The signal processing circuit of claim 1, comprising a signal input between the first signal processing block and the second signal processing block, the second feedback path comprising a negative gain block.

20. A method of processing a signal using a signal processing circuit that comprises a first signal loop comprising a bandpass filter and a first feedback path that extends around the bandpass filter such that the first signal loop comprises a passband, a signal processing block downstream of the bandpass filter, and a second feedback path that extends from downstream of the signal processing block to upstream of the bandpass filter, the method comprising the steps of:
causing the first signal loop to generate a filtered signal in the passband;
processing the filtered signal using the signal processing block downstream of the bandpass filter such that an output signal is conditioned at an output downstream of the bandpass filter.

21. The method of claim 20, wherein the first feedback path is a positive feedback path, the second feedback path is a negative feedback path, and wherein conditioning the output signal comprises suppressing internal noise generated downstream of the bandpass filter.

22. The method of claim 21, wherein the signal processing block applies a domain transformation, and the negative feedback path comprises a further processing block that applies a second domain transformation that is the inverse of the first domain transformation.

23. The method of claim 22, wherein the signal processing block is an analog-to-digital converter (“ADC”), and the further processing block comprises a digital-to-analog converter (“DAC”).

24. The method of claim 23, wherein the internal noise comprises quantization noise from the ADC.

25. The method of claim 20, further comprising the step of adjusting a gain of the first feedback path to cause the bandpass filter to self-oscillate, and then adjusting a gain of the second feedback path to stabilize the bandpass filter.

26. The method of claim 20, wherein generating a filtered signal and conditioning the output signal comprises controlling a gain factor, a phase, or the gain factor and the phase in each of the first feedback path and the second feedback path.

27. The method of claim 20, further comprising the step of tuning a central frequency, a frequency selectivity, or both a central frequency and a frequency selectivity of the bandpass filter.

28. The method of claim 20, comprising a plurality of bandpass filters connected in series, each bandpass filter comprising a corresponding feedback path.

29. The method of claim 28, comprising a plurality of negative feedback paths connected in parallel from downstream of the signal processing block to upstream of the plurality of bandpass filters and between adjacent bandpass filters.

30. A receive module for a digital communication device, the receive module comprising:
a bandpass filter having a passband;
an analog-to-digital converter (“ADC”) downstream of the bandpass filter, the ADC having an output connected to a processor of the digital communication device;
a positive feedback path that extends from between the bandpass filter and the ADC to upstream of the bandpass filter; and
a negative feedback path that extends from downstream of the ADC to upstream of the bandpass filter, the negative feedback path comprising a digital-to-analog converter (“DAC”);
wherein, in operation, the positive feedback path reinforces a signal in the passband and the negative feedback path suppresses internal noise generated downstream of the bandpass filter.

31. The receive module of claim 30, wherein the digital communication device comprises a software defined radio.

32. A signal processing circuit for a digital communication device, comprising:
an outer signal loop comprising an input, an output, and a transformation block adapted to perform a signal transformation operation on a signal being processed; and
an inner signal loop comprising a tunable bandpass filter, the inner signal loop being nested within the outer signal loop such that the tunable bandpass filter is connected within each of the inner signal loop and the outer signal loop, and the transformation block is connected outside the inner signal loop.

33. The signal processing circuit of claim 32, wherein one or more of: a central frequency, a frequency selectivity, a Q factor, or combination thereof, of the bandpass filter are adjustable.

34. The signal processing circuit of claim 32, wherein the bandpass filter comprises a plurality of resonator outputs.

35. The signal processing circuit of claim 34, wherein the transformation block comprises a processor block that is programmed with instructions to individually control poles of a transfer function of the outer signal loop.

36. The signal processing circuit of claim 34, wherein the transformation block is adapted to apply a domain transfer to at least one of the resonator outputs.

37. The signal processing circuit of claim 34, wherein the transformation block receives the plurality of resonator outputs in parallel.

38. The signal processing circuit of claim 32, wherein the outer signal loop is a negative feedback loop and the inner feedback loop is a positive feedback loop.

39. The signal processing circuit of claim 34, wherein the transformation block is in a signal path of the outer signal loop, or in a feedback path of the outer signal loop.

40. The signal processing circuit of claim 32, wherein the inner signal loop comprises a positive feedback path and the outer signal loop comprises a negative feedback loop, such that the positive feedback path reinforces the signal being processed in a passband and the negative feedback path suppresses internal noise generated downstream of the bandpass filter.

41. The signal processing circuit of claim 40, wherein the signal processing block applies a first domain transformation, and the negative feedback path comprises a second processing block that applies a second domain transformation that is the inverse of the first domain transformation.

42. The signal processing circuit of claim 41, wherein the signal processing block comprises an analog-to-digital converter (“ADC”), and the second processing block comprises a digital-to-analog converter (“DAC”).

43. The signal processing circuit of claim 42, wherein the internal noise comprises quantization noise from the ADC.

44. The signal processing circuit of claim 42, further comprising a digital signal processor that conditions a signal in the negative feedback path.

45. The signal processing circuit of claim 32, the outer signal loop comprising an output connected to a transmit device.

46. The signal processing circuit of claim 32, the inner signal loop comprising an input upstream of the tunable bandpass filter outer signal loop that is connected to a receive device.
